(19) United States
(12) Patent Application Publication
(10) Pub. No.: US 2017/0012072 A1
(43) Pub. Date: Jan. 12, 2017

(54) INFRARED SENSOR, NEAR-INFRARED ABSORBING COMPOSITION, CURED FILM, NEAR-INFRARED ABSORBING FILTER, IMAGE SENSOR, CAMERA MODULE, AND COMPOUND

(71) Applicant: FUJIFILM Corporation, Tokyo (JP)

(72) Inventors: Takuya TSURUTA, Haibara-gun (JP); Kyohei ARAYAMA, Haibara-gun (JP); Satoru MURAYAMA, Haibara-gun (JP); Hirotaka TAKISHITA, Haibara-gun (JP)

(73) Assignee: FUJIFILM Corporation, Tokyo (JP)

(21) Appl. No.: 15/274,645

(22) Filed: Sep. 23, 2016

Related U.S. Application Data
(63) Continuation of application No. PCT/JP2015/059384, filed on Mar. 26, 2015.

(30) Foreign Application Priority Data
Mar. 31, 2014 (JP) 2014-073397
Mar. 10, 2015 (JP) 2015-047208

(51) Int. Cl. H01L 27/146; G02B 5/22; C07F 5/02; G02B 5/20

(52) U.S. Cl. CPC H01L 27/14625; G02B 5/208; G02B 5/223; H01L 27/14621; C07F 5/027

(57) ABSTRACT

Provided are an infrared sensor, a near-infrared absorbing composition, a cured film, a near-infrared absorbing filter, an image sensor, a camera module, and a compound. An infrared sensor 100 which has an infrared transmitting filter 113 and a near-infrared absorbing filter 111 and detects objects by detecting light having wavelengths of 700 nm or longer and shorter than 900 nm, in which the near-infrared absorbing filter 111 includes a near-infrared absorbing substance having a maximum absorption wavelength at a wavelength of 700 nm or longer and shorter than 900 nm.

### CROSS-REFERENCE TO RELATED APPLICATIONS

This application is a Continuation of PCT International Application No. PCT/JP2015/059384 filed on Mar. 26, 2015, which claims priority under 35 U.S.C §119(a) to Japanese Patent Application No. 2014-073397 filed on Mar. 31, 2014 and Japanese Patent Application No. 2015-047208 filed on Mar. 10, 2015. Each of the above application(s) is hereby expressly incorporated by reference, in its entirety, into the present application

### BACKGROUND OF THE INVENTION

1. Field of the Invention

The present invention relates to an infrared sensor, a near-infrared absorbing composition, a cured film, a near-infrared absorbing filter, an image sensor, a camera module, and a compound.

2. Description of the Related Art

Charge-coupled device (CCD) or complementary metal oxide semiconductor (CMOS) image sensors which are solid image pickup elements for color images are used for video cameras, digital still cameras, camera function-equipped mobile phones, and the like. In these solid image pickup elements, since silicon photodiodes having sensitivity to near-infrared rays are used in light-receiving sections, it is necessary to correct the luminosity factor, and near-infrared absorbing filters are frequently used.

As compounds capable of absorbing near-infrared rays, pyrrolopyrrole coloring agents and the like are known (for example, JP2011-68731A and Angew. Chem. Int. Ed. 2007, 46, 3750).

### SUMMARY OF THE INVENTION

Studies are underway regarding solid image pickup elements being used as sensors and the like in a variety of usages.

For example, since near-infrared rays have longer wavelengths than visible light, near-infrared rays are not easily scattered and can also be used for distance measurement, three-dimensional measurement, and the like. In addition, since near-infrared rays are invisible to human beings, animals, and the like, subjects are not able to sense their being irradiated even when irradiated using near-infrared light sources during the night, and it is also possible to use near-infrared rays to capture images of nocturnal wild animals or capture images of suspects for security purpose without stimulating the suspects.

As described above, studies are underway regarding solid image pickup elements being used as infrared sensors and the like with which objects are detected by detecting near-infrared rays.

Therefore, an object of the present invention is to provide an infrared sensor that is excellent in terms of detectability and image quality, a near-infrared absorbing composition, a cured film, a near-infrared absorbing filter, an image sensor, a camera module, and a compound.

As a result of detailed studies, the present inventors found that, when a near-infrared absorbing substance having a maximum absorption wavelength in a specific wavelength range is added to near-infrared absorbing filters, the above-described object can be achieved and completed the present invention. The present invention provides the following.

<1> An infrared sensor which has an infrared transmitting filter and a near-infrared absorbing filter and detects objects by detecting light having wavelengths of 700 nm or longer and shorter than 900 nm, in which the near-infrared absorbing filter includes a near-infrared absorbing substance having a maximum absorption wavelength at a wavelength of 700 nm or longer and shorter than 900 nm.

<2> The infrared sensor according to <1>, in which the near-infrared absorbing substance is a compound represented by General Formula (1) below;

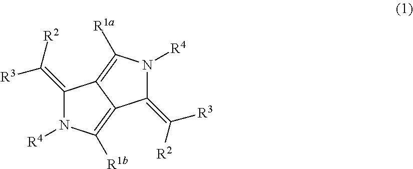

in General Formula (1), R^{1a} and R^{1b} each independently represent an alkyl group, an aryl group, or a heteroaryl group; R² and R³ each independently represent a hydrogen atom or a substituent, and R² and R³ may be bonded to each other and thus form a cyclic structure; R4's each independently represent a hydrogen atom, an alkyl group, an aryl group, a heteroaryl group, (R^{4A})₂B—, (R^{4B})₂P—, (R^{4C})₃Si—, or (R^{4D})ₙM-; R^{4A} to R^{4D} each independently represent an atom or a group; n represents an integer of 2 to 4, and M represents an n+1-valent metal atom; in a case in which R⁴ represents (R^{4A})₂B—, (R^{4B})²P—, (R^{4C})₃Si—, or (R^{4D})ₙM-, R⁴ may form a covalent bond or a coordinate bond with at least one selected from R^{1a}, R^{1b}, and R³; here, General Formula (1) satisfies at least one condition selected from at least one selected from R^{1a}, R^{1b}, and R⁴ having a crosslinking group and at least one selected from R² and R³ having crosslinking groups with a cyclic structure group therebetween.

<3> The infrared sensor according to <2>, in which the near-infrared absorbing substance satisfies at least one selected from conditions 1) to 3) below;

1) in General Formula (1), at least one selected from R^{1a} and R^{1b} has crosslinking groups with a cyclic structure group having aromaticity therebetween;

2) in General Formula (1), R² or R³ has crosslinking groups with a cyclic structure group having aromaticity therebetween; and

3) in General Formula (1), R⁴ has crosslinking groups with a cyclic structure group therebetween.

<4> The infrared sensor according to any one of <1> to <3>, in which the near-infrared absorbing substance has two or more crosslinking groups in a molecule.

<5> The infrared sensor according to any one of <2> to <4>, in which, in a case in which the crosslinking group is an olefin group or a styryl group, the near-infrared absorbing substance has three or more crosslinking groups in a molecule.

<6> The infrared sensor according to any one of <2> to <5>, in which R⁴ in the near-infrared absorbing substance represents (R^{4A})₂B—; here, R^{4A}'s each independently represent an atom or a group.

<7> The infrared sensor according to any one of <2> to <6>, in which one of R² and R³ in the near-infrared absorbing substance is a cyano group, and the other has a heterocyclic group.

<8> The infrared sensor according to <1> or <2>, in which the near-infrared absorbing substance is a compound represented by any one of General Formulae (2) to (4) below;

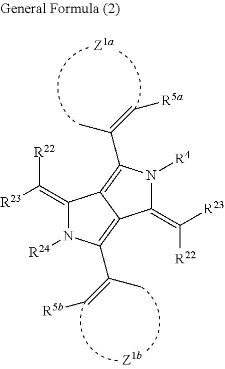

in General Formula (2), Z^{1a} and Z^{1b} each independently represent an atomic group forming an aryl ring or a heteroaryl ring; R^{5a} and R^{5b} each independently represent any one of an aryl group having 6 to 20 carbon atoms, a heteroaryl group having 4 to 20 carbon atoms, an alkyl group having 1 to 20 carbon atoms, an alkoxy group having 1 to 20 carbon atoms, an alkoxycarbonyl group having 2 to 20 carbon atoms, a carboxyl group, a carbamoyl group, a halogen atom, or a cyano group; R^{5a} or R^{5b} and Z^{1a} or Z^{1b} may be bonded to each other and thus form a fused ring; R²² and R²³ each independently represent a cyano group, an acyl group having 2 to 6 carbon atoms, an alkoxycarbonyl group having 2 to 6 carbon atoms, an alkyl group having 1 to 10 carbon atoms, an arylsulfinyl group having 6 to 10 carbon atoms, or a nitrogen-containing heteroaryl group having 3 to 20 carbon atoms, or R²² and R²³ may be bonded to each other and thus represent a cyclic acidic nucleus; R²⁴ represents a hydrogen atom, an alkyl group having 1 to 20 carbon atoms, an aryl group having 6 to 20 carbon atoms, a heteroaryl group having 3 to 20 carbon atoms, (R^{4A})₂B—, (R^{4B})₂P—, (R^{4C})₃Si—, or (R^{4D})ₙM-; R^{4A} to R^{4D} each independently represent an atom or a group; n represents an integer of 2 to 4, and M represents an n+1-valent metal atom; in a case in which R²⁴ represents (R^{4A})₂B—, (R^{4B})₂P—, (R^{4C})₃Si—, or (R^{4D})ₙM-, R²⁴ may form a covalent bond or a coordinate bond with at least one selected from R^{5a} and R²² to R²⁴; General Formula (2) satisfies at least one condition selected from at least one selected from R^{5a}, R^{5b}, and R²⁴ having a crosslinking group and at least one selected from R²² and R²³ having crosslinking groups with a nitrogen-containing heteroaryl group having 3 to 20 carbon atoms therebetween;

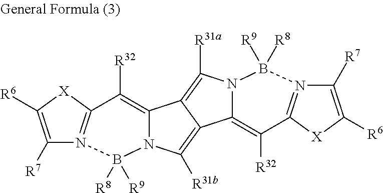

in General Formula (3), R^{31a} and R^{31b} each independently represent an alkyl group having 1 to 20 carbon atoms, an aryl group having 6 to 20 carbon atoms, or a heteroaryl group having 3 to 20 carbon atoms; R³² represents a cyano group, an acyl group having 2 to 6 carbon atoms, an alkoxycarbonyl group having 2 to 6 carbon atoms, an alkyl group having 1 to 10 carbon atoms, an arylsulfinyl group having 6 to 10 carbon atoms, or a nitrogen-containing heteroaryl group having 3 to 10 carbon atoms; R⁶ and R⁷ each independently represent a hydrogen atom, an alkyl group having 1 to 10 carbon atoms, an aryl group having 6 to 10 carbon atoms, or a heteroaryl group having 3 to 10 carbon atoms, R⁶ and R⁷ may be bonded to each other and thus form a ring, the ring being formed being an alicycle having 5 to 10 carbon atoms, an aryl ring having 6 to 10 carbon atoms, or a heteroaryl ring having 3 to 10 carbon atoms; R⁸ and R⁹ each independently represent an alkyl group having 1 to 10 carbon atoms, an alkoxy group having 1 to 10 carbon atoms, an aryl group having 6 to 20 carbon atoms, or a heteroaryl group having 3 to 10 carbon atoms; X represents an oxygen atom, a sulfur atom, —NR—, —CRR′—, or —CH═CH—, and R and R′ each independently represent a hydrogen atom, an alkyl group having 1 to 10 carbon atoms, or an aryl group having 6 to 10 carbon atoms; at least one selected from R⁶ to R⁹, R^{31a}, R^{31b}, and R³² has a crosslinking group;

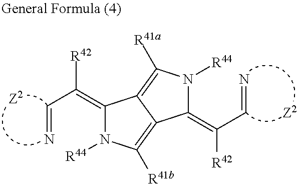

in General Formula (4), R^{41a} and R^{41b} represent mutually different groups and represent alkyl groups having 1 to 20 carbon atoms, aryl groups having 6 to 20 carbon atoms, or heteroaryl groups having 3 to 20 carbon atoms; R⁴² represents a cyano group, an acyl group having 1 to 6 carbon atoms, an alkoxycarbonyl group having 2 to 6 carbon atoms, an alkyl group having 1 to 10 carbon atoms, an arylsulfinyl group having 6 to 10 carbon atoms, or a nitrogen-containing heteroaryl group having 3 to 10 carbon atoms; Z²'s each independently represent an atomic group forming a nitrogen-containing 5-membered heteroring or nitrogen-containing 6-membered heteroring with —C═N—; R⁴⁴ represents a hydrogen atom, an alkyl group having 1 to 20 carbon atoms, an aryl group having 6 to 20 carbon atoms, a heteroaryl group having 4 to 20 carbon atoms, (R^{4A})₂B—, (R^{4B})²P—, (R^{4C})₃Si—, or (R^{4D})ₙM-; R^{4A} to R^{4D} each independently represent an atom or a group; n represents an integer of 2 to 4, and M represents an n+1-valent metal atom; in a case in which R⁴⁴ represents (R^{4A})₂B—, (R^{4B})₂P—, (R^{4C})₃Si—, (R^{4D})ₙM-, R⁴⁴ may form a covalent bond or a coordinate bond with a nitrogen-containing heterocycle formed by Z²; at least one selected from R^{41a}, R^{41b}, R⁴², and R⁴⁴ has a crosslinking group.

<9> The infrared sensor according to <1> or <2>, in which the near-infrared absorbing substance is a compound represented by General Formula (5) below;

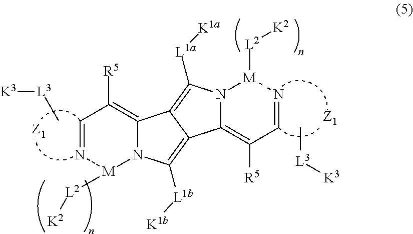

in General Formula (5), L^{1a}, L^{1b}, L², and L³ each independently represent a single bond or a divalent linking group; R⁵'s each independently represent a hydrogen atom or a substituent. Z¹ represents an atomic group forming a nitrogen-containing 5-membered heteroring or nitrogen-containing 6-membered heteroring with —C═N—; K^{1a}, K^{1b}, K², and K³ each independently represent a hydrogen atom, a fluorine atom, or a crosslinking group, and at least one of them represents a crosslinking group; M represents a boron atom, a phosphorus atom, a silicon atom, or a metallic atom; n's each independently represent an integer of 1 to 3; the bond between M and N indicated by a broken line represents a coordinate bond.

<10> The infrared sensor according to <9>, in which the near-infrared absorbing substance satisfies at least one selected from conditions 1A) to 3A) below;

1A) in General Formula (5), at least one selected from L^{1a} and L^{1b} includes a cyclic structure group having aromaticity;

2A) in General Formula (5), L² includes an aromatic hydrocarbon group; and

3A) in General Formula (5), L³ has a cyclic structure group having aromaticity.

<11> The infrared sensor according to <9>, in which, in General Formula (5), L^{1a} and L^{1b} each independently represent a single bond or an alkylene group having 1 to 30 carbon atoms, an arylene group having 6 to 20 carbon atoms, a heteroarylene group having 3 to 20 carbon atoms, —O—, —S—, —C(═O)—, or a group formed of a combination of these groups, L²'s each independently represent a single bond or an alkylene group having 1 to 20 carbon atoms, an arylene group having 6 to 18 carbon atoms, a heteroarylene group having 3 to 18 carbon atoms, —O—, —S—, —C(═O)—, or a group formed of a combination of these groups, L³'s each independently represent a single bond or an alkylene group having 1 to 20 carbon atoms, an arylene group having 6 to 18 carbon atoms, a heteroarylene group having 3 to 18 carbon atoms, —O—, —S—, —C(═O)—, or a group formed of a combination of these groups, and R⁵ is represented by a cyano group or a structure of General Formula (6) below;

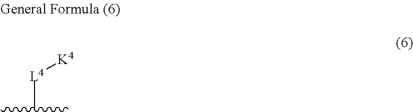

in General Formula (6), L⁴ represents a single bond or —O—, —C(═O)—, a sulfinyl group, an alkylene group having 1 to 10 carbon atoms, an arylene group having 6 to 18 carbon atoms, a nitrogen-containing heteroarylene group having 3 to 18 carbon atoms, or a group formed of a combination of these groups, and K⁴ represents a crosslinking group.

<12> The infrared sensor according to any one of <2> to <11>, in which a crosslinking group is at least one selected from a (meth)acryloyloxy group, an epoxy group, an oxetanyl group, an isocyanate group, a hydroxyl group, an amino group, a carboxyl group, a thiol group, an alkoxysilyl group, a methylol group, a vinyl group, a (meth)acrylamido group, a sulfo group, a styryl group, and a maleimido group.

<13> The infrared sensor according to any one of <2> to <11>, in which a crosslinking group is at least one selected from a (meth)acryloyloxy group, a vinyl group, an epoxy group, and an oxetanyl group.

<14> The infrared sensor according to any one of <2> to <11>, in which a crosslinking group is at least one selected from crosslinking groups represented by General Formulae (A-1) to (A-3) below;

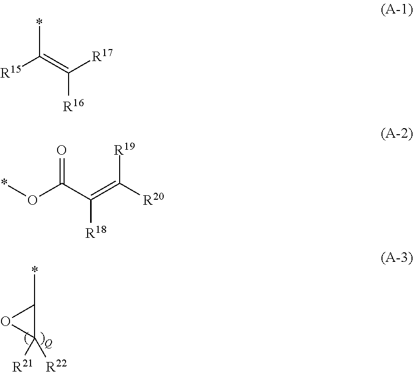

in Formula (A-1), R¹⁵, R¹⁶, and R¹⁷ each independently represent a hydrogen atom, an alkyl group having 1 to 18 carbon atoms, an alkenyl group having 1 to 18 carbon atoms, an alkynyl group having 1 to 18 carbon atoms, a cycloalkyl group having 3 to 18 carbon atoms, a cycloalkenyl group having 3 to 18 carbon atoms, a cycloalkynyl group having 3 to 18 carbon atoms, or an aryl group having 6 to 18 carbon atoms; in Formula (A-2), R¹⁸, R¹⁹, and R²⁰ each independently represent a hydrogen atom, a methyl group, a fluorine atom, or —CF₃; in Formula (A-3), R²¹ and R²² each independently represent a hydrogen atom, a methyl group, a fluorine atom, or —CF₃, and Q represents 1 or 2.

<15> The infrared sensor according to <14>, in which, in Formula (A-1), R¹⁶ and R¹⁷ represent hydrogen atoms, in Formula (A-2), R¹⁹ and R²⁰ represent hydrogen atoms, and, in Formula (A-3), R²¹ and R²² represent hydrogen atoms.

<16> A near-infrared absorbing composition which is used to form near-infrared absorbing layers in infrared sensors that detect objects by detecting light having wavelengths of 700 nm or longer and shorter than 900 nm, comprising a near-infrared absorbing substance having a maximum absorption wavelength at a wavelength of 700 nm or longer and shorter than 900 nm.

<17> The near-infrared absorbing composition according to <16>, in which the near-infrared absorbing substance is a compound represented by General Formula (1) below;

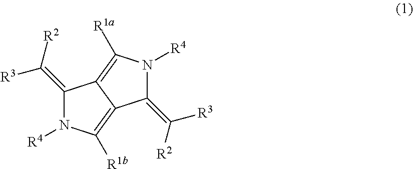

in General Formula (1), R^{1a} and R^{1b} each independently represent an alkyl group, an aryl group, or a heteroaryl group; R² and R³ each independently represent a hydrogen atom or a substituent, and R² and R³ may be bonded to each other and thus form a cyclic structure; R⁴'s each independently represent a hydrogen atom, an alkyl group, an aryl group, a heteroaryl group, (R^{4A})₂B—, (R^{4B})₂P—, (R^{4C})₃Si—, or (R^{4D})ₙM-; R^{4A} to R^{4D} each independently represent an atom or a group; n represents an integer of 2 to 4, and M represents an n+1-valent metal atom; in a case in which R⁴ represents (R^{4A})₂B—, (R^{4B})₂P—, (R^{4C})₃Si—, or (R^{4D})ₙM-, R⁴ may form a covalent bond or a coordinate bond with at least one selected from R^{1a}, R^{1b}, and R³; here, General Formula (1) satisfies at least one condition selected from at least one selected from R^{1a}, R^{1b}, and R⁴ having a crosslinking group and at least one selected from R² and R³ having crosslinking groups with a cyclic structure group therebetween, and, in a case in which the crosslinking group is an olefin group or a styryl group, the total number of the crosslinking groups is three or more.

<18> A near-infrared absorbing composition comprising: a compound represented by General Formula (1) below;

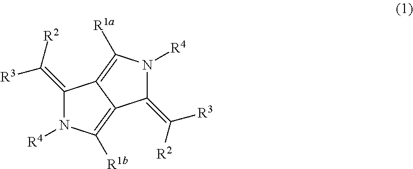

in General Formula (1), R^{1a} and R^{1b} each independently represent an alkyl group, an aryl group, or a heteroaryl group; R² and R³ each independently represent a hydrogen atom or a substituent, and R² and R³ may be bonded to each other and thus form a cyclic structure; R⁴'s each independently represent a hydrogen atom, an alkyl group, an aryl group, a heteroaryl group, (R^{4A})₂B—, (R^{4B})₂P—, (R^{4C})₃Si—, or (R^{4D})ₙM-; R^{4A} to R^{4D} each independently represent an atom or a group; n represents an integer of 2 to 4, and M represents an n+1-valent metal atom; in a case in which R⁴ represents (R^{4A})₂B—, (R^{4B})₂P—, (R^{4C})₃Si—, or (R^{4D})ₙM-, R⁴ may form a covalent bond or a coordinate bond with at least one selected from R^{1a}, R^{1b}, and R³; here, General Formula (1) satisfies at least one condition selected from at least one selected from R^{1a}, R^{1b}, and R⁴ having a crosslinking group and at least one selected from R² and R³ having a crosslinking group through a cyclic structure group, and, in a case in which the crosslinking group is an olefin group or a styryl group, the total number of the crosslinking groups is three or more.

<19> The near-infrared absorbing composition according to any one of <16> to <18>, further comprising: at least one selected from a curable compound, a polymerization initiator, a curing agent, and a solvent.

<20> The near-infrared absorbing composition according to any one of <16> to <19>, further comprising: a coloring agent different from the near-infrared absorbing substance or the compound represented by General Formula (1).

<21> A cured film formed using the near-infrared absorbing composition according to any one of <16> to <20>.

<22> A near-infrared absorbing filter formed using the near-infrared absorbing composition according to any one of <16> to <20>.

<23> An image sensor comprising: a photoelectric conversion element; and the near-infrared absorbing filter according to <22> on the photoelectric conversion element.

<24> A camera module comprising: a solid image pickup element; and the near-infrared absorbing filter according to <22>.

<25> A compound represented by General Formula (1) below:

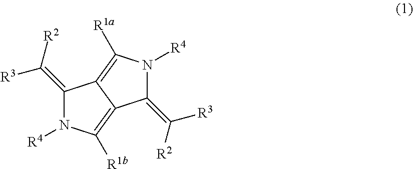

in General Formula (1), R^{1a} and R^{1b} each independently represent an alkyl group, an aryl group, or a heteroaryl group; R² and R³ each independently represent a hydrogen atom or a substituent, and R² and R³ may be bonded to each other and thus form a cyclic structure; R⁴'s each independently represent a hydrogen atom, an alkyl group, an aryl group, a heteroaryl group, (R^{4A})₂B—, (R^{4B})₂P—, (R^{4C})₃Si—, or (R^{4D})ₙM-; R^{4A} to R^{4D} each independently represent an atom or a group; n represents an integer of 2 to 4, and M represents an n+1-valent metal atom; in a case in which R⁴ represents (R^{4A})₂B—, (R^{4B})₂P—, (R^{4C})₃Si—, or (R^{4D})ₙM-, R⁴ may form a covalent bond or a coordinate bond with at least one selected from R^{1a}, R^{1b}, and R³; here, General Formula (1) satisfies at least one condition selected from at least one selected from R^{1a}, R^{1b}, and R⁴ having a crosslinking group and at least one selected from R² and R³ having crosslinking groups with a cyclic structure group therebetween, and, in a case in which the crosslinking group is an olefin group or a styryl group, the total number of the crosslinking groups is three or more.

<26> The compound according to <25>, in which, in General Formula (1), one of R² and R³ is a cyano group, and the other is a group having a heterocyclic ring.

<27> The compound according to <25> or <26>, in which a crosslinking group is at least one selected from a (meth)acryloyloxy group, an epoxy group, an oxetanyl group, an isocyanate group, a hydroxyl group, an amino group, a carboxyl group, a thiol group, an alkoxysilyl group, a methylol group, a vinyl group, a (meth)acrylamido group, a sulfo group, a styryl group, and a maleimido group, and, in a case in which the crosslinking group is a vinyl group or a styryl group, the total number of the crosslinking groups is three or more.

According to the present invention, it become possible to provide an infrared sensor that is excellent in terms of detectability and image quality. In addition, it become possible to provide a near-infrared absorbing composition, a cured film, a near-infrared absorbing filter, an image sensor, a camera module, and a compound.

In addition, according to the near-infrared absorbing composition of the present invention, since the coloring agent has a crosslinking group, it is possible to provide a cured film that is excellent in terms of solvent resistance and photolithographic properties.

### BRIEF DESCRIPTION OF THE DRAWINGS

FIG. 1 is a schematic sectional view illustrating a constitution of a first embodiment of an infrared sensor of the present invention.

FIG. 2 is a function block diagram of an imaging device to which the infrared sensor of the present invention is applied.

FIG. 3 is a view illustrating spectroscopic characteristics of a compound (A-1) in a chloroform solution.

FIG. 4 is a view illustrating spectroscopic characteristics of a compound (A-2) in a chloroform solution.

FIG. 5 is a view illustrating spectroscopic characteristics of a cured film for which a near-infrared absorbing composition of Example 1 is used.

FIG. 6 is a view illustrating spectroscopic characteristics of a cured film for which a near-infrared absorbing composition of Example 2 is used.

### DESCRIPTION OF THE PREFERRED EMBODIMENTS

Hereinafter, the contents of the present invention will be described in detail.

In the present specification, “to” used to express numerical ranges will be used with a meaning that numerical values before and after the “to” are included in the numerical ranges as the lower limit value and the upper limit value.

Regarding the denoting of groups (atomic groups) in the present specification, groups not denoted with ‘substituted’ or ‘unsubstituted’ refer to both groups (atomic groups) having no substituents and groups (atomic groups) having a substituent. For example, “alkyl groups” refer not only to alkyl groups having no substituents (unsubstituted alkyl groups) but also to alkyl groups having a substituent (substituted alkyl groups).

In the present specification, “(meth)acrylates” represent acrylates and methacrylates, “(meth)acrylic” represents acrylic and methacrylic, and “(meth)acryloyl” represents acryloyl and methacryloyl.

In addition, in the present specification, “monomers” and “monomers” refer to the same thing. Monomers are differentiated from oligomers and polymers and refer to compounds having a weight-average molecular weight of 2,000 or less.

In the present specification, polymerizable compounds refer to compounds having a polymerizable functional group and may be monomers or polymers. The polymerizable functional group refers to a group that participates in polymerization reactions.

The weight-average molecular weights and the number-average molecular weights of compounds that are used in the present invention can be measured by means of gel permeation chromatography (GPC) and are defied as polystyrene-equivalent values obtained by GPC measurement. For example, the weight-average molecular weights and the number-average molecular weights of compounds can be obtained using HLC-8220 (manufactured by Tosho Corporation), a 6.0 mmID×15.0 cm TSKgel Super AWM-H (manufactured by Tosho Corporation) as a column, and 10 mmol/L of a lithium bromide N-methyl pyrrolidinone (NMP) solution as an eluent.

Near-infrared rays refer to rays (electromagnetic waves) having a maximum absorption wavelength in a range of 700 to 2,500 nm.

In the present specification, the total solid content refers to the total mass of all the components of a composition excluding a solvent. Solid contents in the present invention refer to solid contents at 25° C.

<Near-Infrared Absorbing Composition>

A near-infrared absorbing composition of the present invention (hereinafter, also referred to as the composition of the present invention) includes a compound represented by General Formula (1) below.

<<Compound Represented by General Formula (1)>>

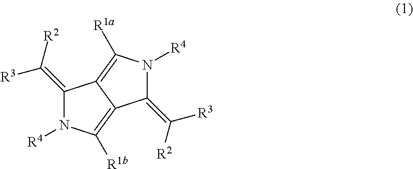

In General Formula (1), R^{1a} and R^{1b} each independently represent an alkyl group, an aryl group, or a heteroaryl group; R² and R³ each independently represent a hydrogen atom or a substituent, and R² and R³ may be bonded to each other and thus form a cyclic structure; R⁴'s each independently represent a hydrogen atom, an alkyl group, an aryl group, a heteroaryl group, (R^{4A})₂B—, (R^{4B})₂P—, (R^{4C})₃Si—, or (R^{4D})ₙM-; R^{4A} to R^{4D} each independently represent an atom or a group; n represents an integer of 2 to 4, and M represents an n+1-valent metal atom; in a case in which R⁴ represents (R^{4A})₂B—, (R^{4B})²P—, (R^{4C})₃Si—, or (R^{4D})ₙM-, R⁴ may form a covalent bond or a coordinate bond with at least one selected from R^{1a}, R^{1b}, and R³; here, at least one selected from R^{1a}, R^{1b}, and R⁴ has a crosslinking group and/or R² and/or R³ have crosslinking groups with a cyclic structure group therebetween.

In General Formula (1), R^{1a} and R^{1b} each independently represent an alkyl group, an aryl group, or a heteroaryl group.

The number of carbon atoms in an alkyl group represented by R^{1a} or R^{1b} is preferably in a range of 1 to 30, more preferably in a range of 1 to 20, and still more preferably in a range of 1 to 10. The alkyl group may have any of a linear shape, a branched shape, and a cyclic shape.

The number of carbon atoms in an aryl group represented by R^{1a} or R^{1b} is preferably in a range of 6 to 30, more preferably in a range of 6 to 20, and still more preferably in a range of 6 to 12.

The number of carbon atoms in a heteroaryl group represented by R^{1a} or R^{1b} is preferably in a range of 1 to 30 and more preferably in a range of 1 to 12. Examples of a heteroatom constituting the heteroaryl group include a nitrogen atom, an oxygen atom, a sulfur atom, and the like.

R^{1a} and R^{1b} may have a substituent, examples of the substituent include a substituent group T described below, and an alkoxy group having 1 to 30 carbon atoms is preferred. In a case in which R^{1a} and R^{1b} have a substituent, R^{1a} and R^{1b} may have another substituent, examples of the substituent include a substituent group T described below, and an alkyl group having 1 to 30 carbon atoms is preferred.

Particularly, the group represented by R^{1a} or R^{1b} is preferably an aryl group having an alkoxy group having a branched alkyl group. An alkyl group in the branched alkyl group preferably has 3 to 30 carbon atoms and more preferably has 3 to 20 carbon atoms. For example, the group represented by R^{1a} or R^{1b} is preferably 4-(2-ethylhexyloxy)phenyl, 4-(2-methylbutyloxy)phenyl, 4-(2-octyldodecyloxy)phenyl, or the like.
R^{1a} and R^{1b} in General Formula (1) may be identical to or different from each other.

(Substituent Group T)

Examples of the substituent group T include the following substituents. The following substituents may be further substituted.

Alkyl groups (preferably having 1 to 30 carbon atoms, more preferably having 1 to 20 carbon atoms, and particularly preferably having 1 to 10 carbon atoms; examples thereof include methyl, ethyl, iso-propyl, tert-butyl, n-octyl, n-decyl, n-hexadecyl, 2-methylbutyl, 2-ethyl cyclohexyl, cyclopentyl, cyclohexyl, and the like.)

Alkenyl groups (preferably having 2 to 30 carbon atoms, more preferably having 2 to 20 carbon atoms, and particularly preferably having 2 to 10 carbon atoms; examples thereof include vinyl, allyl, 2-butenyl, 3-pentenyl, and the like.)

Alkynyl groups (preferably having 2 to 30 carbon atoms, more preferably having 2 to 20 carbon atoms, and particularly preferably having 2 to 10 carbon atoms; examples thereof include propargyl, 3-pentynyl, and the like.)

Aryl groups (preferably having 6 to 30 carbon atoms, more preferably having 6 to 20 carbon atoms, and particularly preferably having 6 to 12 carbon atoms; examples thereof include phenyl, p-methylphenyl, biphenyl, naphthyl, anthranyl, phenanthryl, and the like.)

Amino groups (preferably having 0 to 30 carbon atoms, more preferably having 0 to 20 carbon atoms, and particularly preferably having 0 to 10 carbon atoms and including an alkylamino group and a heterocyclic amino group; examples thereof include amino, methylamino, dimethylamino, diethylamino, dibenzylamino, diphenylamino, and ditolylamino.)

Alkoxy groups (preferably having 1 to 30 carbon atoms, more preferably having 1 to 20 carbon atoms, and particularly preferably having 1 to 10 carbon atoms; examples thereof include methoxy, ethoxy, butoxy, 2-ethylhexyloxy, and the like.)

Aryloxy groups (preferably having 6 to 30 carbon atoms, more preferably having 6 to 20 carbon atoms, and particularly preferably having 6 to 12 carbon atoms; examples thereof include phenyloxy, 1-naphthyloxy, 2-naphthyloxy, and the like.)

Aromatic heterocyclic oxy groups (preferably having 1 to 30 carbon atoms, more preferably having 1 to 20 carbon atoms, and particularly preferably having 1 to 12 carbon atoms; examples thereof include pyridyloxy, pyrazyloxy, pyrimidyloxy, quinolyloxy, and the like.)

Acyl groups (preferably having 2 to 30 carbon atoms, more preferably having 2 to 20 carbon atoms, and particularly preferably having 2 to 12 carbon atoms; examples thereof include acetyl, benzoyl, formyl, pivaloyl, and the like.)

Alkoxycarbonyl groups (preferably having 2 to 30 carbon atoms, more preferably having 2 to 20 carbon atoms, and particularly preferably having 2 to 12 carbon atoms; examples thereof include methoxycarbonyl, ethoxycarbonyl, and the like.)

Aryloxycarbonyl groups (preferably having 7 to 30 carbon atoms, more preferably having 7 to 20 carbon atoms, and particularly preferably having 7 to 12 carbon atoms; examples thereof include phenyloxycarbonyl and the like.)

Acyloxy groups (preferably having 2 to 30 carbon atoms, more preferably having 2 to 20 carbon atoms, and particularly preferably having 2 to 10 carbon atoms; examples thereof include acetoxy, benzoyloxy, and the like.)

Acylamino groups (preferably having 2 to 30 carbon atoms, more preferably having 2 to 20 carbon atoms, and particularly preferably having 2 to 10 carbon atoms; examples thereof include acetylamino, benzoylamino, and the like.)

Alkoxycarbonylamino groups (preferably having 2 to 30 carbon atoms, more preferably having 2 to 20 carbon atoms, and particularly preferably having 2 to 12 carbon atoms; examples thereof include methoxycarbonylamino and the like.)

Aryloxycarbonylamino groups (preferably having 7 to 30 carbon atoms, more preferably having 7 to 20 carbon atoms, and particularly preferably having 7 to 12 carbon atoms; examples thereof include phenyloxycarbonylamino and the like.)

Sulfonylamino groups (preferably having 1 to 30 carbon atoms, more preferably having 1 to 20 carbon atoms, and particularly preferably having 1 to 12 carbon atoms; examples thereof include methanesulfonylamino, benzenesulfonylamino, and the like.)

Sulfamoyl groups (preferably having 0 to 30 carbon atoms, more preferably having 0 to 20 carbon atoms, and particularly preferably having 0 to 12 carbon atoms; examples thereof include sulfamoyl, methylsulfamoyl, dimethylsulfamoyl, phenylsulfamoyl, and the like.)

Carbamoyl groups (examples thereof include carbamoyl, methylcarbamoyl, diethylcarbamoyl, phenylcarbamoyl, and the like.)

Alkylthio groups (preferably having 1 to 30 carbon atoms, more preferably having 1 to 20 carbon atoms, and particularly preferably having 1 to 12 carbon atoms; examples thereof include methylthio, ethylthio, and the like.)

Arylthio groups (preferably having 6 to 30 carbon atoms, more preferably having 6 to 20 carbon atoms, and particularly preferably having 6 to 12 carbon atoms; examples thereof include phenylthio and the like.)

Aromatic heterocyclic thio groups (preferably 1 to 30 carbon atoms, more preferably 1 to 20 carbon atoms, and particularly preferably 1 to 12 carbon atoms; examples thereof include pyridylthio, 2-benzimizolylthio, 2-benzoxazolylthio, 2-benzothiazolylthio, and the like.)

Sulfonyl groups (preferably having 1 to 30 carbon atoms, more preferably having 1 to 20 carbon atoms, and particularly preferably having 1 to 12 carbon atoms; examples thereof include mesyl, tosyl, and the like.)

Sulfinyl groups (preferably having 1 to 30 carbon atoms, more preferably having 1 to 20 carbon atoms, and particularly preferably having 1 to 12 carbon atoms; examples thereof include methanesulfinyl, benzenesulfinyl, and the like.)

Ureido groups (preferably having 1 to 30 carbon atoms, more preferably having 1 to 20 carbon atoms, and particularly preferably having 1 to 12 carbon atoms; examples thereof include ureido, methylureido, phenylureido, and the like.)

Phosphoric amido groups (preferably having 1 to 30 carbon atoms, more preferably having 1 to 20 carbon atoms, and particularly preferably having 1 to 12 carbon atoms; examples thereof include diethylphosphoric amide, phenylphosphoric acid amide, and the like.)

Hydroxyl groups

Mercapto groups

Halogen atoms (for example, a fluorine atom, a chlorine atom, a bromine atom, and an iodine atom)

Cyano groups

Sulfo groups

Carboxyl groups

Nitro groups

Hydroxamic groups

Sulfino groups

Hydrazino groups

Imino groups

Heterocyclic groups (preferably having 1 to 30 carbon atoms and more preferably having 1 to 12 carbon atoms; examples of hetero atoms include a nitrogen atom, an oxygen atom, and a sulfur atom, and specific examples thereof include imidazolyl, pyridyl, quinolyl, furyl, thienyl, piperidyl, morpholino, benzoxazolyl, benzimidazolyl, benzothiazolyl, carbazolyl, azepinyl group, and the like.)

Silyl groups (preferably having 3 to 40 carbon atoms, more preferably having 3 to 30 carbon atoms, and particularly preferably having 3 to 24 carbon atoms; examples thereof include trimethylsilyl, triphenylsilyl, and the like.)

In General Formula (1), R² and R³ each independently represent a hydrogen atom or a substituent, and at least one of R² and R³ is preferably an electron-withdrawing group.

Examples of the electron-withdrawing group include a cyano group, an acyl group, an alkyloxycarbonyl group, an aryloxycarbonyl group, a sulfamoyl group, a sulfinyl group, a heterocyclic group, and the like. These electron-withdrawing groups may be substituted, and examples of the substituent include substituents in the above-described substituent group T.

As the electron-withdrawing group, substituents having a Hammett substituent constant σp value of 0.2 or greater can be exemplified. The σp value is preferably 0.25 or greater, more preferably 0.3 or greater, and particularly preferably 0.35 or greater. The upper limit is not particularly limited, but is preferably 0.80.

Specific examples thereof include a cyano group (0.66), a carboxyl group (—COOH: 0.45), an alkoxycarbonyl group (—COOMe: 0.45), an aryloxycarbonyl group (—COOPh: 0.44), a carbamoyl group (—CONH₂: 0.36), an alkylcarbonyl group (—COMe: 0.50), an arylcarbonyl group (—COPh: 0.43), an alkylsulfonyl group (—SO₂Me: 0.72), an arylsulfonyl group (—SO₂Ph: 0.68), and the like. The electron-withdrawing group is particularly preferably a cyano group. Here, Me represents a methyl group, and Ph represents a phenyl group.

Regarding the Hammett substituent constant σp value, it is possible to refer to, for example, Paragraphs “0017” and “0018” of JP2011-68731A, the content of which is incorporated into the present specification.

In General Formula (1), in a case in which R² and R³ bond to each other and thus form a ring, a 5- to 7-membered ring (preferably 5- or 6-membered ring) is preferably formed. As the ring being formed, rings that are generally used as acidic nuclei in merocyanine coloring agents (cyclic acidic nuclei) are preferred, and specific examples thereof include (a) 1,3-dicarbonyl nuclei, (b) pyrazolinone nuclei, (c) isoxazolinone nuclei, (d) oxyindole nuclei, (e) 2,4,6-triketohexahydropyrimidine nuclei, (f) 2-thio-2,4-thiazolidinedione nuclei, (g) 2-thio-2,4-oxazolidinedione (2-thio-2,4-(3H,5H)-oxazoledione) nuclei, (h) thianaphthenone nuclei, (i) 2-thio-2,5-thiazolidinedione nuclei, (j) 2,4-thiazolidinedione nuclei, (k) thiazolin-4-one nuclei, (l) 4-thiazolidinone nuclei, (m) 2,4-imidazolidinedione (hydantoin) nuclei, (n) 2-thio-2,4-imidazolidinedione (2-thiohydantoin) nuclei, (o) imidazolin-5-one nuclei, (p) 3,5-pyrazolidinedione nuclei, (q) benzothiophen-3-one nuclei, (r) indanone nuclei, and the like. In addition, regarding the detail of the cyclic acidic nuclei, it is possible to refer to Paragraph “0019” of JP2011-68731A, the content of which is incorporated into the present specification.

In General Formula (1), R³ is preferably a heterocycle. Examples of the heterocycle include a pyrazole ring, a thiazole ring, an oxazole ring, an imidazole ring, an oxadiazole ring, a thiadiazole ring, a triazole ring, a pyridine ring, a pyridazine ring, a pyrimidine ring, a pyrazine ring; benzo-fused rings or naphtho-fused rings thereof, composites of these fused rings, and the like.

The two R²'s in General Formula (1) may be identical to or different from each other, and the two R³'s may be identical to or different from each other.

In General Formula (1), R⁴ represents a hydrogen atom, an alkyl group, an aryl group, a heteroaryl group, (R^{4A})₂B—, (R^{4B})₂P—, (R^{4C})³Si—, or (R^{4D})ₙM-, and preferably represents (R^{4A})₂B—.

In a case in which groups represented by R⁴ are alkyl groups, aryl groups, or heteroaryl groups, the alkyl groups, the aryl groups, or the heteroaryl groups are identical to the alkyl groups, the aryl groups, or the heteroaryl groups described in the section of R^{1a} and R^{1b} in General Formula (1), and preferred ranges thereof are also identical.

In a case in which groups represented by R⁴ are (R^{4A})₂B—'s, R^{4A}'s each independently represent an atom or a group. The atom represented by R^{4A} is preferably a halogen atom. The groups represented by R^{4A} are preferably alkyl groups, alkoxy groups, aryl groups, or heteroaryl groups and more preferably aryl groups. The alkyl groups, the aryl groups, and the heteroaryl groups are identical to R^{1a} and R^{1b} in General Formula (1). In a case in which R^{4A} represents a group, the group may have a substituent, and examples of the substituent include substituents in the above-described substituent group T. The two R^{4A}'s may be identical to or different from each other and may be bonded to each other and thus form a ring.

In a case in which groups represented by R⁴ are (R^{4B})₂P—'s, R^{4B}'s each independently represent an atom or a group, is identical to R^{4A}, and is preferably an aryl group. In a case in which R^{4B} represents a group, the group may have a substituent, and examples of the substituent include substituents in the above-described substituent group T. The two R^{4B}'s may be identical to or different from each other and may be bonded to each other and thus form a ring.

In a case in which groups represented by R⁴ are (R^{4C})₃Si—'s, R^{4C}'s each independently represent an atom or a group, is identical to R^{4A}, and is preferably an alkyl group. In a case in which R^{4C} represents a group, the group may have a substituent, and examples of the substituent include substituents in the above-described substituent group T. The three R^{4C}'s may be identical to or different from each other and may be bonded to each other and thus form a ring.

In a case in which groups represented by R⁴ are (R^{4D})ₙM—'s, R^{4D}'s each independently represent an atom or a group, is identical to R^{4A}, and is preferably a halogen atom or an alkyl group. n represents an integer of 2 to 4 and is preferably 2. M represents an n+1-valent metallic atom, and examples thereof include transition metals (for example, a copper atom, a zinc atom, and the like).

In a case in which R⁴ represents (R^{4A})₂B—, (R^{4B})²P—, (R^{4C})₃Si—, or (R^{4D})ₙM-, R⁴ may form a covalent bond with at least one selected from R^{1a}, R^{1b}, and R³. In addition, R⁴ may form a coordinate bond with at least one selected from R^{1a}, R^{1b}, and R³.

In General Formula (1), it is preferable that at least one selected from R^{1a}, R^{1b}, and R⁴ has a crosslinking group or R² and/or R³ have crosslinking groups with a cyclic structure group therebetween. When the above-described constitution is formed, for example, the crosslinking group bonds to a curable compound, and it becomes easy for the compound represented by General Formula (1) to be fixed in cured films, and thus solvent resistance can be improved. In addition, when the compound represented by General Formula (1) has a crosslinking group, it is possible to provide cured films that are also excellent in terms of photolithographic properties.

Here, the crosslinking group in the compound represented by General Formula (1) refers to a group that generates covalent bonds through chemical reactions. The crosslinking group may be present in at least one terminal selected from R^{1a}, R^{1b}, R², R³, and R⁴ in General Formula (1) or may be present in a location other than terminals.

In a case in which at least one selected from R^{1a} and R^{1b} in General Formula (1) has a crosslinking group, the groups preferably have crosslinking groups with a cyclic structure group having aromaticity therebetween. The cyclic structure group having aromaticity may be an aromatic hydrocarbon group or an aromatic heterocyclic group. In a case in which the cyclic structure group having aromaticity is an aromatic hydrocarbon group, the number of carbon atoms is preferably in a range of 6 to 30, more preferably in a range of 6 to 20, and still more preferably in a range of 6 to 12. In a case in which the cyclic structure group having aromaticity is an aromatic heterocyclic group, the number of carbon atoms in the aromatic heterocyclic group is preferably in a range of 1 to 30 and more preferably in a range of 1 to 12. Examples of heteroatoms constituting the aromatic heterocyclic group include a nitrogen atom, an oxygen atom, a sulfur atom, and the like. The aromatic heterocycle is preferably a 3- to 8-membered ring.

In a case in which R² or R³ in General Formula (1) has a crosslinking group, the group preferably has crosslinking groups with a cyclic structure group having aromaticity therebetween. The cyclic structure group having aromaticity is identical to that described in the section of R^{1a} and R^{1b} in General Formula (1).

In a case in which R⁴ in General Formula (1) has a crosslinking group, the group preferably has crosslinking groups with a cyclic structure group having aromaticity therebetween. The cyclic structure group may or may not have aromaticity. The cyclic structure group may be a heterocycle. The cyclic structure group may be a monocycle or a polycycle but is preferably a monocycle. The cyclic structure group is preferably a 3- to 8-membered ring.

The crosslinking group in the compound represented by General Formula (1) is not particularly limited, but is preferably one or more selected from a (meth)acryloyloxy group, an epoxy group, an oxetanyl group, an isocyanate group, a hydroxyl group, an amino group, a carboxyl group, a thiol group, an alkoxysilyl group, a methylol group, a vinyl group, a (meth)acrylamido group, a sulfo group, a styryl group, and a maleimido group and more preferably one or more selected from a (meth)acryloyloxy group, a vinyl group, an epoxy group, and an oxetanyl group. The crosslinking groups in the compound represented by General Formula (1) may belong to the same kind or different kinds.

In addition, as the crosslinking group, at least one of crosslinking groups represented by General Formulae (A-1) to (A-3) is also preferred.

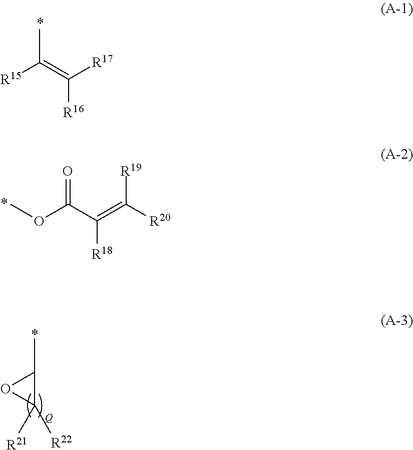

In Formula (A-1), R¹⁵, R¹⁶, and R¹⁷ each independently represent a hydrogen atom, an alkyl group having 1 to 18 carbon atoms, an alkenyl group having 1 to 18 carbon atoms, an alkynyl group having 1 to 18 carbon atoms, a cycloalkyl group having 3 to 18 carbon atoms, a cycloalkenyl group having 3 to 18 carbon atoms, a cycloalkynyl group having 3 to 18 carbon atoms, or an aryl group having 6 to 18 carbon atoms.

The number of carbon atoms in the alkyl group having 1 to 18 carbon atoms is preferably in a range of 1 to 10, more preferably in a range of 1 to 6, still more preferably in a range of 1 to 3, and particularly preferably 1.

The number of carbon atoms in the alkenyl group having 1 to 18 carbon atoms is preferably in a range of 1 to 10, more preferably in a range of 1 to 6, and still more preferably in a range of 1 to 3.

The number of carbon atoms in the alkynyl group having 1 to 18 carbon atoms is preferably in a range of 1 to 10, more preferably in a range of 1 to 6, and still more preferably in a range of 1 to 3.

The number of carbon atoms in the cycloalkyl group having 3 to 18 carbon atoms is preferably in a range of 3 to 10, more preferably in a range of 3 to 8, and still more preferably in a range of 3 to 6.

The number of carbon atoms in the cycloalkenyl group having 3 to 18 carbon atoms is preferably in a range of 3 to 10, more preferably in a range of 3 to 8, and still more preferably in a range of 3 to 6.

The number of carbon atoms in the cycloalkynyl group having 3 to 18 carbon atoms is preferably in a range of 3 to 10, more preferably in a range of 3 to 8, and still more preferably in a range of 3 to 6.

The number of carbon atoms in the aryl group having 6 to 18 carbon atoms is preferably in a range of 6 to 12, more preferably in a range of 6 to 8, and still more preferably 6.

In Formula (A-1), R¹⁵ is preferably a hydrogen atom or an alkyl group having 1 to 18 carbon atoms and more preferably a hydrogen atom. In Formula (A-1), R¹⁶ and R¹⁷ each are independently a hydrogen atom or an alkyl group having 1 to 18 carbon atoms and a hydrogen atom.

In Formula (A-2), R¹⁸, R¹⁹, and R²⁰ each independently represent a hydrogen atom, a methyl group, a fluorine atom, or —CF₃. In Formula (A-2), R¹⁸ is preferably a methyl group. In Formula (A-2), R¹⁹ and R²⁰ are preferably hydrogen atoms.

In Formula (A-3), R²¹ and R²² each independently represent a hydrogen atom, a methyl group, a fluorine atom, or —CF₃ and is preferably a hydrogen atom. In Formula (A-3), Q represents 1 or 2.

The compound represented by General Formula (1) preferably has two or more crosslinking groups in a molecule. In addition, in a case in which the crosslinking group is an olefin group (for example, a vinyl group) or a styryl group, the compounds represented by General Formula (1) preferably has three or more crosslinking groups in a molecule. When the above-described constitution is formed, solvent resistance can be further improved.

For example, in a case in which the crosslinking group is a vinyl group or a styryl group, the total number of the crosslinking groups in a molecule of the compound represented by General Formula (1) is preferably three or more and more preferably four or more. In a case in which the crosslinking group is neither a vinyl group nor a styryl group, the total number of the crosslinking groups in a molecule of the compound represented by General Formula (1) is one or more, preferably two or more, and more preferably three or more. The upper limit of the total number of the crosslinking groups is not particularly limited, but is preferably ten or less.

The compound represented by General Formula (1) is also preferably a compound represented by General Formulae (2) to (4) below.

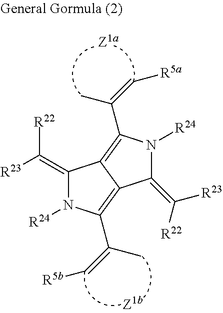

In General Formula (2), Z^{1a} and Z^{1b} each independently represent an atomic group forming an aryl ring or a heteroaryl ring; R^{5a} and R^{5b} each independently represent any one of an aryl group having 6 to 20 carbon atoms, a heteroaryl group having 4 to 20 carbon atoms, an alkyl group having 1 to 20 carbon atoms, an alkoxy group having 1 to 20 carbon atoms, an alkoxycarbonyl group having 2 to 20 carbon atoms, a carboxyl group, a carbamoyl group, a halogen atom, or a cyano group; R^{5a} or R^{5b} and Z^{1a} or Z^{1b} may be bonded to each other and thus form a fused ring; R²² and R²³ each independently represent a cyano group, an acyl group having 2 to 6 carbon atoms, an alkoxycarbonyl group having 2 to 6 carbon atoms, an alkyl group having 1 to 10 carbon atoms, an arylsulfinyl group having 6 to 10 carbon atoms, or a nitrogen-containing heteroaryl group having 3 to 20 carbon atoms, or R²² and R²³ may be bonded to each other and thus represent a cyclic acidic nucleus; R²⁴ represents a hydrogen atom, an alkyl group having 1 to 20 carbon atoms, an aryl group having 6 to 20 carbon atoms, a heteroaryl group having 3 to 20 carbon atoms, (R^{4A})₂B—, (R^{4B})²P—, (R^{4C})₃Si—, or (R^{4D})ₙM-; R^{4A} to R^{4D} each independently represent an atom or a group; n represents an integer of 2 to 4, and M represents an n+1-valent metal atom; in a case in which R²⁴ represents (R^{4A})₂B—, (R^{4B})₂P—, (R^{4C})₃Si—, or (R^{4D})ₙM-, R²⁴ may form a covalent bond or a coordinate bond with at least one selected from R^{5a} and R²² to R²⁴; at least one selected from R^{5a}, R^{5b}, and R²⁴ has a crosslinking group and/or R²² and/or R²³ have crosslinking groups with a nitrogen-containing heteroaryl group having 3 to 20 carbon atoms therebetween.

In General Formula (2), the aryl ring and the heteroaryl ring formed of Z^{1a} and Z^{1b} are identical to the aryl ring and the heteroaryl ring described as the substituents of R² and R³ in General Formula (1), and preferred ranges thereof are also identical. Z^{1a} and Z^{1b} are preferably identical to each other.

In General Formula (2), R^{5a} and R^{5b} are preferably identical to each other. R^{5a} or R^{5b} and Z^{1a} or Z^{1b} may be bonded to each other and thus form a fused ring, and examples of the fused ring include a naphthyl ring, a quinoline ring, and the like.

In a case in which R²² and R²³ bond to each other and thus represent a cyclic acidic nucleus, the cyclic acidic nucleus is identical to the above-described cyclic acidic nucleus.

R²⁴ is identical to R⁴ in General Formula (1), and a preferred range thereof is also identical.

The compound represented by General Formula (2) may further have a substituent, the substituent is identical to the above-described substituent group T, and a preferred range thereof is also identical.

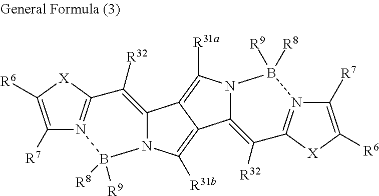

In General Formula (3), R^{31a} and R^{31b} each independently represent an alkyl group having 1 to 20 carbon atoms, an aryl group having 6 to 20 carbon atoms, or a heteroaryl group having 3 to 20 carbon atoms; R³² represents a cyano group, an acyl group having 2 to 6 carbon atoms, an alkoxycarbonyl group having 2 to 6 carbon atoms, an alkyl group having 1 to 10 carbon atoms, an arylsulfinyl group having 6 to 10 carbon atoms, or a nitrogen-containing heteroaryl group having 3 to 10 carbon atoms; R⁶ and R⁷ each independently represent a hydrogen atom, an alkyl group having 1 to 10 carbon atoms, an aryl group having 6 to 10 carbon atoms, or a heteroaryl group having 3 to 10 carbon atoms, R⁶ and R⁷ may be bonded to each other and thus form a ring, the ring being formed being an alicycle having 5 to 10 carbon atoms, an aryl ring having 6 to 10 carbon atoms, or a heteroaryl ring having 3 to 10 carbon atoms; R⁸ and R⁹ each independently represent an alkyl group having 1 to 10 carbon atoms, an alkoxy group having 1 to 10 carbon atoms, an aryl group having 6 to 20 carbon atoms, or a heteroaryl group having 3 to 10 carbon atoms; X represents an oxygen atom, a sulfur atom, —NR—, —CRR′—, or —CH═CH—, and R and R′ each independently represent a hydrogen atom, an alkyl group having 1 to 10 carbon atoms, or an aryl group having 6 to 10 carbon atoms; at least one selected from R⁶ to R⁹, R^{31a}, R^{31b}, and R³² has a crosslinking group.

In General Formula (3), R^{31a} and R^{31b} are identical to the examples described in the section of R^{1a} and R^{1b} in General Formula (1), and preferred examples thereof are also identical. R^{31a} and R^{31b} are preferably identical to each other.

In General Formula (3), R³² is identical to the example of R² in General Formula (1), and a preferred example thereof is also identical.

In General Formula (3), R⁶ and R⁷ are identical to the examples of the substituents of R² and R³ in General Formula (1), and preferred examples thereof are also identical. In addition, in a case in which R⁶ and R⁷ bond to each other and thus form a ring, preferred examples of the ring include a benzene ring, a naphthalene ring, a pyridine ring, and the like.

In General Formula (3), R⁸ and R⁹ are identical to the examples of the substituents of R² and R³ in General Formula (1), and preferred examples thereof are also identical.

X represents an oxygen atom, a sulfur atom, —NR—, —CRR′—, or —CH═CH—. Here, R and R′ each independently represent a hydrogen atom, an alkyl group having 1 to 10 carbon atoms, or an aryl group having 6 to 10 carbon atoms and is preferably a hydrogen atom, an alkyl group or a phenyl group having 1 to 6 carbon atoms.

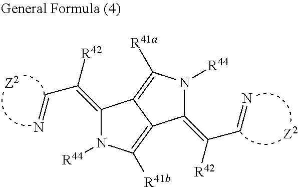

In General Formula (4), R^{41a} and R^{41b} represent mutually different groups and represent alkyl groups having 1 to 20 carbon atoms, aryl groups having 6 to 20 carbon atoms, or heteroaryl groups having 3 to 20 carbon atoms; R⁴² represents a cyano group, an acyl group having 1 to 6 carbon atoms, an alkoxycarbonyl group having 2 to 6 carbon atoms, an alkyl group having 1 to 10 carbon atoms, an arylsulfinyl group having 6 to 10 carbon atoms, or a nitrogen-containing heteroaryl group having 3 to 10 carbon atoms; Z²'s each independently represent an atomic group forming a nitrogen-containing 5-membered heteroring or nitrogen-containing 6-membered heteroring with —C═N—; R⁴⁴ represents a hydrogen atom, an alkyl group having 1 to 20 carbon atoms, an aryl group having 6 to 20 carbon atoms, a heteroaryl group having 4 to 20 carbon atoms, (R^{4A})₂B—, (R^{4B})²P—, (R^{4C})₃Si—, or (R4D)ₙM-; R^{4A} to R^{4D} each independently represent an atom or a group; n represents an integer of 2 to 4, and M represents an n+1-valent metal atom; in a case in which R⁴⁴ represents (R^{4A})₂B—, (R^{4B})₂P—, (R^{4C})₃Si—, or (R^{4D})ₙM-, R⁴ may form a covalent bond or a coordinate bond with a nitrogen-containing heterocycle formed by Z²; at least one selected from R^{41a}, R^{41b}, R⁴², and R⁴⁴ has a crosslinking group.

In General Formula (4), R^{41a} and R^{41b} are identical to the examples described in the section of R^{1a} and R^{1b} in General Formula (1), and preferred examples thereof are also identical. Here, R^{41a} and R^{41b} represent mutually different groups.

R⁴² is identical to the example of R² in General Formula (1), and a preferred example thereof is also identical.

Z² represents an atomic group forming a nitrogen-containing 5-membered heteroring or nitrogen-containing 6-membered heteroring with —C═N—, and examples of the nitrogen-containing heterocycle include a pyrazole ring, a thiazole ring, an oxazole ring, an imidazole ring, an oxadiazole ring, a thiadiazole ring, a triazole ring, a pyridine ring, a pyridazine ring, a pyrimidine ring, a pyrazine ring, benzo-fused rings or naphtho-fused rings thereof, and composites of these fused rings.

R⁴⁴ may have a covalent bond or a coordinate bond with the nitrogen-containing heterocycle formed by Z².

The compound represented by General Formula (1) is also preferably represented by General Formula (5) below.

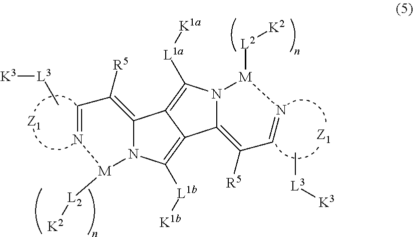

In General Formula (5), L¹, L^{1b}, L², and L³ each independently represent a single bond or a divalent linking group; R⁵'s each independently represent a hydrogen atom or a substituent. Z¹ represents an atomic group forming a nitrogen-containing 5-membered heteroring or nitrogen-containing 6-membered heteroring with —C═N—; K^{1a}, K^{1b}, K², and K³ each independently represent a hydrogen atom, a fluorine atom, or a crosslinking group, and at least one of them represents a crosslinking group; M represents a boron atom, a phosphorus atom, a silicon atom, or a metallic atom; n's each independently represent an integer of 1 to 3; the bond between M and N indicated by a broken line represents a coordinate bond.

In a case in which L^{1a} and L^{1b} each independently represent a divalent linking group, the groups preferably represent alkylene groups having 1 to 30 carbon atoms, arylene groups having 6 to 20 carbon atoms, heteroarylene groups having 3 to 20 carbon atoms, —O—, —S—, —C(═O)—, or groups formed of a combination of these groups. In addition, at least one selected from L^{1a} and L^{1b} also preferably includes a cyclic structure group having aromaticity, and the cyclic structure group having aromaticity is identical to the cyclic structure group having aromaticity in a case in which R^{1a} and R^{1b} in General Formula (1) have the crosslinking group.

In a case in which L² represents a divalent linking group, the group preferably represents an alkylene group having 1 to 20 carbon atoms, an arylene group having 6 to 18 carbon atoms, a heteroarylene group having 3 to 18 carbon atoms, —O—, —S—, —C(═O)—, or a group formed of a combination of these groups. In addition, L² also preferably includes an aromatic hydrocarbon group, and the aromatic hydrocarbon group is identical to the aromatic hydrocarbon group in a case in which R^{1a} and R^{1b} in General Formula (1) have the crosslinking group.

In a case in which L³ represents a divalent linking group, the group preferably represents an alkylene group having 1 to 20 carbon atoms, an arylene group having 6 to 18 carbon atoms, a heteroarylene group having 3 to 18 carbon atoms, —O—, —S—, —C(═O)—, or a group formed of a combination of these groups. In addition, L³ also preferably has a cyclic structure group having aromaticity, and the cyclic structure group having aromaticity is identical to the cyclic structure group having aromaticity in a case in which R² and R³ in General Formula (1) have the crosslinking group.

Z¹ represents an atomic group forming a nitrogen-containing 5-membered heteroring or nitrogen-containing 6-membered heteroring with —C═N— and is identical to Z² in General Formula (4), and a preferred range thereof is also identical.

In a case in which at least one selected from K^{1a}, K^{1b}, K², and K³ represents a crosslinking group, the crosslinking group is identical to the crosslinking group described in the section of General Formula (1), and a preferred range thereof is also identical.

In a case in which M represents a metallic atom, examples thereof include transition metals (for example, a copper atom, a zinc atom, and the like).

In a case in which R⁵ represents a substituent, examples of the substituent include the above-described substituent group T, and R⁵ is preferably represented by a cyano group or a structure of General Formula (6) below.

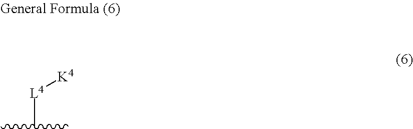

In General Formula (6), L⁴ represents a single bond or —O—, —C(═O)—, a sulfinyl group, an alkylene group having 1 to 10 carbon atoms, an arylene group having 6 to 18 carbon atoms, a nitrogen-containing heteroarylene group having 3 to 18 carbon atoms, or a group formed of a combination of these groups. The arylene group having 6 to 18 carbon atoms is preferably a phenylene group. K⁴ in General Formula (6) represents a crosslinking group and is identical to the crosslinking group described in the section of General Formula (1), and a preferred range thereof is also identical.

Hereinafter, exemplary compounds of near-infrared absorbing substances that can be used in the present invention will be illustrated, but the near-infrared absorbing substances are not limited thereto. Broken lines in the following compounds represent coordinate bonds.

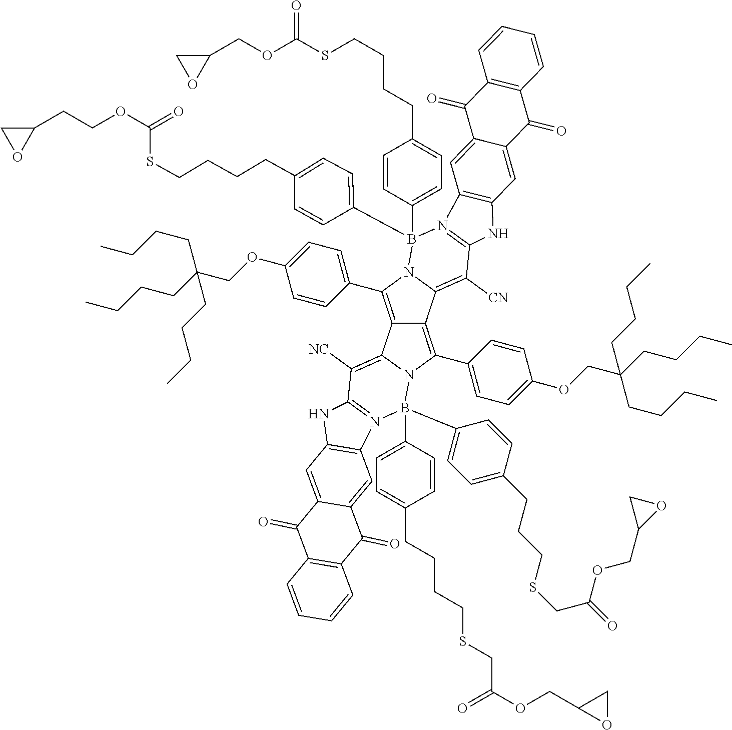

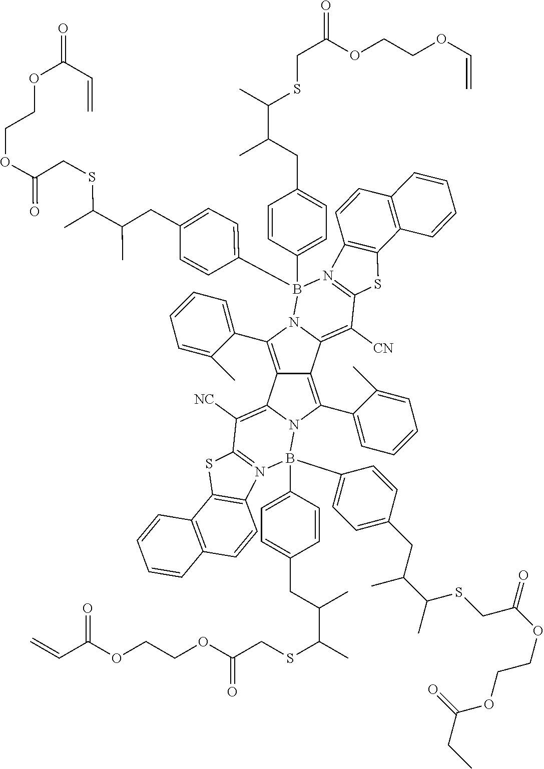

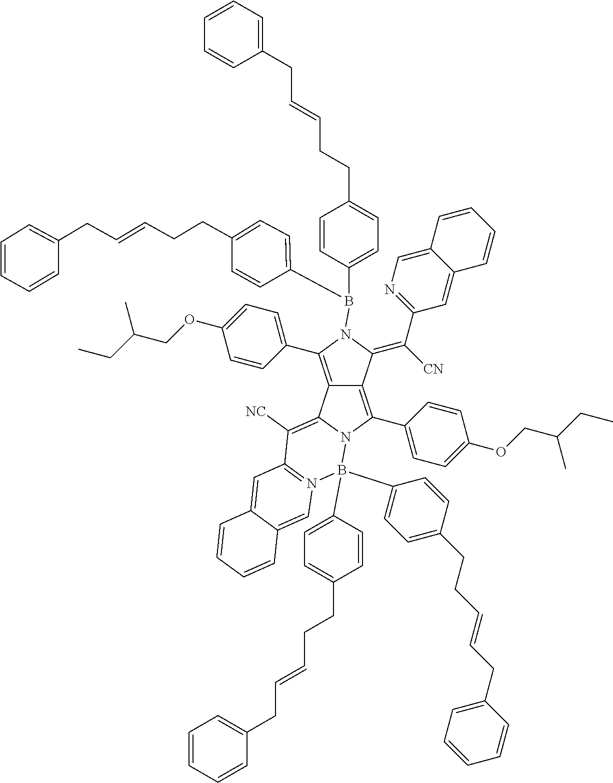

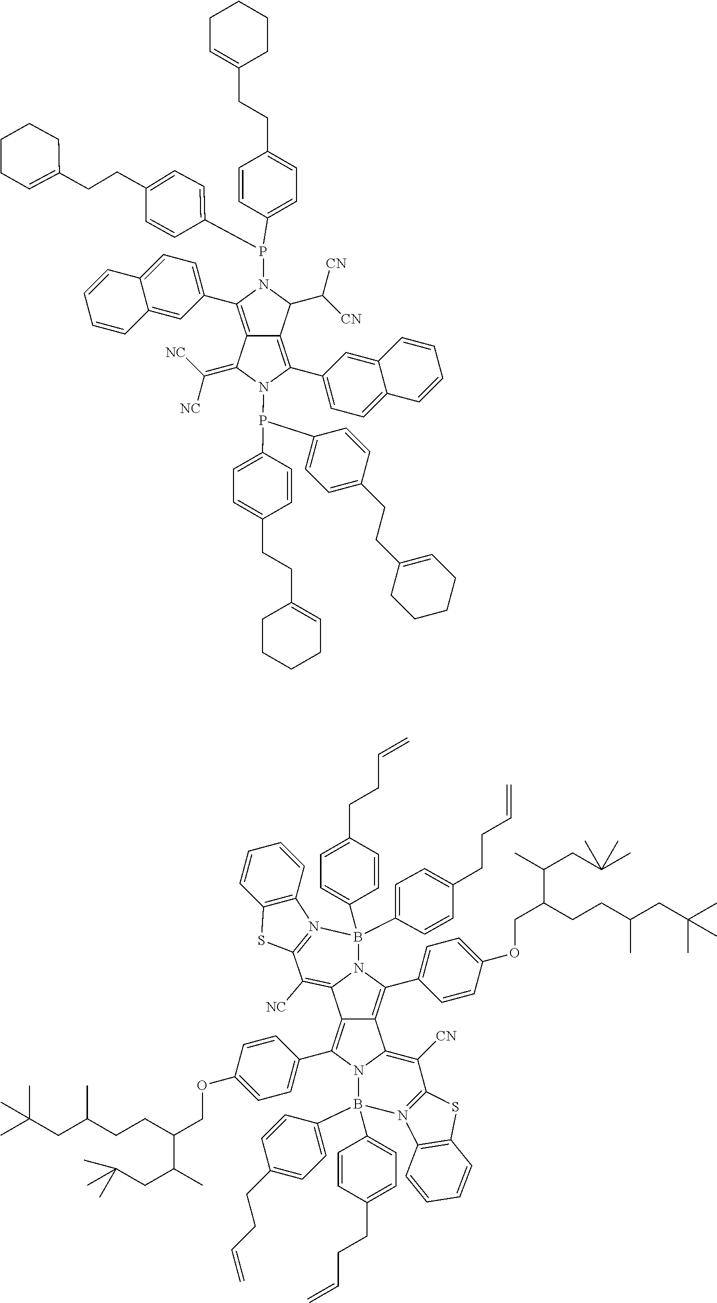

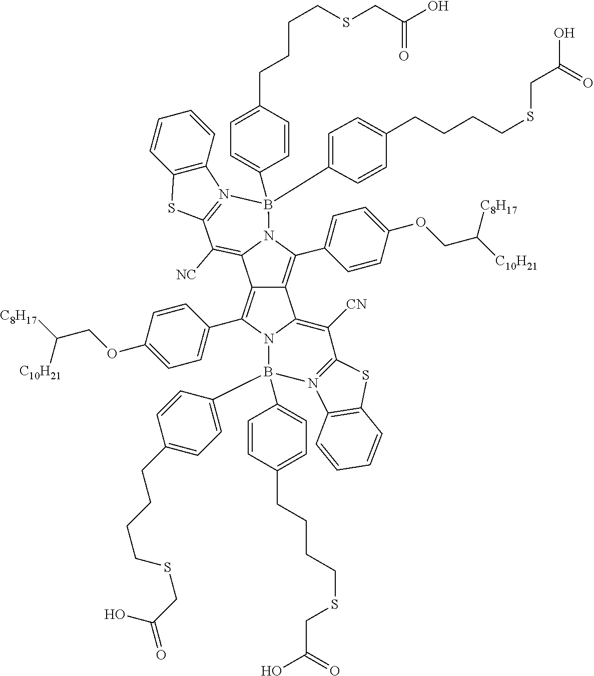

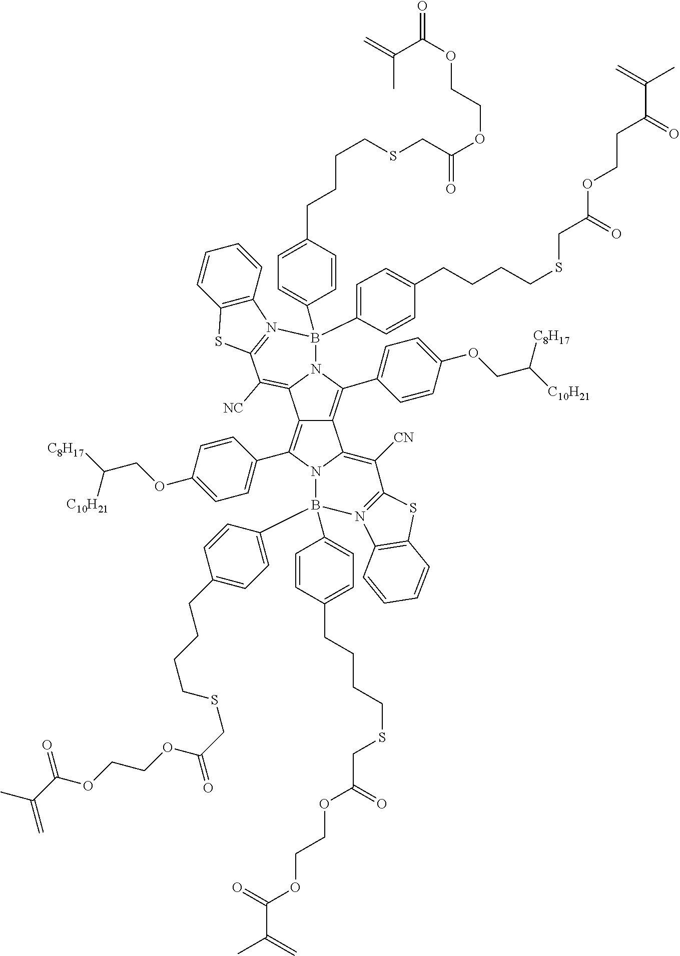

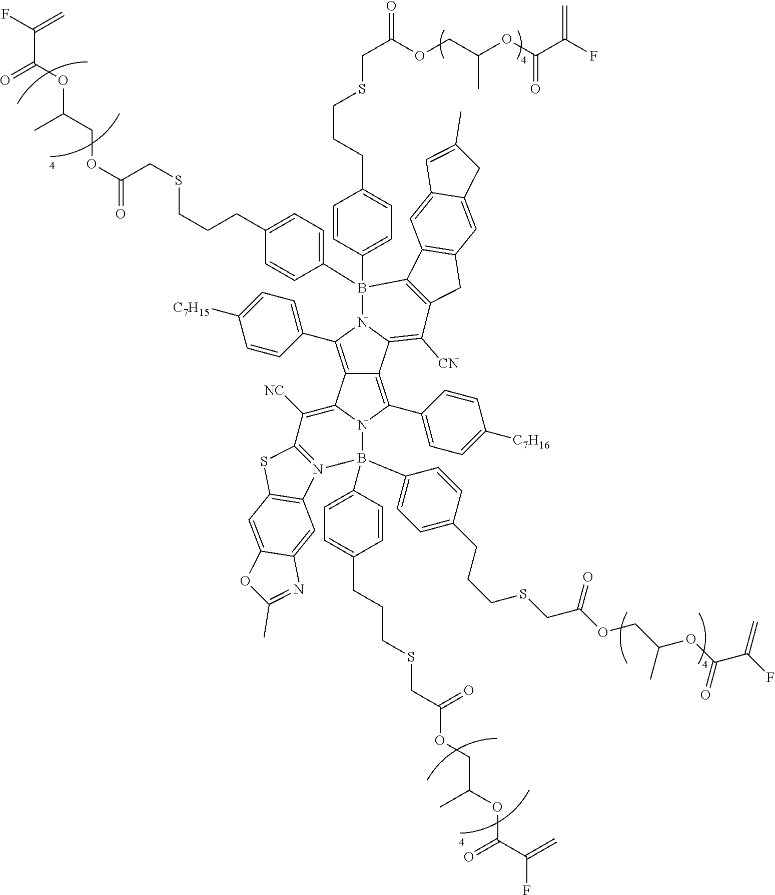

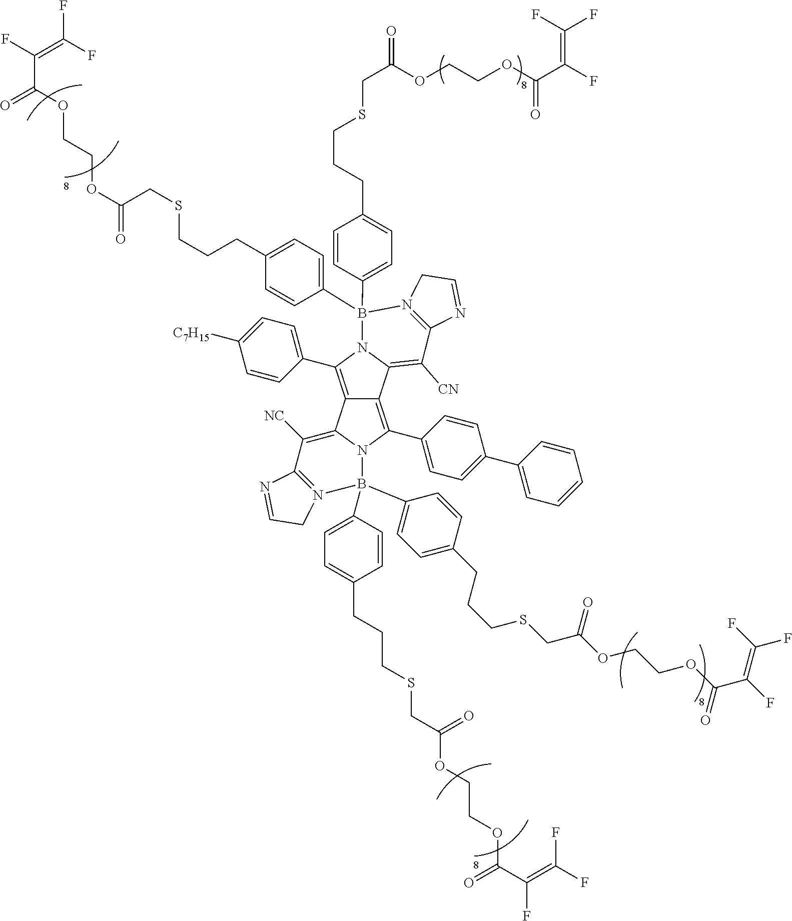

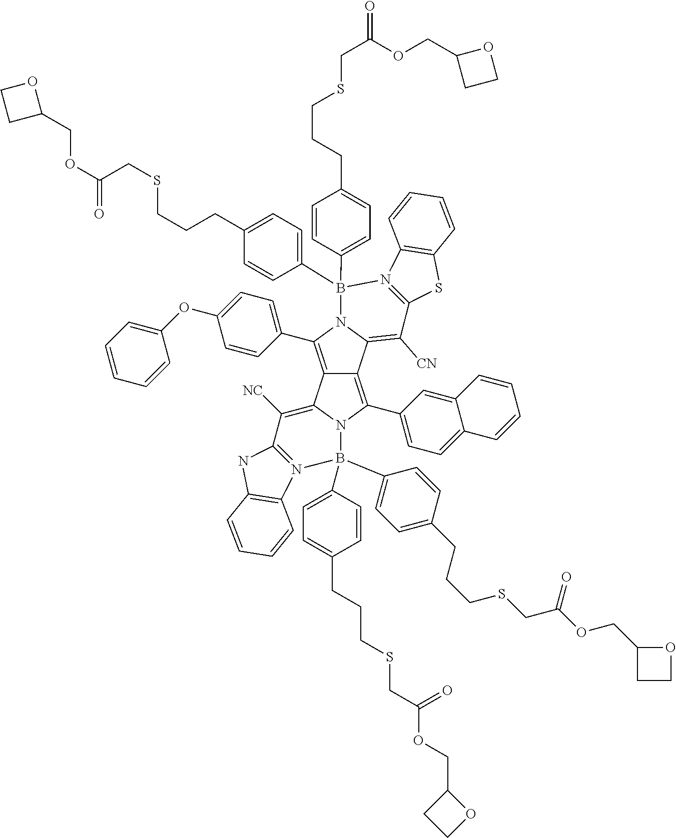

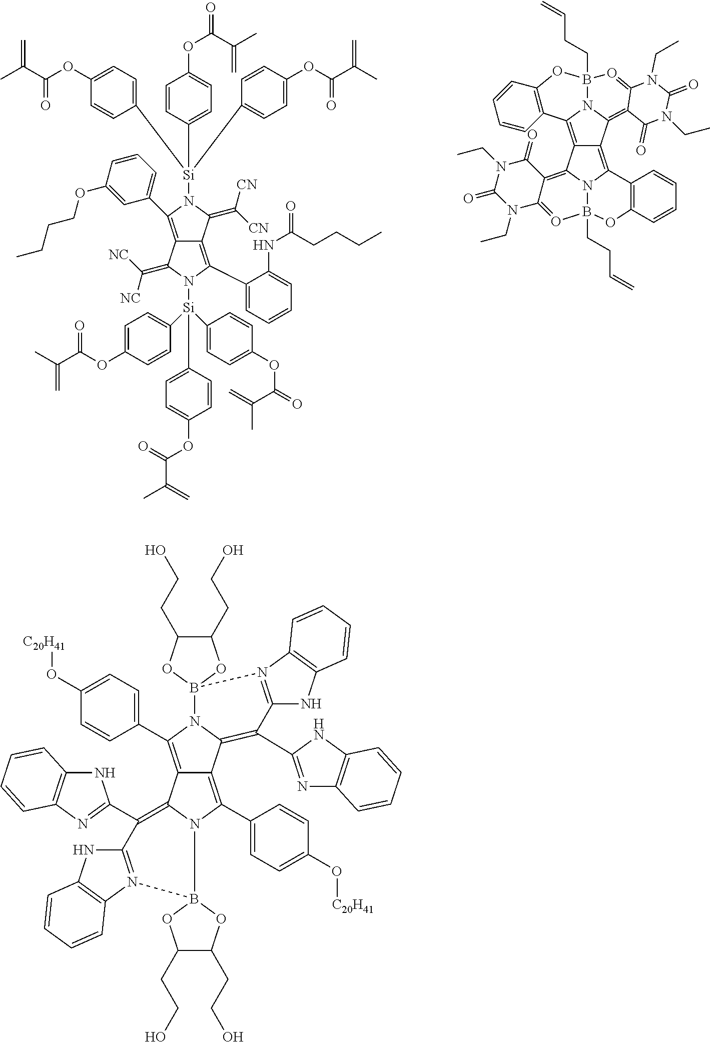

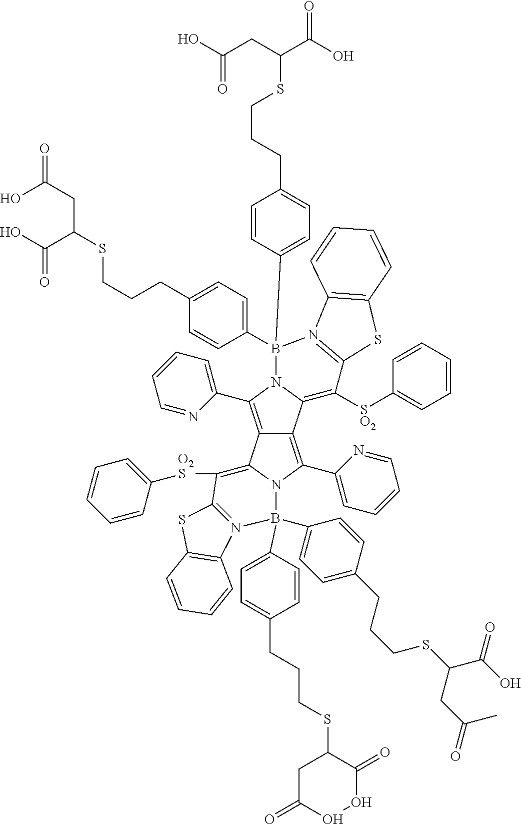

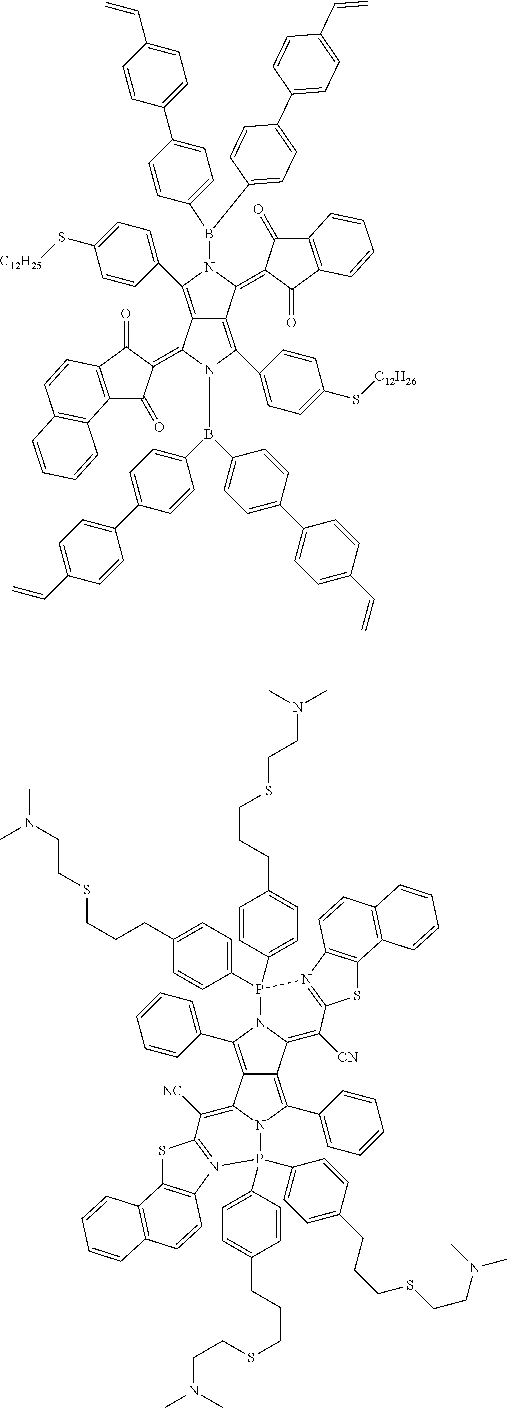

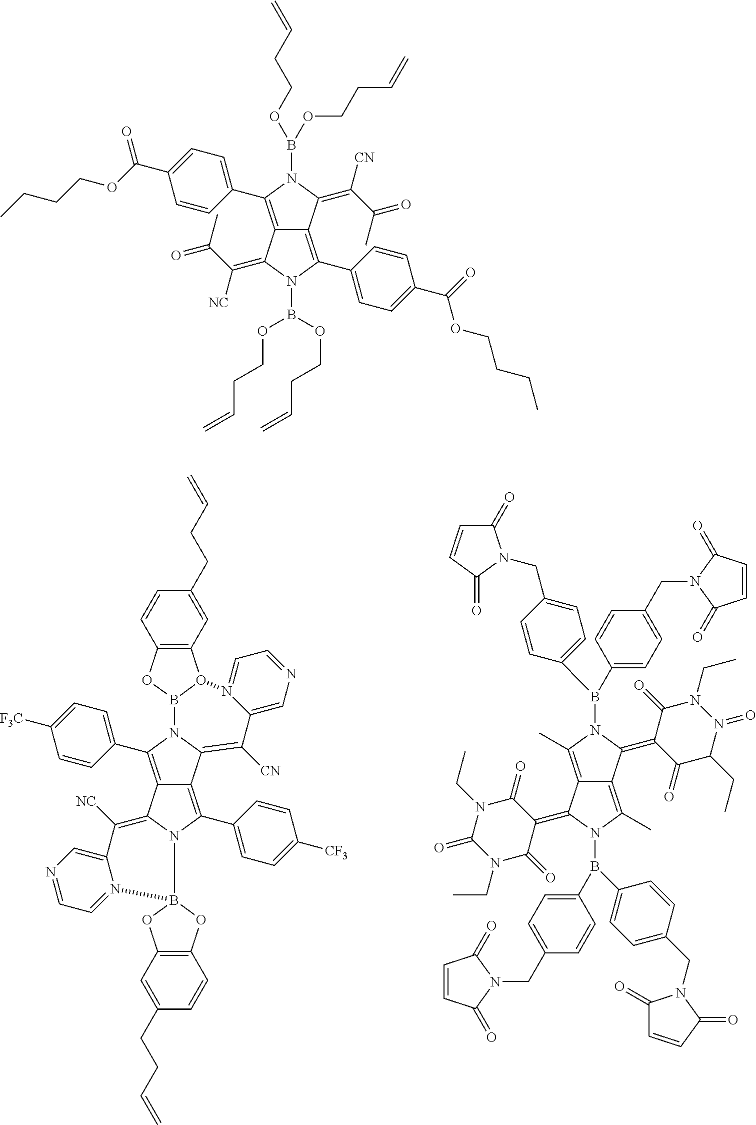

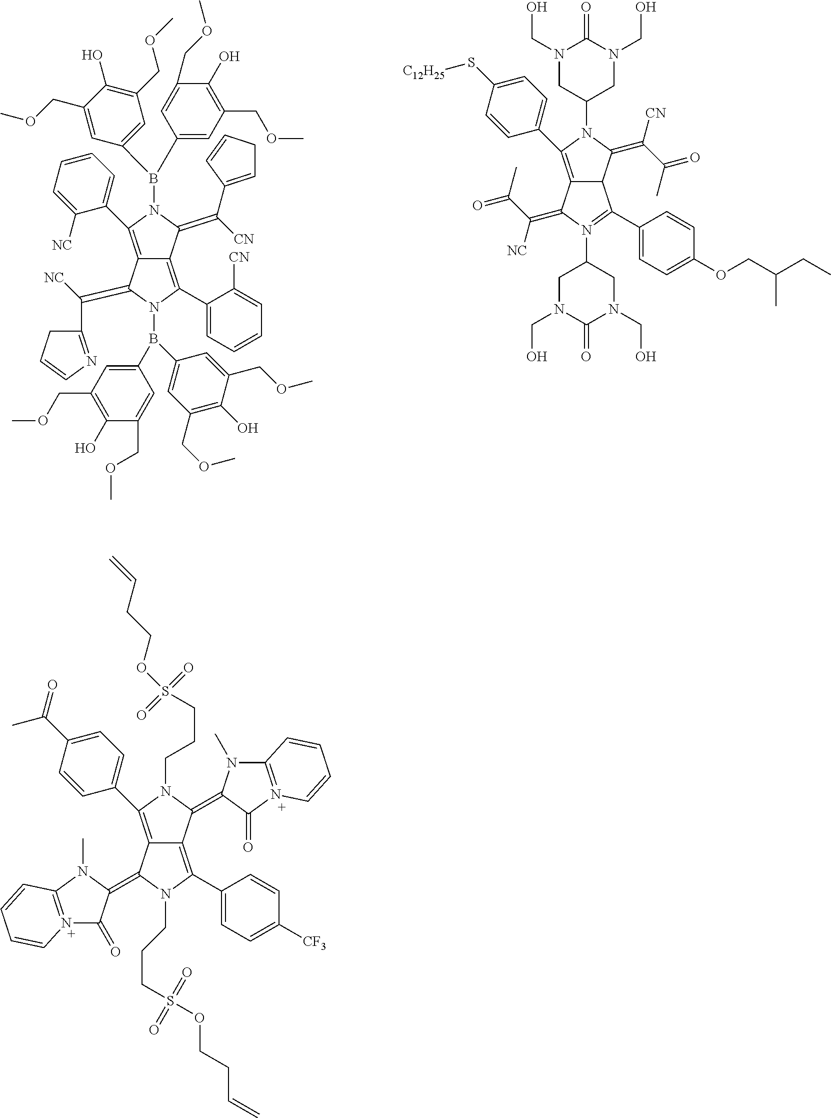

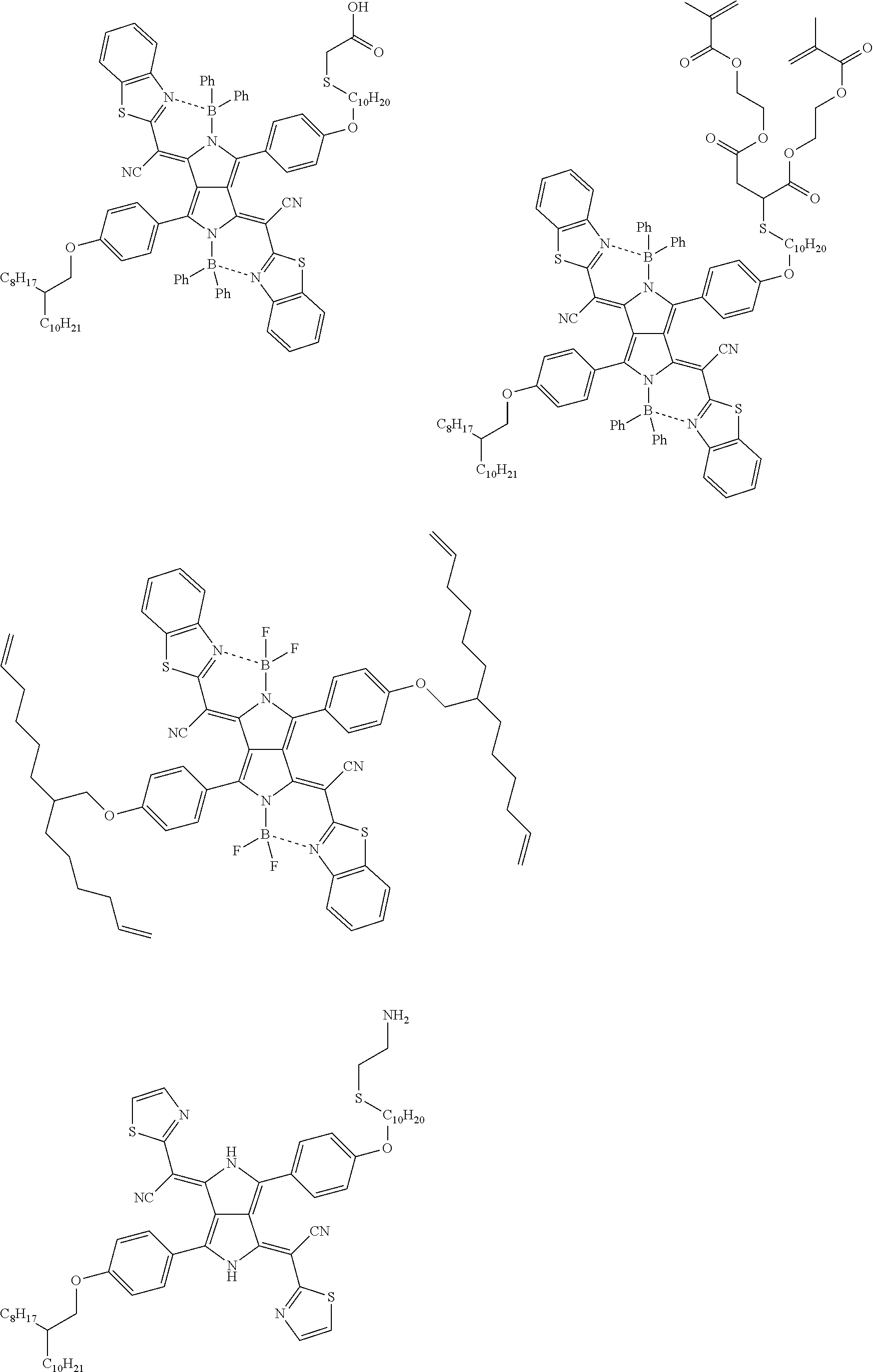

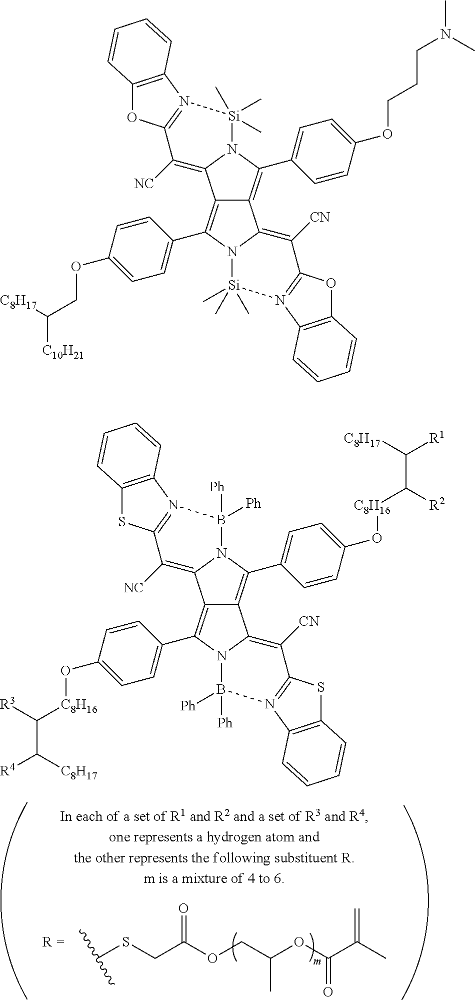

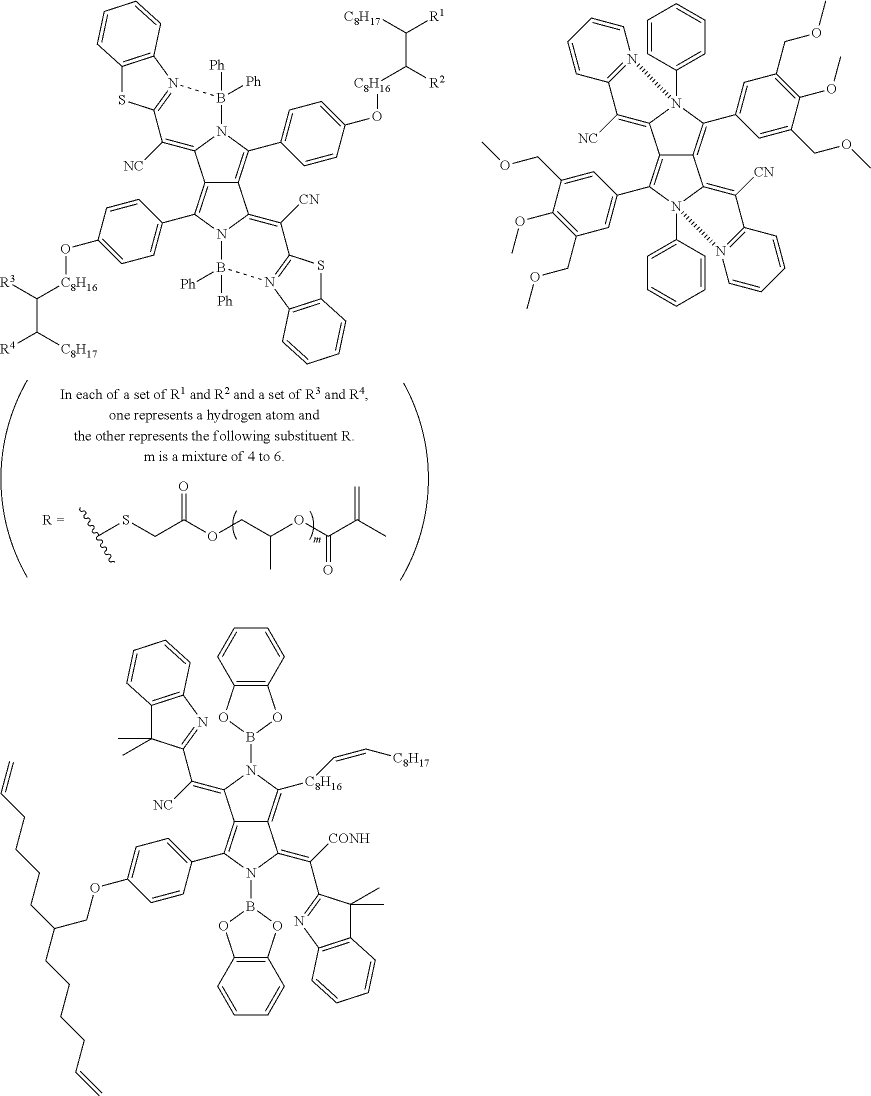

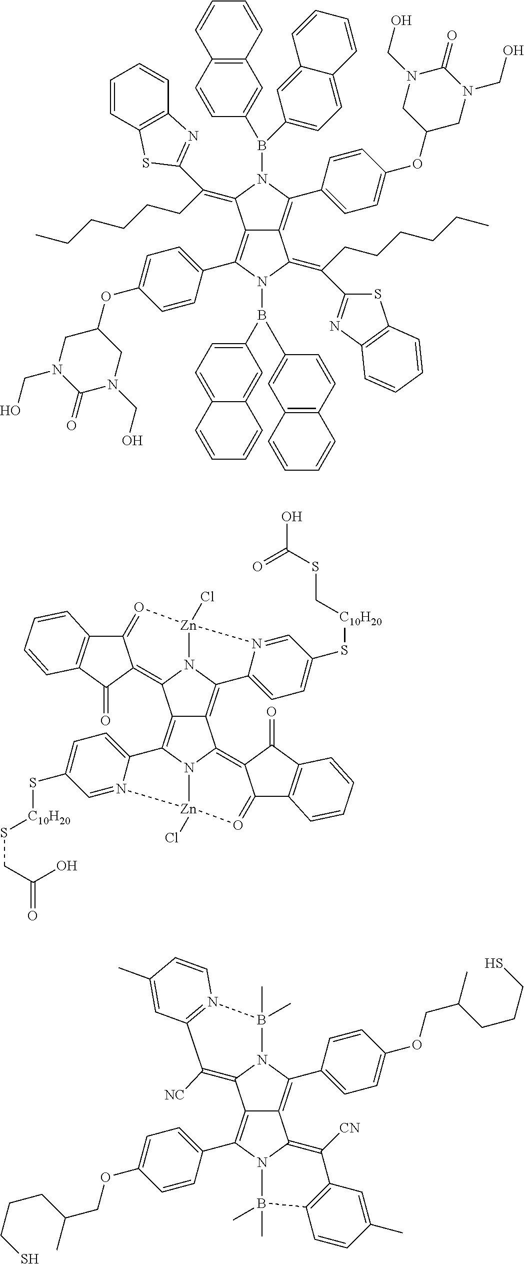

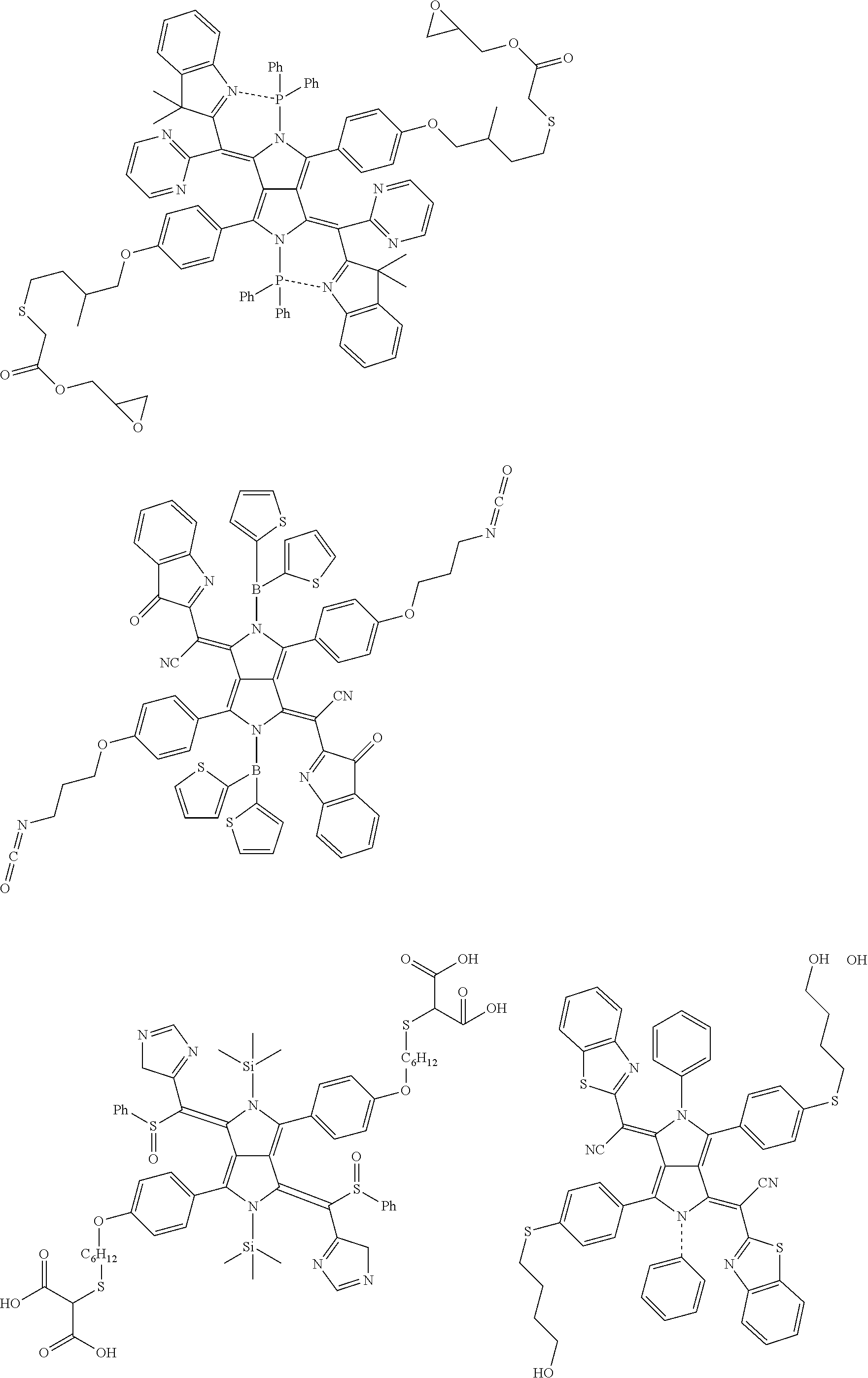

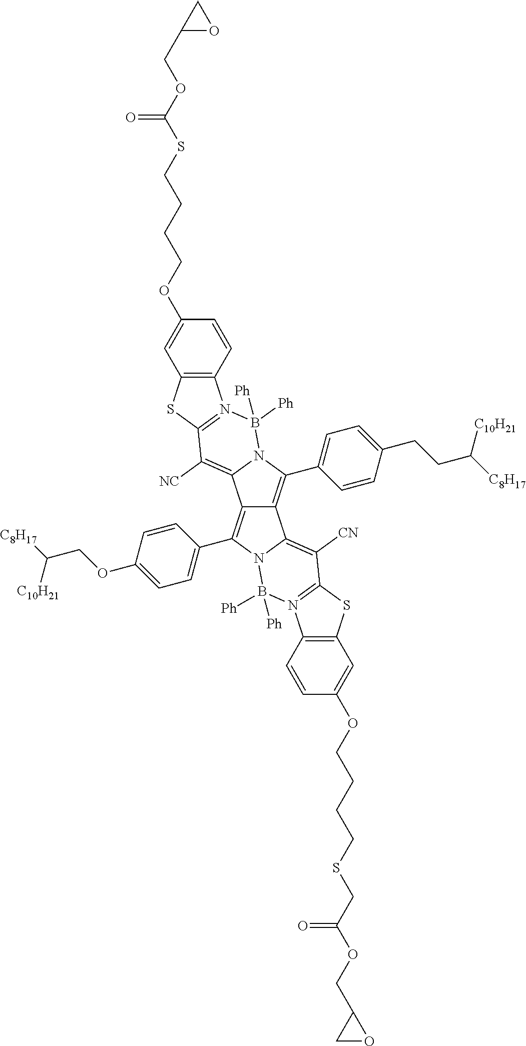

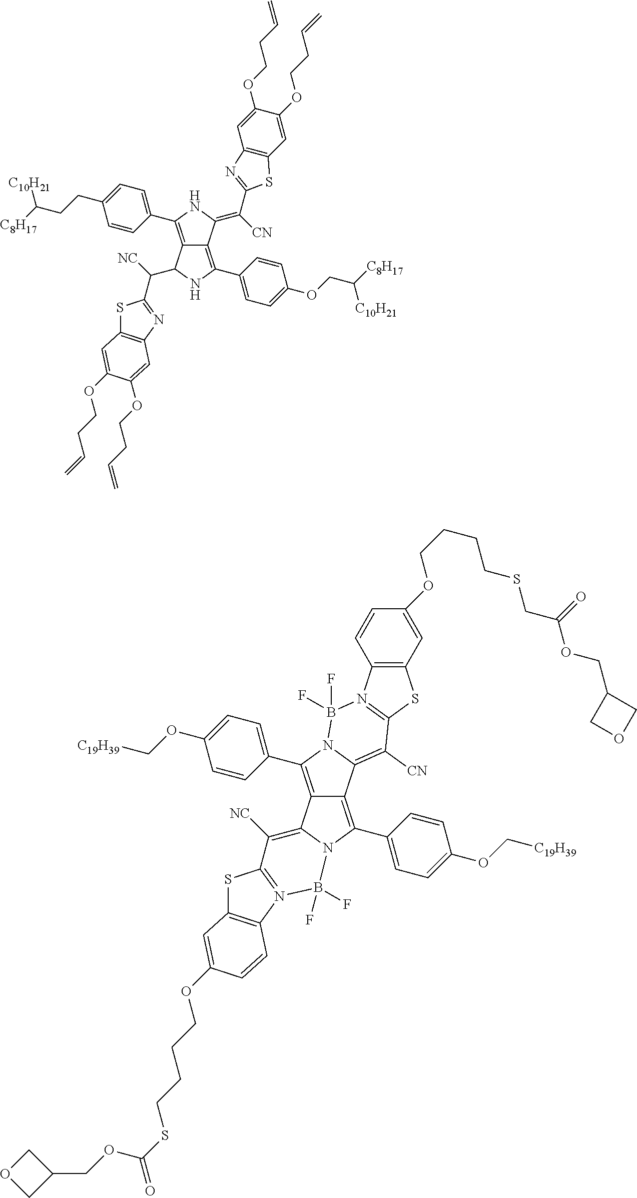

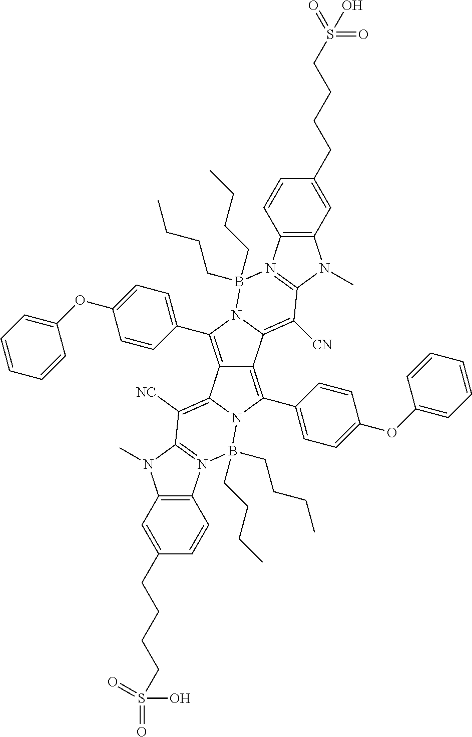

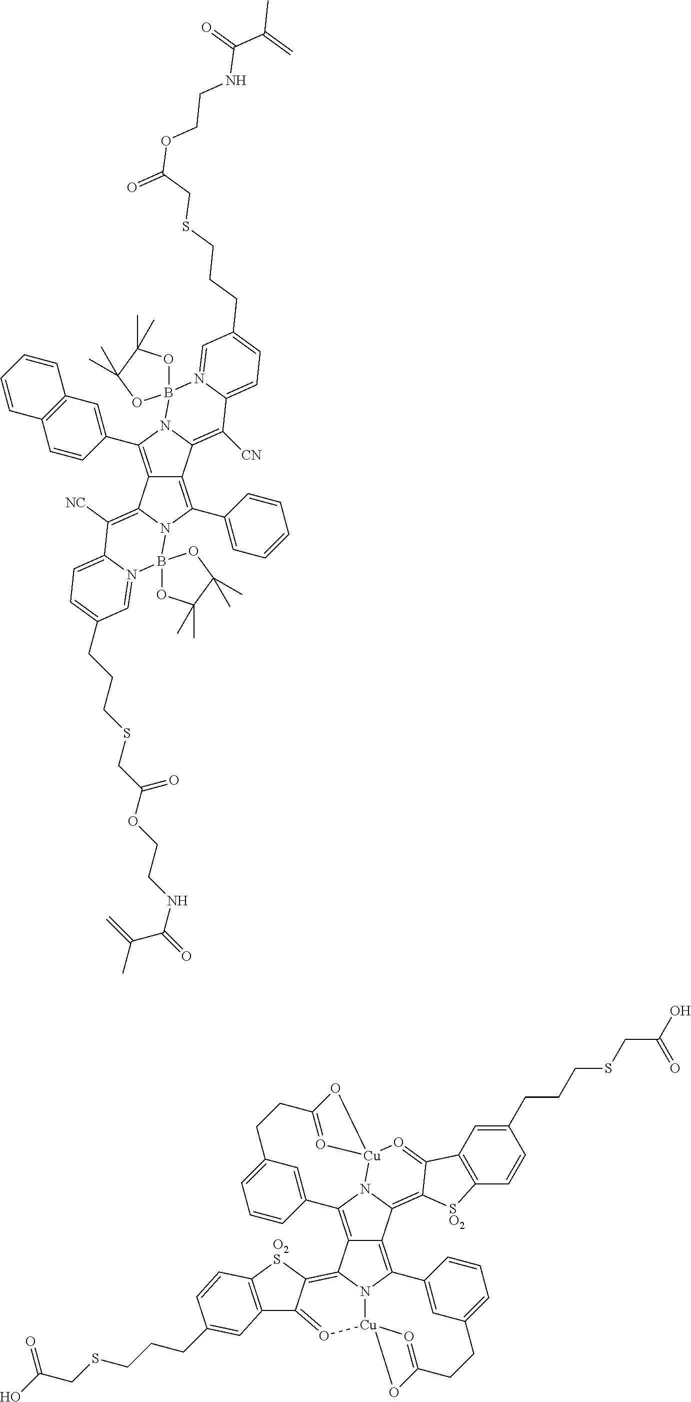

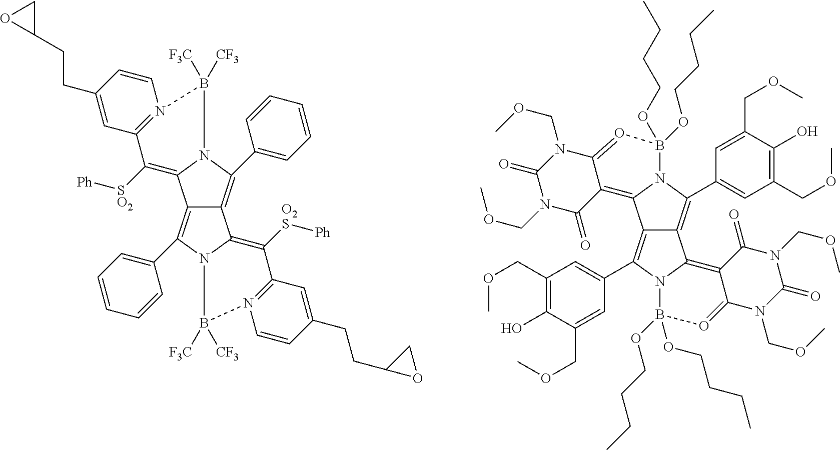

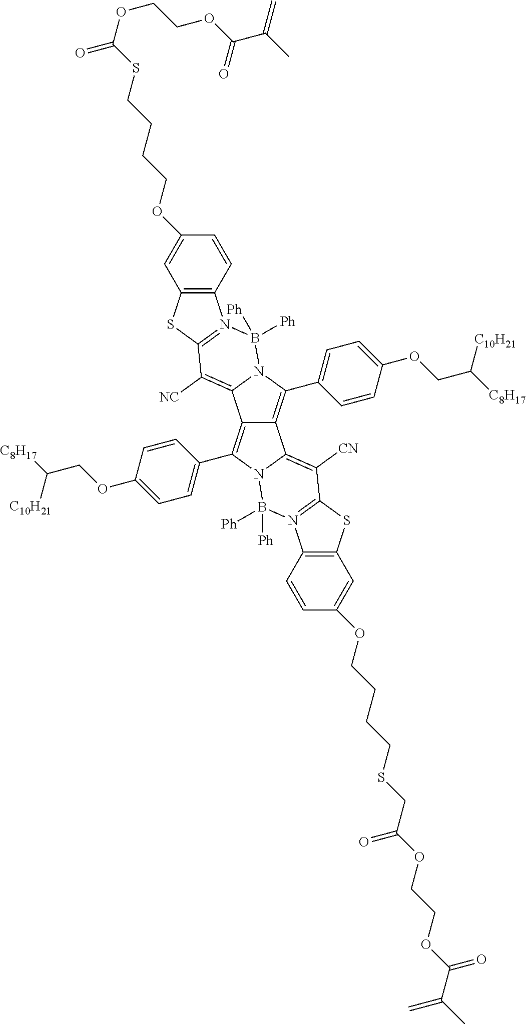

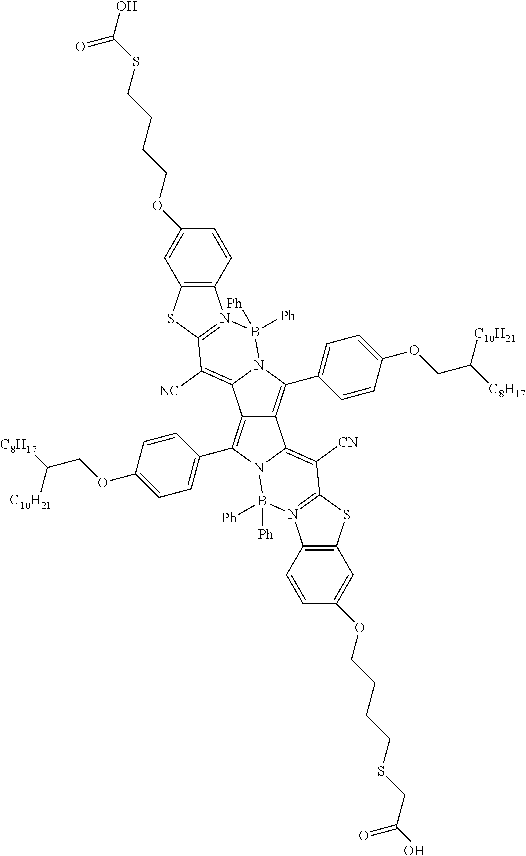

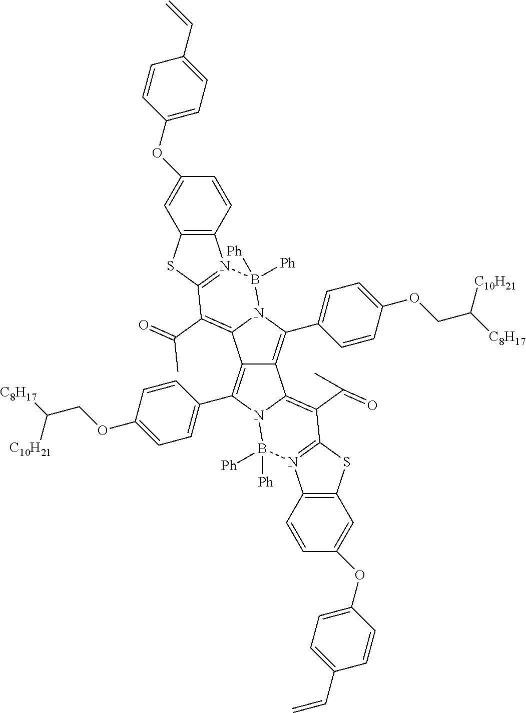

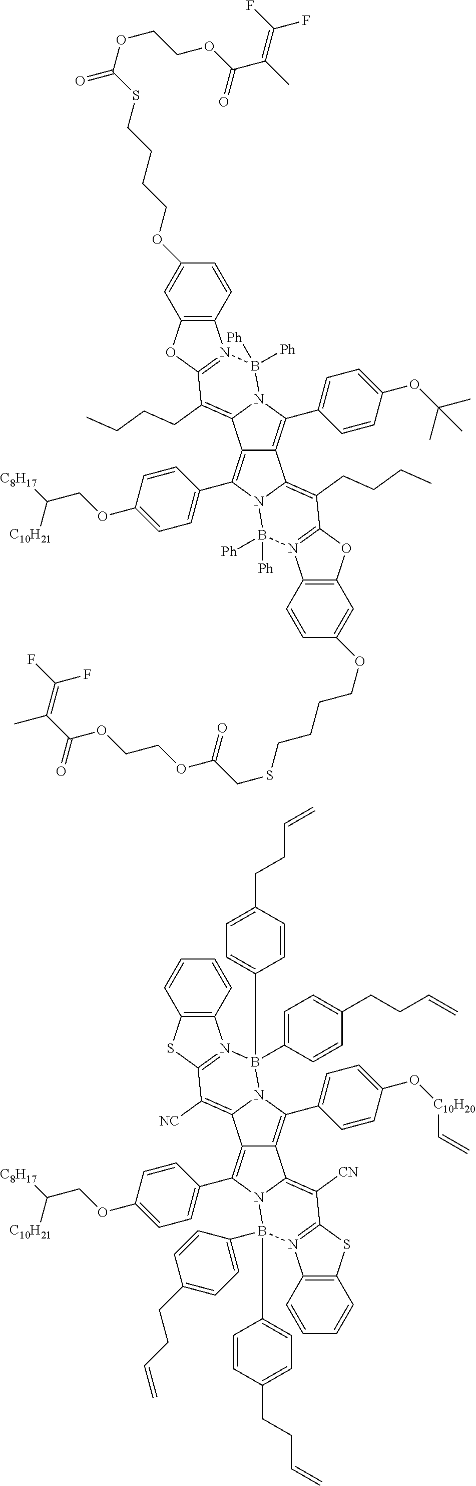

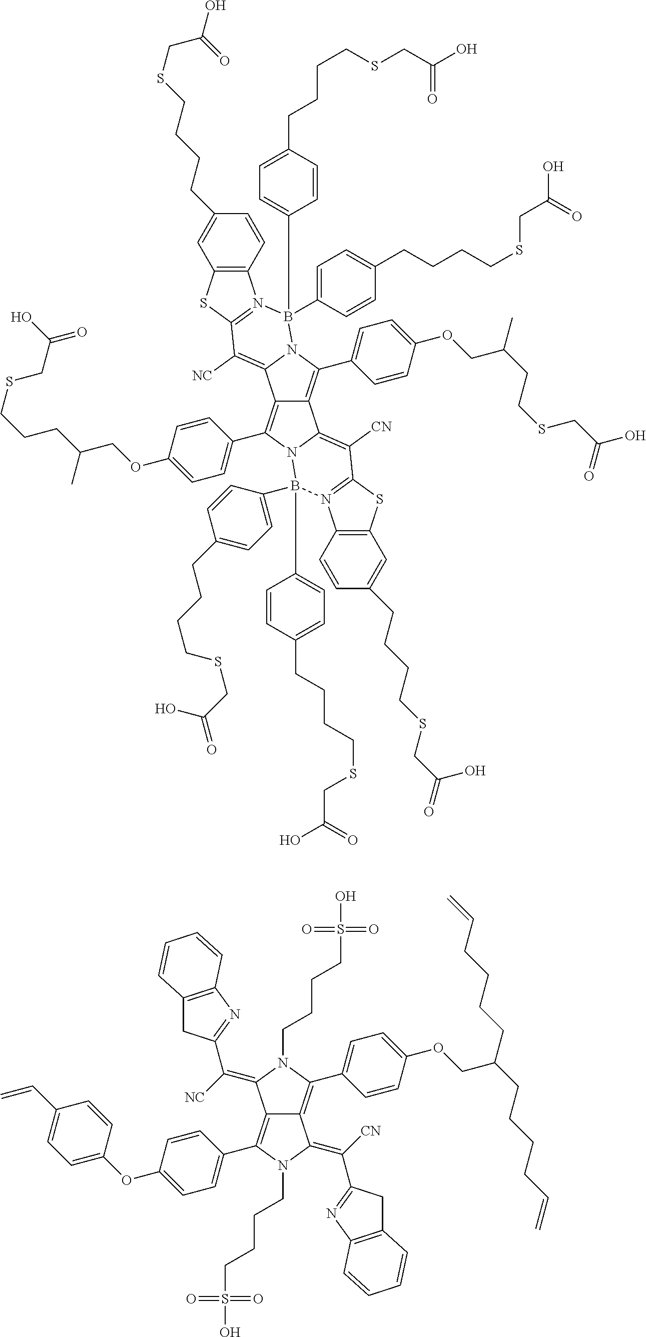

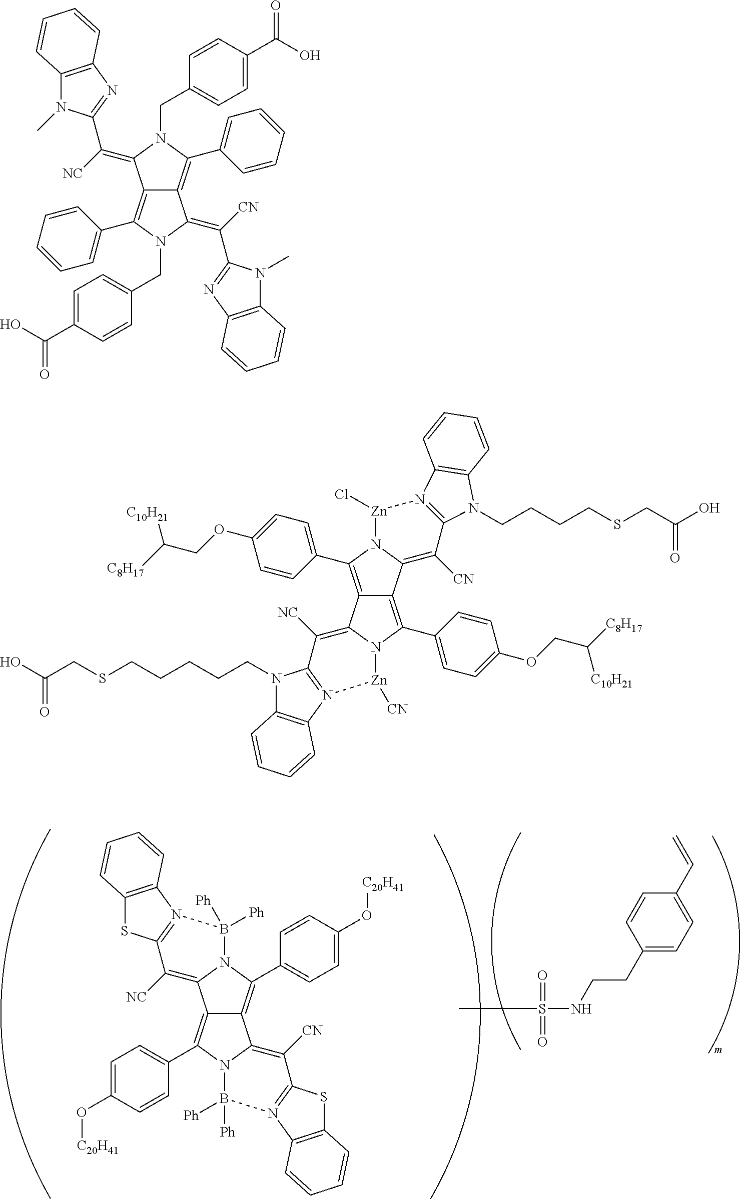

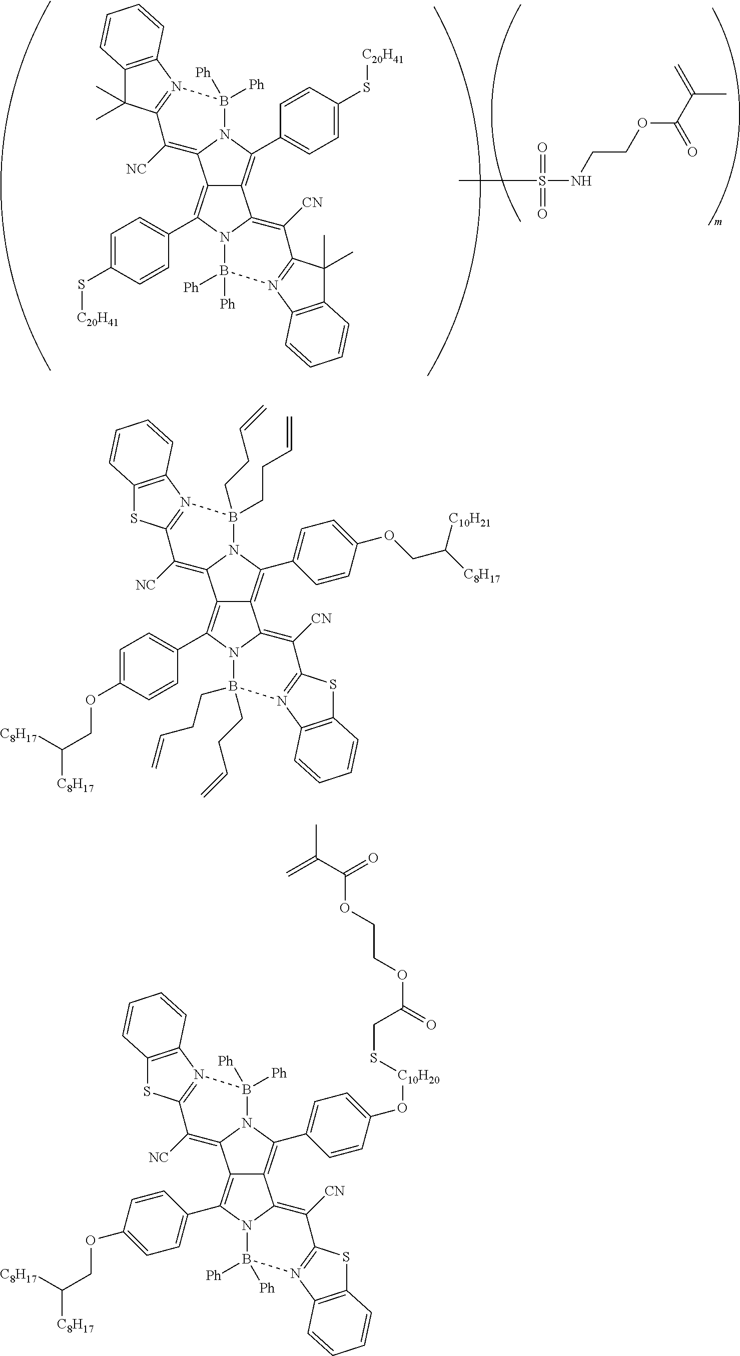

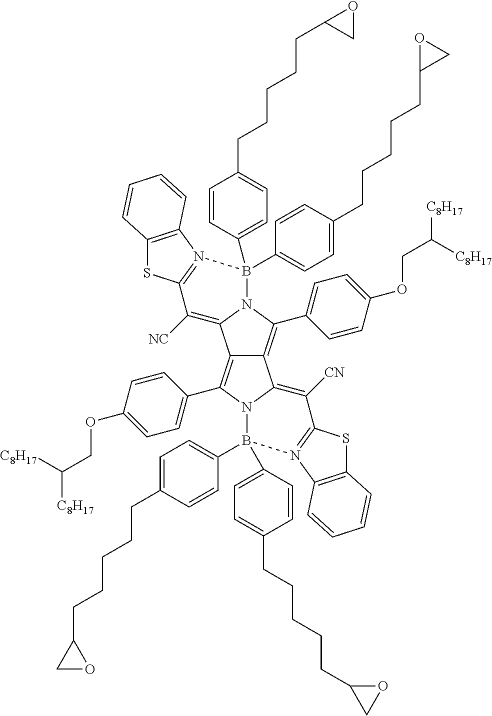

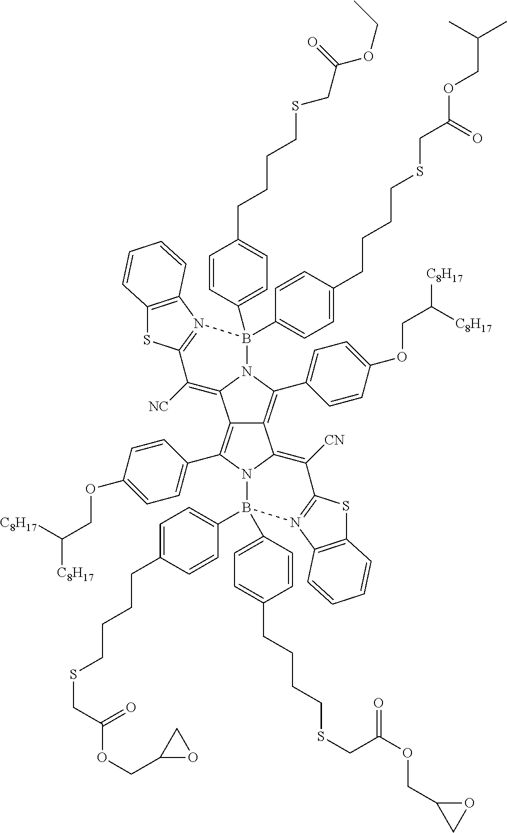

In the composition of the present invention, the content of the compound represented by General Formula (1) is preferably in a range of 0.01% to 50% by mass, more preferably in a range of 0.1% to 30% by mass, and more preferably in a range of 1% to 25% by mass of the total solid contents in the composition. Only one kind of the compound represented by General Formula (1) may be used, or two or more kinds of the compounds may be jointly used.

The composition of the present invention may further include near-infrared absorbing substances other than the above-described near-infrared absorbing substances.

The composition of the present invention may further include components other than the compound represented by General Formula (1) depending on usages in which the composition is used.

The composition of the present invention can be used in, for example, (i) the usage of near-infrared absorbing filters capable of absorbing light in a specific near-infrared range, (ii) infrared absorbing filters capable of absorbing light in a near-infrared range that is wider than a wavelength range in which light can be cut using the compound represented by General Formula (1) alone, and the like.

In a case in which the composition is used in (i) the usage of near-infrared absorbing filters, it is preferable that the composition of the present invention includes the compound represented by General Formula (1) and does not substantially include compounds that absorb light in a wavelength range other than a wavelength range in which light is absorbed by the compound represented by General Formula (1). Here, compounds not being substantially included means that the content of the compounds is 1% by mass or less of the compound represented by General Formula (1). Furthermore, the composition may include a curable compound, a curing agent, a surfactant, a solvent, and the like.

In a case in which the composition is used in (ii) the near-infrared absorbing filter usage, the composition of the present invention preferably includes, in addition to the compound represented by General Formula (1), other near-infrared absorbing substances having an absorption maximum in a near-infrared range different from a wavelength range in which the compound represented by General Formula (1) has an absorption maximum. Furthermore, the composition may include a curable compound, a curing agent, a surfactant, a solvent, and the like.

Hereinafter, other components that the composition of the present invention may include will be described.

<<Curable Compound>>

The composition of the present invention may include a curable compound. The curable compound is preferably a compound having a polymerizable group (hereinafter, in some cases, referred to as the “polymerizable compound”).

The polymerizable compound may be monofunctional or polyfunctional. However, when the composition includes a polyfunctional compound, heat resistance can be further improved.

Example of the curable compound include monofunctional (meth)acrylates, polyfunctional (meth)acrylates (preferably trifunctional to hexafunctional (meth)acrylates), polybasic acid-modified acryl oligomers, epoxy resins, and polyfunctional epoxy resins.

<<<Compound having Ethylenic Unsaturated Bond>>>

Regarding examples of a compound having an ethylenic unsaturated bond, it is possible to refer to Paragraphs “0033” and “0034” of JP2013-253224A, the content of which is incorporated into the present specification.

The compound having an ethylenic unsaturated bond is preferably ethyleneoxy-modified pentaerythritol tetraacrylate (NK ester ATM-35E as a commercially available product: manufactured by Shin-Nakamura Chemical Co., Ltd.), dipentaerythritol triacrylate (KAYARAD D-330 as a commercially available product; manufactured by Nippon Kayaku Co., Ltd.), dipentaerythritol tetraacrylate (KAYARAD D-320 as a commercially available product; manufactured by Nippon Kayaku Co., Ltd.), dipentaerythritol penta(meth)acrylate (KAYARAD D-310 as a commercially available product; manufactured by Nippon Kayaku Co., Ltd.), dipentaerythritol hexa(meth)acrylate (KAYARAD DPHA as a commercially available product; manufactured by Nippon Kayaku Co., Ltd.), or a structure in which the above-described (meth)acryloyl groups are through ethylene glycol and propylene glycol residues. In addition, oligomer types thereof can also be used.

In addition, it is possible to refer to the description of polymerizable compounds in Paragraphs “0034” to “0038” of JP2013-253224A, the content of which is incorporated into the present specification.

In addition, examples thereof include polymerizable monomers and the like described in Paragraph “0477” of JP2012-208494A ([0585] in the specification of the corresponding US2012/0235099A), the content of which is incorporated into the present specification.

In addition, DIGLYCERIN EO (ethylene oxide)-modified (meth)acrylate (M-460 as a commercially available product; manufactured by Toagosei Co., Ltd.) is preferred. Pentaerythritol tetraacrylate (manufactured by Shin-Nakamura Chemical Co., Ltd., A-TMMT) and 1,6-hexanediol diacrylate (manufactured by Nippon Kayaku Co., Ltd., KAYARAD HDDA) are also preferred. Oligomer types thereof can also be used. Examples thereof include RP-1040 (manufactured by Nippon Kayaku Co., Ltd.) and the like.

The compound having an ethylenic unsaturated bond may be a polyfunctional monomer having an acid group such as a carboxylic group, a sulfonic acid group, or a phosphoric acid group. Therefore, when a polymerizable compound having an ethylenic unsaturated bond has an unreacted carboxyl group as in a case in which the polymerizable compound is a mixture as described above, it is possible to use the polymerizable compound having an ethylenic unsaturated bond as it is; however, if necessary, an acid group may be introduced into the polymerizable compound having an ethylenic unsaturated bond by reacting a non-aromatic carboxylic acid anhydride with a hydroxyl group in the above-described ethylenic compound. In this case, specific examples of the non-aromatic carboxylic acid anhydride being used include anhydrous tetrahydrophthalic acid, alkylated anhydrous tetrahydrophthalic acid, anhydrous hexahydrophthalic acid, alkylated anhydrous hexahydrophthalic acid, anhydrous succinic acid, and anhydrous maleic acid.

The compound having an ethylenic unsaturated bond having an acid group is preferably an ester of an aliphatic polyhydroxy compound and an unsaturated carboxylic acid which is a polyfunctional monomer provided with an acid group by reacting a non-aromatic carboxylic anhydride with an unreacted hydroxyl group in an aliphatic polyhydroxy compound and particularly preferably the ester in which the aliphatic polyhydroxy compound is pentaerythol and/or dipentaerythritol. Examples of commercially available products thereof include ARONIX series M-305, M-510, M-520, and the like which are polybasic acid-modified acryl oligomers manufactured by Toagosei Co., Ltd.

The preferred acid value of the polyfunctional monomer having an acid group is in a range of 0.1 to 40 mg-KOH/g and particularly preferably in a range of 5 to 30 mg-KOH/g. In a case in which two or more polyfunctional monomers having different acid groups are jointly used or polyfunctional monomers having no acid groups are jointly used, the acid value of all of the polyfunctional monomers is adjusted so as to fall within the above-described range.

<<<Compound having Epoxy Group or Oxetanyl Group>>>

The composition of the present invention may include a compound having an epoxy group or an oxetanyl group as the polymerizable compound. The compound having an epoxy group or an oxetanyl group is specifically a polymer having an epoxy group in a side chain or a polymerizable monomer or oligomer having two or more epoxy groups in the molecule, and examples thereof include bisphenol A-type epoxy resins, bisphenol F-type epoxy resins, phenol novolac-type epoxy resins, cresol novolac-type epoxy resins, aliphatic epoxy resins, and the like. In addition, examples thereof also include monofunctional or polyfunctional glycidyl ether compounds, and polyfunctional aliphatic glycidyl ether compounds are preferred.

As the above-described compound, a commercially available product may be used or the compound can be obtained by introducing an epoxy group into a side chain of a polymer.

Regarding the commercially available product, it is possible to refer to, for example, the description of Paragraphs “0191” and the like of JP2012-155288A, the content thereof is incorporated into the specification of the present application.

In addition, examples of the commercially available product include polyfunctional aliphatic glycidyl ether compounds such as DENACOL EX-212L, EX-214L, EX-216L, EX-321L, and EX-850L (all manufactured by Nagase ChemteX Corporation). These products are low-chlorine products, but it is also possible to use EX-212, EX-214, EX-216, EX-321, EX-850, and the like which are not low-chlorine products in a similar manner.

Additionally, examples thereof also include ADEKA RESIN EP-40005, ADEKA RESIN EP-4003S, ADEKA RESIN EP-4010S, ADEKA RESIN EP-4011S (all manufactured by Adeka Corporation), NC-2000, NC-3000, NC-7300, XD-1000, EPPN-501, EPPN-502 (all manufactured by Adeka Corporation), JER1031S, CEROXIDE2021P, CEROXIDE2081, CEROXIDE2083, CEROXIDE2085, EHPE3150, EPOLEAD PB 3600, EPOLEAD PB 4700 (all manufactured by Daicel Corporation), CYCLOMER P ACA 200M, CYCLOMER P ACA 230AA, CYCLOMER P ACA Z250, CYCLOMER P ACA Z251, CYCLOMER P ACA Z300, CYCLOMER P ACA Z320 (all manufactured by Daicel Corporation), and the like.

Furthermore, examples of the commercially available product of the phenol novolac-type epoxy resins include JER-157S65, JER-152, JER-154, and JER-157S70 (all manufactured by Mitsubishi Chemical Corporation), and the like.

Specific examples of the polymer having an oxetanyl group in a side chain and the above-described polymerizable monomer or oligomer having two or more oxetanyl groups in the molecule that can be used include ARONOXETANE OXT-121, OXT-221, OX-SQ, and PNOX (all manufactured by Toagosei Co., Ltd.).

The weight-average molecular weight is in a range of 500 to 5,000,000 and more preferably in a range of 1,000 to 500,000.

As an epoxy unsaturated compound, it is also possible to use any compounds having a glycidyl group as the epoxy group such as glycidyl (meth)acrylate or allyl glycidyl ether, but an unsaturated compound having an alicyclic epoxy group is preferred. Regarding the above-described compound, it is possible to refer to, for example, the description of Paragraphs “0045” and the like of JP2009-265518A, the content of which is incorporated into the present specification.

<<<Other Curable Compounds>>>

In addition, the composition of the present invention preferably includes a polyfunctional monomer having a caprolactone-modified structure as the curable compound. The polyfunctional monomer having a caprolactone-modified structure can be used singly, or two or more kind of the polyfunctional monomers having a caprolactone-modified structure can be used in a mixed form.

Regarding the polyfunctional monomer having a caprolactone-modified structure, it is possible to refer to, for example, the description in Paragraphs “0042” to “0045” of JP2013-253224A, the content of which is incorporated into the specification of the present application.

Examples of a commercially available product thereof include SR-494 manufactured by Sartomer which is a tetrafunctional acrylate having four ethyleneoxy chains, TPA-330 which is a trifunctional acrylate having three isobutyleneoxy chains, and the like.

In addition, examples of the polyfunctional monomer include trimethylolpropane tri(meth)acrylate, pentaerythritol tri(meth)acrylate, ethylene glycol di(meth)acrylate, tetraethylene glycol di(meth)acrylate, polyethylene glycol di(meth)acrylate, 1,4-butanediol di(meth)acrylate, 1,6-hexanediol di(meth)acrylate, neopentyl glycol di(meth)acrylate, trimethylolpropane trioxyethyl(meth)acrylate, tris(2-hydroxyethyl) isocyanurate tri(meth)acrylate, tris(acryloyloxy) isocyanurate, tricyclodecane dimethanol diacrylate, di(meth)acrylates of a diol which is an adduct of polyethylene oxide or propylene oxide of bisphenol A, di(meth)acrylates of diols which are adducts of ethylene oxides or propylene oxides of hydrogenated bisphenol A, epoxy (meth) acrylates obtained by adding (meth)acrylate to diglycidyl ether of bisphenol A, triethylene glycol dimethanol divinyl ether, and the like. Among these, tricyclodecane dimethanol diacrylate is preferred.

Examples of commercially available products of the above-exemplified polyfunctional monomers include YUPIMER UV SA1002, SA2007 (all manufactured by Mitsubishi Chemical Corporation), VISCOAT #195, #230, #215, #260, #335HP, #295, #300, #360, #700, GPT, 3PA (all manufactured by Osaka Organic Chemical Industry Ltd.), LIGHT ACRYLATE 4EG-A, 9EG-A, NP-A, DCP-A, BP-4EA, BP-4PA, TMP-A, PE-3A, PE-4A, DPE-6A (all manufactured by Kyoeisha Chemical Co., Ltd.), KAYARAD PET-30, TMPTA, R-604, DPCA-20, DPCA-30, DPCA-60, DPCA-120, HX-620, D-330 (all manufactured by Nippon Kayaku Co., Ltd.), ARONIX M208, M210, M215, M220, M240, M309, M310, M315, M325, M400 (all manufactured by Toagosei Co., Ltd.), RIPOXY VR-77, VR -60, VR-90 (all manufactured by Showa Highpolymer Co., Ltd.), and the like.

In a case in which the near-infrared absorbing composition of the present invention includes the curable compound, the content of the curable compound can also be set to 1% by mass or higher, 15% by mass or higher, and 40% by mass or higher of the total solid contents excluding solvents. In addition, the content of the curable compound can also be set to 90% by mass or lower, 80% by mass or lower, 50% by mass or lower, 30% by mass or lower, and 25% by mass or lower of the total solid contents excluding solvents.

In a case in which a polymer having a repeating unit having a polymerizable group is used as the curable compound, the content of the polymer is preferably in a range of 2% to 80% by mass, more preferably in a range of 5% to 75% by mass, and particularly preferably in a range of 10% to 75% by mass of the total solid contents of the composition of the present invention excluding solvents.

The number of the kinds of the curable compounds may be one or more. In a case in which two or more kinds of the curable compounds are used, the total amount thereof preferably falls into the above-described range.

<<Polymerization Initiator>>

The composition of the present invention may include a polymerization initiator. The number of the kinds of polymerization initiators may be one or more, and, in a case in which two or more kinds of polymerization initiators are used, the total amount thereof falls into the following range. The content of the polymerization initiator is preferably in a range of 0.01% to 30% by mass, more preferably in a range of 0.1% to 20% by mass, and particularly preferably in a range of 0.1% to 15% by mass.

The polymerization initiator is not particularly limited as long as the polymerization initiator is capable of initiating the polymerization of polymerizable compounds using either or both light and heat, but is preferably a photopolymerizable compound. In a case in which polymerization is initiated using light, polymerization initiators having sensitivity to light rays in the ultraviolet range to the visible light range are preferred.

In addition, in a case in which polymerization is initiated using heat, polymerization initiators that are decomposed at a temperature in a range of 150 to 250° C. are preferred.

The polymerization initiator is preferably a compound having at least an aromatic group, and examples thereof include acylphosphine compounds, acetophenone-based compounds, α-aminoketone compounds, benzophenone-based compounds, benzoin ether-based compounds, ketal derivative compounds, thioxanthone compounds, oxime compounds, hexaaryl biimidazole compounds, trihalomethyl compounds, azo compounds, organic peroxides, diazonium compounds, iodonium compounds, sulfonium compounds, azinium compounds, benzoin ether-based compounds, ketal derivative compounds, onium salt compounds such as metallocene compounds, organic boron salt compounds, disulfone compounds, thio compounds, and the like.

Regarding the polymerization initiator, it is possible to refer to the description of Paragraphs “0217” to “0228” in JP2013-253224A, the content of which is incorporated into the specification of the present application.

As the oxime compound, it is possible to use a commercially available product IRGACURE-OXE01 (manufactured by BASF) or IRGACURE-OXE02 (manufactured by BASF). As the acetophenone-based initiator, it is possible to use commercially available products IRGACURE-907, IRGACURE-369, and IRGACURE-379 (trade names, all manufactured by BASF Japan Ltd.). In addition, as the acylphosphine-based initiator, it is possible to use a commercially available product IRGACURE-819 or DAROCUR-TPO (trade name, all manufactured by BASF Japan Ltd.).

In the present invention, as the polymerization initiator, it is also possible to use an oxime compound having a fluorine atom. Specific examples of the oxime compound having a fluorine atom include the compounds described in JP2010-262028A, Compounds 24 and 36 to 40 described in JP2014-500852A, Compound (C-3) described in JP2013-164471A, and the like. These contents are incorporated into the present specification.

<<Curing Agent>>

The composition of the present invention may include a curing agent. As the curing agent, it is possible to preferably use the curing agents and the accelerators described in Chapter 3, “Review Paper Epoxy Resin Basic I” published by The Japan Society of Epoxy Resin Technology on Nov. 19, 2003, and, for example, polyvalent carboxylic acid anhydrides or polyvalent carboxylic acids can be used.

Specific examples of the polyvalent carboxylic acid anhydrides include aliphatic or alicyclic dicarboxylic acid anhydrides such as phthalic anhydride, itaconic anhydride, succinic anhydride, citraconic anhydride, dodecenylsuccinic anhydride, tricarballylic anhydride, maleic anhydride, hexahydrophthalic anhydride, dimethyltetrahydrophthalic anhydride, himic anhydride, and vanadic acid anhydride; aliphatic polyvalent carboxylic dianhydrides such as 1,2,3,4-butane tetracarboxylic acid dianhydride and cyclopentane tetracarboxylic acid dianhydride; aromatic polyvalent carboxylic acid anhydrides such as pyromellitic anhydride, trimellitic anhydride, benzophenone tetracarboxylic anhydride; and ester group-containing organic anhydrides such as ethylene glycol bistrimellitate and glycerin tristrimellitate, and particularly preferred examples thereof include aromatic polyvalent carboxylic anhydrides. In addition, it is also possible to preferably use epoxy resin curing agents consisting of commercially available carboxylic anhydrides.

In addition, specific examples of the polyvalent carboxylic acid include aliphatic polyvalent carboxylic acids such as succinic acid, glutaric acid, adipic acid, butane tetracarboxylic acid, maleic acid, and itaconic acid; aliphatic polyvalent carboxylic acids such as hexahydrophthalic acid, 1,2-cyclohexanedicarboxylic acid, 1,2,4-cyclohexane tricarboxylic acid, and cyclopentane tetracarboxylic acid; and aromatic polyvalent carboxylic acids such as phthalic acid, isophthalic acid, terephthalic acid, pyromellitic acid, trimellitic acid, 1,4,5,8-naphthalene tetracarboxylic acid, and benzophenonetetracarboxylic acid, and preferred examples thereof include aromatic polyvalent carboxylic acids.

In addition, as the polyvalent carboxylic acid, vinyl ether blocked carboxylic acid is preferably used. Specific examples thereof include vinyl ether blocked carboxylic acids described in pp. 193 and 194 of “Review Paper Epoxy Resin Basic I” published by The Japan Society of Epoxy Resin Technology, JP2003-66223A, and JP2004-339332A. When carboxylic acid is blocked using vinyl ether, an addition reaction (esterification reaction) between the carboxylic acid and an epoxy compound gradually proceeds at room temperature, and it is possible to suppress viscosity being increased over time. In addition, solubility in a variety of solvents, epoxy monomers, and epoxy resins improves, and it is possible to produce homogeneous compositions. This vinyl ether blocked carboxylic acid is preferably used together with a heat-latent catalyst described below. When the vinyl ether blocked carboxylic acid is jointly used with the heat-latent catalyst, a de-blocking reaction is accelerated during heating, films reduce only to a small extent during heating, and it is possible to form color filters having a higher strength.

In addition, as the curing agent, it is also possible to use a mixture of glycerin bisanhydrotrimellitate monoacetate and an alicyclic dicarboxylic anhydride. As a commercially available product, it is possible to use, for example, RIKACID MTA-15 (all manufactured by New Japan Chemical Co., Ltd.).

The content of the curing agent is preferably in a range of 0.01% to 20% by mass and more preferably in a range of 0.1% to 20% by mass of the total solid contents of the composition of the present invention. The number of the kinds of the curing agents used may be one or more.

<<Alkali-Soluble Resin>>

The composition of the present invention may also include an alkali-soluble resin. When an alkali-soluble resin is blended into the composition, it is possible to form desired patterns using alkali development.

The alkali-soluble resin can be appropriately selected from alkali-soluble resins having at least one group that accelerates alkali solubility in the molecule (preferably molecules having an acryl-based copolymer or a styrene-based copolymer as a main chain). From the viewpoint of heat resistance, polyhydroxy styrene-based resins, polysiloxane-based resins, acryl-based resins, acrylamide-based resins, and acryl/acrylamide copolymer resins are preferred, and, from the viewpoint of controlling development properties, acryl-based resins, acrylamide-based resins, acryl/acrylamide copolymer resins are preferred. Regarding the alkali-soluble resin, it is possible to refer to the description of Paragraphs “0558” to “0571” of JP2012-208494A (“0685” to “0700” in the specification of the corresponding US2012/0235099A), the content of which is incorporated into the specification of the present application.

The alkali-soluble resin also preferably includes a polymer (a) formed by polymerizing monomer components including a compound represented by General Formula (ED1) below and/or a compound represented by General Formula (ED2) below (hereinafter, in some cases, these compounds will also be referred to as “ether dimers”).

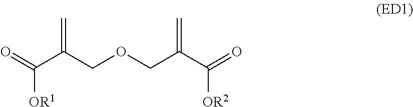

In General Formula (ED1), R¹ and R² each independently represent a hydrogen atom or a hydrocarbon group having 1 to 25 carbon atoms which may have a substituent.

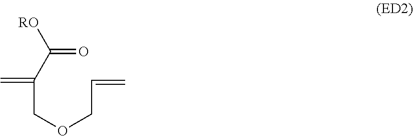

In General Formula (ED2), R represents a hydrogen atom or an organic group having 1 to 30 carbon atoms. Regarding specific examples of General Formula (ED2), it is possible to refer to JP2010-168539A.

In General Formula (ED1), the hydrocarbon group having 1 to 25 carbon atoms which may have a substituent represented by R¹ or R² is not particularly limited, and examples thereof include linear or branched alkyl groups such as methyl, ethyl, n-propyl, isopropyl, n-butyl, isobutyl, tert-butyl, tert-amyl, stearyl, lauryl, and 2-ethylhexyl; aryl groups such as phenyl; alicyclic groups such as cyclohexyl, tert-butylcyclohexyl, dicyclopentadienyl, tricyclodecanyl, isobornyl, adamantyl, and 2-methyl-2-adamantantyl; alkyl groups substituted with an alkoxy such as 1-methoxyethyl and 1-ethoxyethyl; alkyl group substituted with an aryl group such as benzyl; and the like. Among these, substituents of primary or secondary carbon which are not easily desorbed using acids or heat such as methyl, ethyl, cyclohexyl, and benzyl are particularly preferred in terms of heat resistance.

Regarding specific examples of ether dimers, it is possible to refer to, for example, Paragraph “0317” of JP2013-29760A, the content of which is incorporated into the present specification. The number of the kinds of the ether dimers may be one or more. Structures derived from the compound represented by General Formula (ED) may be copolymerized with other monomers.

In a case in which the composition of the present invention includes an alkali-soluble resin, the content of the alkali-soluble resin is preferably 1% by mass or higher and can be set to 2% by mass or higher, 5% by mass or higher, or 10% by mass or higher of the total solid contents of the composition of the present invention. In addition, the content of the alkali-soluble resin can be set to 80% by mass or lower, 65% by mass or lower, 60% by mass or lower, or 15% by mass or lower.

Furthermore, in a case in which patterns are not formed by means of alkali development using the composition of the present invention, it is needless to say that the composition may not include the alkali-soluble resin.

<<Surfactant>>

The composition of the present invention may include a surfactant. Only one surfactant may be used or a combination of two or more surfactants may be used. The amount of the surfactant added is preferably in a range of 0.0001% to 5% by mass and more preferably in a range of 0.001% to 1.0% by mass of the solid contents of the composition of the present invention.

As the surfactant, a variety of surfactants such as a fluorine-based surfactant, a nonionic surfactant, a cationic surfactant, an anionic surfactant, and a silicone-based surfactant can be used.

Particularly, when the composition of the present invention includes at least any one of a fluorine-based surfactant and a silicone-based surfactant, liquid characteristics (particularly, fluidity) are further improved when a coating fluid is produced. Therefore, the uniformity of the coating thickness or liquid-saving properties are further improved.

That is, in a case in which a film is formed using a coating fluid to which the composition including at least any one of a fluorine-based surfactant and a silicone-based surfactant is applied, the surface tension between a surface to be coated and the coating fluid is decreased, and thus the wettability to the surface to be coated is improved, and the coating properties to the surface to be coated improve. Therefore, in a case in which a thin film having a thickness of approximately several micrometers is formed using a small amount of the fluid as well, it is effective to include the surfactant since a film having a uniform thickness with little thickness unevenness can be more preferably formed.

The content ratio of fluorine in the fluorine-based surfactant is preferably in a range of 3% to 40% by mass, more preferably in a range of 5% to 30% by mass, and particularly preferably in a range of 7% to 25% by mass. Fluorine-based surfactants having a content ratio of fluorine in the above-described range are effective in terms of the uniformity of the thickness of coated films or liquid-saving properties and also have favorable solubility in the composition.

Specific examples of the fluorine-based surfactant include the surfactants described in Paragraph “0552” in JP2012-208494A (“0678” in the specification of the corresponding US2012/0235099A), the content of which is incorporated into the specification of the present application. Examples of commercially available products of the fluorine-based surfactant include MEGAFAC F-171, MEGAFAC F-172, MEGAFAC F-173, MEGAFAC F-176, MEGAFAC F-177, MEGAFAC F-141, MEGAFAC F-142, MEGAFAC F-143, MEGAFAC F-144, MEGAFAC R30, MEGAFAC F-437, MEGAFAC F-475, MEGAFAC F-479, MEGAFAC F-482, MEGAFAC F-554, MEGAFAC F-780 (all manufactured by DIC Corporation), FLORADO FC430, FLORADO FC431, FLORADO FC171 (all manufactured by Sumitomo 3M Limited), Surflon S-382, Surflon SC-101, Surflon SC-103, Surflon SC-104, Surflon SC-105, Surflon SC-1068, Surflon SC-381, Surflon SC-383, Surflon S-393, Surflon KH-40 (all manufactured by Asahi Glass Co., Ltd.), and the like.

In addition, the following compound is also exemplified as the fluorine-based surfactant that is used in the present invention.

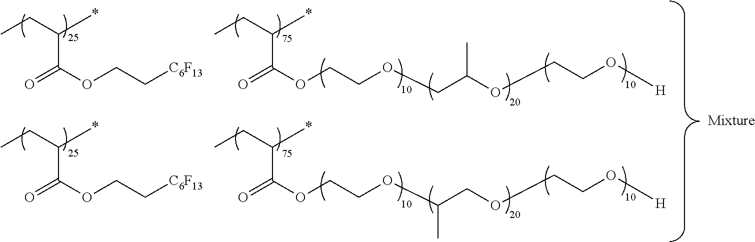

The weight-average molecular weight of the above-described compound is, for example, 14,000.

Examples of the nonionic surfactant include polyoxyethylene alkyl ethers, polyoxyethylene alkyl allyl ethers, polyoxyethylene fatty acid esters, sorbitan aliphatic esters, polyoxyethylene sorbitan fatty acid esters, polyoxyethylene alkyl amines, glycerin fatty acid esters, oxyethyleneoxy propylene blocked copolymers, acetylene glycol-based surfactants, acetylene-based polyoxyethylene oxides, and the like. These surfactants can be used singly or two or more surfactants can be used.

Examples of specific commercially available products thereof include SURFYNOL 61, 82, 104, 104E, 104H, 104A, 104BC, 104DPM, 104PA, 104PG-50, 104S, 420, 440, 465, 485, 504, CT-111, CT-121, CT-131, CT-136, CT-141, CT-151, CT-171, CT-324, DF-37, DF-58, DF-75, DF-110D, DF-210, GA, OP-340, PSA-204, PSA-216, PSA-336, SE, SE-F, TG, GA, DYNOL 604 (all manufactured by Nissin Chemical Co., Ltd. and Air Products & Chemicals, Inc.), OLFIN A, B, AK-02, CT-151W, E1004, E1010, P, SPC, STG, Y, 32W, PD-001, PD-002W, PD-003, PD-004, EXP. 4001, EXP. 4036, EXP. 4051, AF-103, AF-104, SK-14, AE-3 (all manufactured by Nissin Chemical Co., Ltd.), ACETYLENOL E00, E13T, E40,E60, E81, E100, E200 (all are trade names and are manufactured by Kawaken Fine Chemicals Co., Ltd.), and the like. Among these, OLFIN E1010 is preferred.

Additionally, specific examples of the nonionic surfactant include the nonionic surfactants described in Paragraph “0553” of JP2012-208494A (“0679” in the specification of the corresponding US2012/0235099A), the content of which is incorporated into the specification of the present application.

Specific examples of the cationic surfactant include the cationic surfactants described in Paragraph “0554” of JP2012-208494A (“0680” in the specification of the corresponding US2012/0235099A), the content of which is incorporated into the specification of the present application.

Specific examples of the anionic surfactant include W004, W005, W017 (manufactured by Yusho Co., Ltd.), and the like.

Examples of silicone-based surfactant include the silicone-based surfactants described in Paragraph “0556” of JP2012-208494A (“0682” in the specification of the corresponding US2012/0235099), the content of which is incorporated into the specification of the present application. In addition, examples thereof also include “TORAY SILICONE SF8410”, TORAY SILICONE SF8427”, TORAY SILICONE SF8400”, “ST8OPA”, “ST83PA”, “ST86PA” all manufactured by Dow Corning Toray Co., Ltd., “TSF-400”, “TSF-401”, “TSF-410”, “TSF-4446” manufactured by Momentive Performance Materials Worldwide Inc., “KP321”, “KP323”, “KP324”, “KP340” manufactured by Shin-Etsu Chemical Co., Ltd. and the like.

<Polymerization Inhibitor>

The composition of the present invention may include a small amount of a polymerization inhibitor in order to inhibit unnecessary thermal polymerization of polymerizable compounds.

Examples of the polymerization inhibitor include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), N-nitrosophenylhydroxyamine cerium salt, and the like, and p-methoxyphenol is preferred.

In a case in which the composition of the present invention includes a polymerization inhibitor, the content of the polymerization inhibitor is preferably in a range of 0.01% to 5% by mass of the solid contents of the composition of the present invention.

<<Solvent>>

The composition of the present invention may include a solvent. The solvent is not particularly limited and can be appropriately selected depending on purposes as long as the solvent is capable of homogeneously dissolving or dispersing the respective components of the composition of the present invention, and preferred examples thereof include water and water-based solvents such as alcohols. In addition, additionally, preferred examples of solvents that can be used in the present invention include organic solvents, ketones, ethers, esters, aromatic hydrocarbons, halogenated hydrocarbons, dimethylformamide, dimethylsulfoxide, sulfolane, and the like. These solvents may be used singly, or two or more solvents may be jointly used.

Specific examples of the alcohols, the aromatic hydrocarbons, and the halogenated hydrocarbons include those described in Paragraphs “0136’ and the like of JP2012-194534A, the content of which is incorporated into the specification of the present application. In addition, specific examples of the esters, the ketones, and the ethers include those described in Paragraph “0497” of JP2012-208494A (Paragraph “0609” in the specification of the corresponding US2012/0235099A) and further include n-amyl acetate, ethyl propionate, dimethyl phthalate, ethyl benzoate, methyl sulfate, acetone, methyl isobutyl ketone, diethyl ether, ethylene glycol monobutyl ether acetate, and the like.

Particularly, as the solvent, at least one selected from cyclohexanone, propylene glycol monomethyl ether acetate, N-methyl-2-pyrrolidone, butyl acetate, ethyl lactate, and propylene glycol monomethyl ether is preferably used.

The content of the solvent in the composition of the present invention is preferably an amount at which the total solid contents in the composition of the present invention falls into a range of 5% to 90% by mass, more preferably an amount at which the total solid contents in the composition of the present invention falls into a range of 10% to 80% by mass, and still more preferably an amount at which the total solid contents in the composition of the present invention falls into a range of 20% to 75% by mass.

<<Other Components>>

Examples of other components that can be jointly used in the composition of the present invention include a sensitizer, a crosslinking agent, a curing accelerator, a filler, a thermal curing accelerator, a plasticizer, and the like. Furthermore, an adhesion accelerator to the surface of a base material and other auxiliary agents (for example, conductive particles, a filler, a defoamer, a flame retardant, a leveling agent, a peeling accelerator, an antioxidant, a fragrance, a surface tension adjuster, a chain transfer agent, and the like) may also be jointly used.

When these components are appropriately added to the composition of the present invention, it is possible to adjust properties such as stability and film properties of target near-infrared absorbing filters.

Regarding the above-described components, it is possible to refer to, for example, the descriptions in Paragraphs “0183” to “0228” of JP2012-003225A (“0237” to “0309” in the specification of the corresponding US2013/0034812A), Paragraphs “0101” and “0102” of JP2008-250074A, Paragraphs “0103” and “0104” in JP2008-250074A, and Paragraphs “0107” to “0109” of JP2008-250074A, Paragraphs “0159” to “0184” of JP2013-195480A, and the like, the contents of which are incorporated into the specification of the present application.

<Preparation and Application of Near-Infrared Absorbing Composition>

The composition of the present invention can be prepared by mixing the respective components described above.

In a case in which, for example, a near-infrared absorbing filter is formed by means of coating, the viscosity of the composition of the present invention is preferably in a range of 1 to 3,000 mPa·s, more preferably in a range of 10 to 2,000 mPa·s, and still more preferably in a range of 100 to 1,500 mPa·s.

The composition of the present invention can be used for near-infrared absorbing filters, near-infrared absorbing layers in infrared sensors which detect articles by detecting light having wavelength of 700 nm or longer and shorter than 900 nm, and the like. In addition, the composition can also be used for near-infrared absorbing filters on the light-receiving side of solid image pickup element substrates (for example, near-infrared absorbing filters in wafer level lenses), near-infrared absorbing filters on the rear surface side (the side opposite to the light-receiving side) of solid image pickup element substrates, and the like.

In addition, the composition of the present invention may be used by being directly applied onto image sensors so as to form coated films. Since the composition of the present invention can be supplied in a state in which the composition can be applied, it is possible to easily form near-infrared absorbing filters at desired members or locations in solid image pickup elements.

<Near-Infrared Absorbing Filter>

Next, a near-infrared absorbing filter of the present invention will be described.

The near-infrared absorbing filter of the present invention is formed by curing the above-described composition of the present invention.

In a case in which the composition of the present invention includes the above-described compound represented by General Formula (1), the compound represented by General Formula (1) forms J aggregates in cured films. Therefore, near-infrared absorbing filters in which a composition including the compound represented by General Formula (1) is used have maximum absorption wavelengths at 700 nm or longer and shorter than 900 nm.

The light transmittance of the near-infrared absorbing filter preferably satisfies at least one condition of the following (1) to (7) and more preferably satisfies all conditions of the following (1) to (7).

(1) The light transmittance at a wavelength of 400 nm is preferably 70% or higher, more preferably 80% or higher, still more preferably 90% or higher, and particularly preferably 99.9% or higher.

(2) The light transmittance at a wavelength of 500 nm is preferably 70% or higher, more preferably 80% or higher, still more preferably 90% or higher, and particularly preferably 99.9% or higher.

(3) The light transmittance at a wavelength of 600 nm is preferably 70% or higher, more preferably 80% or higher, still more preferably 90% or higher, and particularly preferably 99.9% or higher.

(4) The light transmittance at a wavelength of 700 nm is preferably 30% or lower, more preferably 20% or lower, still more preferably 10% or lower, and particularly preferably 0.1% or lower.

(5) The light transmittance at a wavelength of 750 nm is preferably 30% or lower, more preferably 20% or lower, still more preferably 10% or lower, and particularly preferably 0.1% or lower.

(6) The light transmittance at a wavelength of 800 nm is preferably 30% or lower, more preferably 20% or lower, still more preferably 10% or lower, and particularly preferably 0.1% or lower.

(7) The light transmittance at a wavelength of 900 nm is preferably 30% or lower, more preferably 20% or lower, still more preferably 10% or lower, and particularly preferably 0.1% or lower.

The near-infrared absorbing filter can be appropriately selected depending on purposes, but the film thickness is preferably set to 20 μm or smaller, more preferably set to 10 μm or smaller, and still more preferably set to 5 μm or smaller. The lower limit of the film thickness is, for example, preferably 0.1 μm or greater, more preferably 0.2 μm or greater, and more preferably 0.3 μm or greater. According to the composition of the present invention, the composition has favorable near-infrared shielding properties, and thus it is possible to reduce the film thicknesses of the near-infrared absorbing filter.

In the near-infrared absorbing filter, the visible light transmittance at a film thickness of 20 μm or smaller in the full wavelength range of 400 to 550 nm is preferably 75% or higher and more preferably 90% or higher. In addition, the light transmittance is preferably 20% or lower in at least one point in a wavelength range of 700 nm or longer and shorter than 900 nm. According to the present invention, it is possible to ensure a wide visible light range with a high transmittance and provide near-infrared absorbing filters having favorable near-infrared shielding properties.

The near-infrared absorbing filter can be used for lenses having a function of absorbing and cutting near-infrared rays (optical lenses such as lenses for cameras such as digital cameras, mobile phones, and in-vehicle cameras, f-θ lenses, and pick-up lenses), optical filters for semiconductor light-receiving elements, near-infrared absorbing films or near-infrared absorbing plates that shield heat rays for energy saving, agricultural coating agents intended for selective use of sunlight, recording media in which near-infrared ray-absorbed heat is used, near-infrared absorbing filters for electronic devices or photographs, protective glasses, sunglasses, heat ray-shielding films, optical letter-read recording, prevention of copying classified documents, electrophotographic photoreceptors, laser fusion, and the like. In addition, the near-infrared absorbing filter is also useful for noise cut-off filters for CCD cameras and filters for CMOS image sensors.

<Method for Manufacturing Near-Infrared Absorbing Filter>

The near-infrared absorbing filter can be manufactured through a step of forming a film by applying the composition of the present invention (preferably by means of a dropwise addition method, coating, or printing) to a support and a step of drying the film. The film thickness, the laminate structure, and the like can be appropriately selected depending on purposes. In addition, a step of forming a pattern may be further carried out.

The step of forming a film can be carried out by applying the composition of the present invention to a support using a dropwise addition method (drop casting), spin coating, slit spin coating, screen printing, applicator coating, or the like. In the case of the dropwise addition method (drop casting), it is preferable to form a dropwise addition region of the near-infrared absorbing composition on a support using photoresists as partition walls so as to obtain a uniform film having a predetermined film thickness. Meanwhile, the film thickness can be adjusted by using the dropwise addition amount and solid content concentration of the composition and the area of the dropwise addition region.

The support to which the composition of the present invention is applied may be a transparent substrate made of glass or the like. In addition, the support may be a solid image pickup element substrate. In addition, the support may be a separate substrate provided on the light-receiving side of a solid image pickup element substrate. In addition, the support may be a layer such as a flattening layer provided on the light-receiving side of a solid image pickup element substrate.

In the step of drying the film, drying conditions vary depending on the kind and used proportions of individual components and a solvent; however, generally, the film is dried at a temperature in a range of 60 to 150° C. for approximately 30 seconds to 15 minutes.

Examples of the step for forming a pattern include methods including a step of forming a film-like composition layer by applying the composition of the present invention onto the support, a step of exposing the composition layer in a pattern shape, and a step of forming a pattern by removing non-exposed portions by means of development. In the step of forming a pattern, a pattern may be formed using a photolithography method or a pattern may be formed using a dry etching method.

The method for manufacturing the near-infrared absorbing filter may also include other steps. Other steps are not particularly limited and can be appropriately selected depending on purposes. Examples thereof include a surface treatment step of the base material, a preheating step (prebaking step), a curing treatment step, a post heating step (post baking step), and the like.

<<Preheating Step and Post Heating Step>>

The heating temperatures in the preheating step and the post heating step are generally in a range of 80° C. to 200° C. and preferably in a range of 90° C. to 150° C. The heating durations in the preheating step and the post heating step are generally in a range of 30 seconds to 240 seconds and preferably in a range of 60 seconds to 180 seconds.

<<Curing Treatment Step>>

The curing treatment step refers to a step of carrying out a curing treatment on the formed film as necessary and the curing treatment improves the mechanical strength of the near-infrared absorbing filter.

The curing treatment step is not particularly limited and can be appropriately selected depending on purposes, and preferred examples thereof include a full-surface exposure treatment, a full-surface heating treatment, and the like. In the present invention, the meaning of “exposure” includes the irradiation of the surface with radioactive rays such as electron beams or X rays as well as with light rays having a variety of wavelengths.

The exposure is preferably carried out by means of irradiation with radioactive rays and, as the radioactive rays that can be used in the exposure, particularly, ultraviolet rays such as electron beams, KrF, ArF, g-rays, h-rays, or i-rays or visible light are preferably used.

Examples of the exposure method include stepper exposure, exposure using a high-pressure mercury lamp, and the like.

The exposure amount is preferably in a range of 5 to 3,000 mJ/cm², more preferably in a range of 10 to 2,000 mJ/cm², and particularly preferably in a range of 50 to 1,000 mJ/cm².

Examples of a method for the full-surface exposure treatment include a method in which the full surface of the formed film is exposed. In a case in which the near-infrared absorbing composition includes a polymerizable compound, the full-surface exposure accelerates the curing of polymerizable components in the film formed of the composition, makes the film further cured, and improves mechanical strength and durability.

A device for carrying out the full-surface exposure is not particularly limited and can be appropriately selected depending on purposes, and preferred examples thereof include ultraviolet (UV) steppers such as ultrahigh-pressure mercury lamps.

In addition, examples of the method for the full-surface heating treatment include a method in which the full surface of the formed film is heated. The heating of the full surface increases the film strength of patterns.

The heating temperature during the full-surface heating is preferably in a range of 120° C. to 250° C. and more preferably in a range of 160° C. to 220° C. When the heating temperature is 120° C. or higher, the heating treatment improves film strength, and, when the heating temperature is 250° C. or lower, components in the film are decomposed and it is possible to prevent the film from becoming weak and brittle.

The heating duration in the full-surface heating is preferably in a range of 3 minutes to 180 minutes and more preferably in a range of 5 minutes to 120 minutes.

A device for carrying out the full-surface heating is not particularly limited and can be appropriately selected from well-known devices depending on purposes, and examples thereof include a drying oven, a hot plate, an infrared (IR) heater, and the like.

<Infrared Sensor>

An infrared sensor of the present invention has an infrared transmitting filter and a near-infrared absorbing filter and detects objects by detecting light having wavelengths of 700 nm or longer and shorter than 900 nm, and the near-infrared absorbing filter includes a near-infrared absorbing substance having a maximum absorption wavelength at a wavelength of 700 nm or longer and shorter than 900 nm.

According to the infrared sensor of the present invention, since the near-infrared absorbing filter includes a near-infrared absorbing substance having a maximum absorption wavelength at a wavelength of 700 nm or longer and shorter than 900 nm, in the near-infrared absorbing filter, it is possible to efficiently shield light derived from visible light and produce infrared sensors having favorable sensor sensitivity.

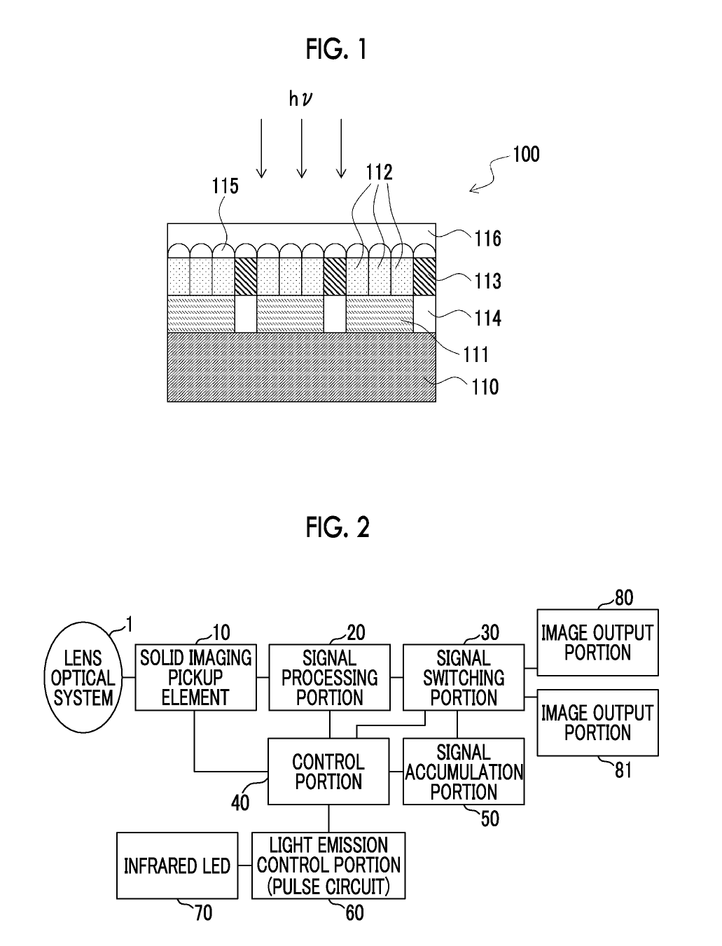

Hereinafter, an embodiment of the infrared sensor of the present invention will be described using FIG. 1.

In an infrared sensor 100 illustrated in FIG. 1, Reference Sign 110 indicates a solid image pickup element substrate.

Imaging regions provided on the solid image pickup element substrate 110 has a near-infrared absorbing filter 111 and color filters 112.

A region 114 in which the near-infrared absorbing filter 111 is not formed is provided between the infrared transmitting filter 113 and the solid image pickup element substrate 110. Microlenses 115 are disposed on an incidence ray hν side of the color filters 112 and the infrared transmitting filters 113. A flattening layer 116 is formed so as to cover the microlenses 115.

In an embodiment illustrated in FIG. 1, the color filters 112 are provided on the incidence ray hν side of the near-infrared absorbing filters 111, but the order of the near-infrared absorbing filter 111 and the color filter 112 may be switched with each other, or the near-infrared absorbing filter 111 may be provided on the incidence ray hν side of the color filters 112.

In addition, in the embodiment illustrated in FIG. 1, the near-infrared absorbing filter 111 and the color filter 112 are adjacently laminated together, but both filters do not need to be adjacent to each other at all times, and other layers may be provided therebetween.

In addition, in the embodiment illustrated in FIG. 1, the near-infrared absorbing filter 111 and the color filter 112 are provided as separate members, it is also possible to provide the function of near-infrared absorbing filters to the color filters 112 by adding the near-infrared absorbing substance to the color filters 112. In this case, the near-infrared absorbing filters 111 may not be provided.

The infrared sensor of the present invention comprises the near-infrared absorbing filter therein, and thus near-infrared absorbing filters serving as camera modules become unnecessary, the number of components in camera modules can be reduced, and the size reduction of camera modules is possible.

<<Near-Infrared Absorbing Filter 111>>

The near-infrared absorbing filter 111 includes a near-infrared absorbing substance having a maximum absorption wavelength at a wavelength of 700 nm or longer and shorter than 900 nm and can be formed using near-infrared absorbing compositions. The maximum absorption wavelength is preferably almost the same as the light emission wavelength of infrared LEDs (infrared light-emitting diodes) described below, and the difference between both maximum absorption wavelengths is preferably 20 nm or smaller and more preferably 10 nm or smaller. The near-infrared absorbing substance is preferably a pyrrolopyrrole compound, and the compound represented by General Formula (1) is preferably used.

In addition, the near-infrared absorbing filter 111 is preferably formed by curing the above-described composition of the present invention. The near-infrared absorbing filter 111 preferably has the same light transmitting properties as those of the above-described near-infrared absorbing filter. The near-infrared absorbing filter 111 can be produced in the same manner as the above-described near-infrared absorbing filter.

<<Color Filter 112>>

The color filter 112 is not particularly limited, and well-known color filters for forming pixels in the related art can be used. Regarding the color filter, it is possible to refer to, for example, the description in Paragraphs “0214” to “0263” of JP2014-043556A, the content of which is incorporated into the specification of the present application.

<Infrared Transmitting Filter 113>

As a method for forming the infrared transmitting filter 113, it is possible to employ methods such as a method in which a coloring radiation-sensitive composition (infrared transmitting composition) described below is prepared and an infrared transmitting filter is provided using a lithographic method or a method in which an infrared transmitting filter is provided using an ink jet method.

For the infrared transmitting filter 113, the characteristics are selected depending on the light emission wavelengths of infrared LEDs described below. For example, what has been described above will be described with an assumption that the light emission wavelength of an infrared LED is 830 nm.

For the infrared transmitting filter 113, the maximum value of the light transmittance in the film thickness direction in a wavelength range of 400 to 650 nm (more preferably in a wavelength range of 400 to 750 nm) is preferably 30% or lower, more preferably 20% or lower, still more preferably 15% or lower, particularly preferably 10% or lower, and far still more preferably 0.1% or lower. This transmittance preferably satisfies the above-described condition in the full wavelength range of 400 to 650 nm. The maximum value in a wavelength range of 400 to 650 nm is generally 0.1% or higher.

For the infrared transmitting filter 113, the minimum value of the light transmittance in the film thickness direction in a wavelength range of 800 nm or longer (more preferably in a wavelength range of 800 to 1,300 nm and still more preferably in a wavelength range of 900 to 1,300 nm) is preferably 70% or higher, more preferably 80% or higher, still more preferably 90% or higher, particularly preferably 98% or higher, and far still more preferably 99.9% or higher. This transmittance preferably satisfies the above-described condition in a part of a wavelength range of 800 nm or longer and preferably satisfies the above-described condition at wavelengths corresponding to the light emission wavelengths of infrared LEDs described below. The minimum value in a wavelength range of 900 to 1,300 nm is generally 99.9% or lower.

The film thickness is preferably 100 μm or smaller, more preferably 15 μm or smaller, still more preferably 5 μm or smaller, and particularly preferably 1 μm or smaller. The lower limit value thereof is preferably 0.1 μm. When the film thickness is in the above-described range, it is possible to produce films satisfying the above-described spectroscopic characteristics.

Methods for measuring the spectroscopic characteristics, film thickness, and the like of films will be described below.

The film thickness was measured from a dried substrate including a film using a stylus surface profiler (DEKTAK150 manufactured by ULVAC, Inc.).

The spectroscopic characteristics of the film are the values of transmittance measured in a wavelength range of 300 to 1,300 nm using a spectrophotometer (ref. a glass substrate) of a UV-VIS-NIR spectrophotometer (U-4100 manufactured by Hitachi High-Technologies Corporation).

The above-described transmittance conditions may be achieved using any means, and, for example, the above-described light transmittance conditions can be preferably achieved by adding two or more kinds of pigments to the composition and adjusting the kinds and contents of the respective pigments.

The infrared transmitting filter 113 can be produced using, for example, a colorant described below (preferably a coloring radiation-sensitive composition including a colorant containing two or more kinds of colorants selected from a red colorant, a yellow colorant, a blue colorant, and a violet colorant (infrared transmitting composition)), and, as the colored radiation-sensitive composition, a black composition is preferably used. The coloring radiation-sensitive composition may also include a pigment dispersant, a pigment derivative, a polymer compound, a curable compound, a polymerization innitiator, an alkali-soluble resin, a solvent, a surfactant, a polymerization inhibitor, and the like in addition to the above-described colorant. Regarding the curable compound, the polymerization innitiator, the alkali-soluble resin, the surfactant, the polymerization inhibitor, and the solvent, it is possible to refer to those described in the section of the above-described composition of the present invention, and preferred ranges thereof are also identical.

<<Colorant>>

The colorant may be a pigment or a dye. The pigment is preferably an organic pigment, and examples thereof include the following pigments. However, the present invention is not limited thereto.

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, and the like (all yellow pigments),

C. I. Pigment Orange 2, 5, 13, 16, 17:1, 31, 34, 36, 38, 43, 46, 48, 49, 51, 52, 55, 59, 60, 61, 62, 64, 71, 73, and the like (all orange pigments),

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, and the like (all red pigments),

C. I. Pigment Green 7, 10, 36, 37, 58, and the like (all green pigments),

C. I. Pigment Violet 1, 19, 23, 27, 32, 37, 42, and the like (all violet pigments),

C. I. Pigment Blue 1, 2, 15, 15:1, 15:2, 15:3, 15:4, 15: 6, 16, 22, 60, 64, 66, 79, 80, and the like (all blue pigments),

C. I. Pigment Black 1, 7, and the like (all black pigments)

These organic pigments can be used singly, or a combination of a variety of organic pigments can be used.

The dye is not particularly limited, and well-known dyes for color filters in the related art can be used.

As chemical structures, pyrazole azo-based, anilino azo-based, triphenylmethane-based, anthraquinone-based, anthrapyridone-based, benzylidene-based, oxonol-based, pyrazolotriazole azo-based, pyridone azo-based, cyanine-based, phenothiazine-based, pyrrolopyrazole azomethine-based, xanthene-based, phthalocyanine-based, benzopyran-based, indigo-based, pyrromethene-base dyes can be used. In addition, polymers of these dyes may also be used.

In addition, there are cases in which acidic dyes and/or derivatives thereof can be preferably used as the dye.

Additionally, it is also possible to usefully use direct dyes, basic dyes, mordant dyes, acidic mordant dyes, azoic dyes, dispersed dyes, oil-soluble dyes, food dyes, and/or derivatives thereof.

Hereinafter, specific examples of acid dyes will be listed, but the acid dyes are not limited thereto. Examples thereof include dyes below and derivatives of these dyes.

acid alizarin violet N,

acid black 1, 2, 24, 48,

acid blue 1, 7, 9, 15, 18, 23, 25, 27, 29, 40 to 45, 62, 70, 74, 80, 83, 86, 87, 90, 92, 103, 112, 113, 120, 129, 138, 147, 158, 171, 182, 192, 243, 324:1,

acid chrome violet K,

acid Fuchsin; acid green 1, 3, 5, 9, 16, 25, 27, 50,

acid orange 6, 7, 8, 10, 12, 50, 51, 52, 56, 63, 74, 95,

acid red 1, 4, 8, 14, 17, 18, 26, 27, 29, 31, 34, 35, 37, 42, 44, 50, 51, 52, 57, 66, 73, 80, 87, 88, 91, 92, 94, 97, 103, 111, 114, 129, 133, 134, 138, 143, 145, 150, 151, 158, 176, 183, 198, 211, 215, 216, 217, 249, 252, 257, 260, 266, 274,

acid violet 6B, 7, 9, 17, 19,

acid yellow 1, 3, 7, 9, 11, 17, 23, 25, 29, 34, 36, 42, 54, 72, 73, 76, 79, 98, 99, 111, 112, 114, 116, 184, 243,

Food Yellow 3

In addition, other than the above-described dyes, azo-based, xanthene-based, and phthalocyanine-based acid dyes are also preferred, and acidic dyes such as C. I. Solvent Blue 44, 38; C. I. Solvent orange 45; Rhodamine B, Rhodamine 110 and derivatives thereof are also preferably used.

Among these, the dye is preferably a colorant selected from triarylmethane-based, anthraquinone-based, azomethine-based, benzylidene-based, oxonol-based, cyanine-based, phenothiazine-based, pyrrolopyrazole azomethine-based, xanthene-based, phthalocyanine-based, benzopyran-based, indigo-based, pyrazole azo-based, anilinoazo-based, pyrazolotriazole azo-based, pyridone azo-based, anthrapyridone-based, and pyrromethene-based dyes.

Furthermore, a combination of the pigment and the dye may also be used.

Regarding the average particle size in the pigment that can be used as the colorant and a method for miniaturizing the pigment, it is possible to refer to the description of Paragraphs “0080” to “0085” in JP2013-064993A, the content of which is incorporated into the specification of the present application.

A preferred aspect of the colorant preferably includes two or more colorants selected from a red colorant, a blue colorant, and a violet colorant and more preferably includes a red colorant, a yellow colorant, a blue colorant, and a violet colorant. A preferred specific example thereof preferably includes C. I. Pigment Red 254 as the red pigment, C. I. Pigment Yellow 139 as the yellow pigment, C. I. Pigment Blue 15:6 as the blue pigment, and C. I. Pigment Violet 23 as the violet pigment.

In a case in which the colorant added to the coloring radiation-sensitive composition is a combination of a red colorant, a yellow colorant, a blue colorant, and a violet colorant, the mass ratio of the red colorant to the full amount of the colorant is in a range of 0.2 to 0.5, the mass ratio of the yellow colorant is in a range of 0.1 to 0.2, the mass ratio of the blue colorant is in a range of 0.25 to 0.55, and the mass ratio of the violet colorant is in a range of 0.05 to 0.15.

In addition, the mass ratio of the red colorant to the full amount of the colorant is in a range of 0.3 to 0.4, the mass ratio of the yellow colorant is in a range of 0.1 to 0.2, the mass ratio of the blue colorant is in a range of 0.3 to 0.4, and the mass ratio of the violet colorant is in a range of 0.05 to 0.15.

The content of the pigments in the colorant is preferably 95% by mass or higher, more preferably 97% by mass or higher, and still more preferably 99% by mass or higher of the full amount of the colorant. The upper limit of the content of the pigments in the colorant is 100% by mass or lower of the full amount of the colorant.

The content of the colorant in the composition of the present invention is preferably in a range of 20% to 70% by mass, more preferably in a range of 25% to 65% by mass, and still more preferably in a range of 30 to 60% by mass of the total solid contents of the composition.

In a case in which the coloring radiation-sensitive composition include the pigment, the coloring radiation-sensitive composition may be prepared by dispersing the pigment together with other components such as a pigment dispersant, an organic solvent, a pigment derivative, and a polymer compound as necessary so as to prepare a pigment dispersion liquid, and mixing the obtained pigment dispersion liquid with other components that are added as necessary. As other components, the same materials as the materials (other than the near-infrared absorbing substance) used for the near-infrared absorbing composition can be used.

Hereinafter, the composition of the pigment dispersion liquid and a method for dispersing the pigment dispersion liquid will be described in detail.

A method for preparing the pigment dispersion liquid is not particularly limited, and, in the dispersion method, for example, a substance in which the pigment, the pigment dispersant, and the like are mixed together in advance and are dispersed in advance using a homogenizer or the like can be finely dispersed using a bead disperser (for example, DISPERMAT manufactured by VMA-GETZMANN GMBH) in which zirconia beads are used.

<<Pigment Dispersant>>

Examples of the pigment dispersant that can be used to prepare the pigment dispersion liquid include polymer dispersants [for example, polyamidoamine and salts thereof, polycarboxylic acid and salts thereof, high-molecular-weight unsaturated acid esters, modified polyurethane, modified polyesters, modified poly(meth)acrylates, (meth)acryl-based copolymers, and naphthalene sulfonic acid formalin condensates), surfactants such as polyoxyethylenealkyl phosphoric acid esters, polyoxyethylene alkyl amine, and alkanolamines, pigment derivatives, and the like.

The polymer dispersants can be further classified into linear polymers, terminal-modified polymers, graft-type polymers, and block-type polymers on the basis of structures thereof.

Examples of terminal-modified polymers having an anchor portion to pigment surfaces include polymers having a phosphate group at the terminal described in JP1991-112992A (JP-H3-112992A) and JP2003-533455A, polymers having a sulfonate group at the terminal described in JP2002-273191A, polymers having a partial skeleton or heterocycle of an organic coloring agent described in JP1997-77994A (JP-H9-77994A), and the like. In addition, polymers having two or more anchor portions (acidic groups, basic groups, partial skeletons or heterocycles of organic coloring agents, or the like) to pigment surfaces introduced into polymer terminals described in JP2007-277514A are also excellent in terms of dispersion stability and are preferred.

Examples of graft-type polymers having an anchor portion to pigment surfaces include the reaction products between poly(lower alkyleneimine) and polyester described in JP1979-37082A (JP-S54-37082A), JP1996-507960A (JP-H8-507960A), JP2009-258668A, and the like, the reaction products between polyallylamine and polyester described in JP1997-169821A (JP-H9-169821A) and the like, the copolymers of a macromonomer and a nitrogen atom monomer described in JP1998-339949A (JP-H10-339949A) and JP2004-37986A, the graft-type polymers having a partial skeleton or heterocycle of an organic coloring agent described in JP2003-238837A, JP2008-94726A, JP2008-81732A, and the like, the copolymers of a macromonomer and an acidic group-containing monomer described in JP2010-106268A, and the like.

As macromonomers used to manufacture the graft-type polymers having an anchor portion to pigment surfaces by means of radical polymerization, well-known macromonomers can be used, and examples thereof include macromonomers AA-6 (polymethyl methacrylate having a methacryloyl group as a terminal group), AS-6 (polystyrene having a methacryloyl group as a terminal group), AN-6S (a copolymer of styrene and acrylonitrile having a methacryloyl group as a terminal group), and AB-6 (polybutyl acrylate having a methacryloyl group as a terminal group) which are all manufactured by Toagosei Co., Ltd., PLACCEL FM5 (2-hydroxyethyl methacrylate containing 5 molar equivalent of ε-caprolactone) and FA10L (2-hydroxyethyl acrylate containing 10 molar equivalent of ε-caprolactone) which are all manufactured by Daicel Corporation, polyeter-based macromonomers described in JP1990-272009A (JP-H2-272009A), and the like. Among these, polyester-based macromonomers which are particularly excellent in terms of flexibility and solvent affinity are preferred, and polyester-based macromonomers represented by the polyester-based macromonomers described in JP1990-272009A (JP-H2-272009A) are also preferred.

Block-type polymers having an anchor portion to pigment surfaces are preferably the block-type polymers described in JP2003-49110A, JP2009-52010A, and the like.

The pigment dispersant can be procured from commercially available products, and specific examples thereof include “DISPERBYK-101 (polyamide amine phosphoric acid salt), 107 (carboxylic acid ester), 110 (copolymer having an acidic group), 130 (polyamide), 161, 162, 163, 164, 165, 166, and 170 (high-molecular-weight copolymers)” and “BYK-P104 and P105 (high-molecular-weight unsaturated polycarboxylic acids)” all manufactured by BYK-Chemie GmbH, “EFKA4047, 4050 to 4010 to 4165 (polyurethane-based), EFKA4330 to 4340 (blocked copolymers), 4400 to 4402 (modified polyacrylates), 5010 (polyester amide), 5765 (high-molecular-weight polycarboxylate), 6220 (fatty acid polyester), 6745 (phthalocyanine derivative), and 6750 (azo pigment derivative)” manufactured by EFKA Additives Inc., “AJISUPER PB821, PB822, PB880, and PB881” manufactured by Ajinomoto Fine Techno Co., Inc., “FLOWLEN TG-710 (urethane oligomer)”, “POLYFLOW No. 50E and No. 300 (acryl-based copolymer)” manufactured by Kyoeisha Chemical Co. Ltd., “DISPARLON KS-860, 873SN, 874, and #2150 (aliphatic polyvalent carboxylic acids), #7004 (polyether ester), DA-703-50, DA-705, and DA-725” manufactured by Kusumoto Chemicals, Ltd., “DEMOL RN and N (naphthalene sulfonate formaldehyde condensates), MS, C, and SN-B (aromatic sulfonate formaldehyde condensates)”, “HOMOGENOL L-18 (polymer polycarboxylic acid)”, “EMULGEN920, 930, 935, and 985 (polyoxyethylene nonyl phenyl ethers)”, and “ACETAMIN86 (stearyl amine acetate)” manufactured by Kao Corporation, “SOLSPERSE5000 (phthalocyanine derivative), 22000 (azo pigment derivative), 13240 (polyester amine), 3000, 17000, and 27000 (polymers having a functional portion at the terminal), and 24000, 28000, 32000, and 38500 (graft-type polymers)” manufactured by The Lubrizol Corporation, “NIKKOL T106 (polyoxyethylene sorbitan monooleate) and MYS-IEX (polyoxyethylene monostearate) manufactured by Nikko Chemical Co., Ltd., “HINOACT T-8000E” and the like manufactured by Kawaken Fine Chemicals Co., Ltd., “organosiloxane polymer KP341” manufactured by Shin-Etsu Chemical Co., Ltd., “W001: cationic surfactant” manufactured by Yusho Co., Ltd., nonionic surfactants such as polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid ester, anionic surfactants such as “W004, W005, and W017”, “EFKA-46, EFKA-47, EFKA-47EA, EFKA polymer 100, EFKA polymer 400, EFKA polymer 401, and EFKA polymer 450” manufactured by Morishita Co., Ltd., polymer dispersants such as “DISPERSE AID 6, DISPERSE AID 8, DISPERSE AID 15, and DISPERSE AID 9100” manufactured by San Nopco Limited, “ADEKA PLURONIC L31, F38, L42, L44, L61, L64, F68, L72, P95, F77, P84, F87, P94, L101, P103, F108, L121, and P-123” manufactured by ADEKA Corporation, “IONET S-20” manufactured by Sanyo Chemical Industries, and the like.

The pigment dispersant may be used singly, or a combination of two or more pigment dispersants may be used.

The content of the pigment dispersant in the pigment dispersion liquid is preferably in a range of 1 to 80 parts by mass, more preferably in a range of 5 to 70 parts by mass, and still more preferably in a range of 10 to 60 parts by mass with respect to 100 parts by mass of the pigment.

In a case in which the polymer dispersant is used, the amount of the pigment dispersant is preferably in a range of 5 to 100 parts and more preferably in a range of 10 to 80 parts with respect to 100 parts by mass of the pigment in terms of mass.

<<Pigment Derivative>>

The pigment derivative is a compound having a structure formed by substituting a part of an organic pigment with an acidic group, a basic group, or a phthalimidomethyl group. The coloring radiation-sensitive composition preferably includes a pigment derivative having an acidic group or a basic group from the viewpoint of dispersability and dispersion stability.

Examples of an organic pigment for constituting the pigment derivative include diketopyrrolopyrrole-based pigments, azo-based pigments, phthalocyanine-based pigments, anthraquinone-based pigments, quinacridone-based pigments, dioxazine-based pigments, perinone-based pigments, perylene-based pigments, thioindigo-based pigments, isoindoline-based pigments, isoindolinone-based pigments, quinophthalone-based pigments, threne-based pigments, metal complex-based pigments, and the like.

Particularly, the pigment derivative is preferably a quinoline-based, benzimidazolone-based, or isoindoline-based pigment derivative and more preferably a quinoline-based or benzimidazolone-based pigment derivative.

The content of the pigment derivative in the pigment dispersion liquid is preferably in a range of 1% to 50% by mass and more preferably in a range of 3% to 30% by mass of the total mass of the pigment. Only one pigment derivative may be used, or two or more pigment derivatives may be jointly used.

In addition, in a case in which the pigment derivatives are jointly used, the amount of the pigment derivatives used is preferably in a range of 1 to 30 parts, more preferably in a range of 3 to 20 parts, and particularly preferably in a range of 5 to 15 parts with respect to 100 parts by mass of the pigment in terms of mass.

<<Solvent that Pigment Dispersion Liquid may Include>>

The pigment dispersion liquid preferably includes a solvent. As the solvent, the above-described solvents can be used. The content of the solvent in the pigment dispersion liquid is preferably in a range of 40% to 95% by mass and more preferably in a range of 70% to 90% by mass.

<<Polymer Compound>>

Example of the polymer compound that can be used to prepare the pigment dispersion liquid include polyamideamines and salts thereof, polycarboxylic acid and salts thereof, high-molecular-weight unsaturated acid esters, modified polyurethane, modified polyesters, modified poly(meth)acrylates, (meth)acryl-based copolymers (particularly, (meth)acrylate-based copolymers having a carboxylate group and a polymerizable group in a side chain are preferred), and naphthalene sulfonic acid formalin condensates), and the like. These polymer materials are adsorbed to the surfaces of the pigment and act so as to prevent re-agglomeration, and thus terminal modified-type polymers, graft-type polymers, and block-type polymers which have an anchor portion to pigment surfaces are preferred, and examples thereof include graft copolymers having a monomer having a heterocycle and a polymerizable oligomer having an ethylenic unsaturated bond as a copolymer unit.

Examples of other polymer materials further include polyamidoamine phosphate, high-molecular-weight unsaturated polycarboxylic acids, polyether esters, aromatic sulfonate formaldehyde condensates, polyoxyethylene nonyl phenyl ether, polyester amines, polyoxyethylene sorbitan monooleate polyoxyethylene monostearate, and the like.

These polymer materials may be used singly, or a combination of two or more polymer materials may be used. The content of the polymer material in the pigment dispersion liquid is preferably in a range of 20% to 80% by mass, more preferably in a range of 30% to 70% by mass, and still more preferably in a range of 40% to 60% by mass of the pigment.

Next, as an example to which the infrared sensor of the present invention is applied, an imaging device will be described.

FIG. 2 is a function block diagram of the imaging device. The imaging device comprises a lens optical system 1, a solid image pickup element 10, a signal processing portion 20, a signal switching portion 30, a control portion 40, a signal accumulation portion 50, a light emission control portion 60, an infrared LED 70 (having light emission wavelengths preferably in a range of 700 to 900 nm and more preferably in a range of 800 to 900 nm) of a light-emitting element that emits infrared light, and image output portions 80 and 81. Meanwhile, as the solid image pickup element 10, it is possible to use the above-described near-infrared sensor 100. In addition, all or part of constitutions except for the solid image pickup element 10 and the lens optical system 1 can also be formed on the same semiconductor substrate. Regarding the respective constitutions of the imaging device, it is possible to refer to Paragraphs “0032” to “0036” of JP2011-233983A, the content of which is incorporated into the specification of the present application. In the imaging device, it is possible to embed a camera module having a solid image pickup element and the above-described near-infrared absorbing filter.

<Compound>

A compound of the present invention is the compound represented by General Formula (1) which has been described in the section of the composition of the present invention, and preferred examples are also identical.

In a chloroform solution, the compound of the present invention preferably has a maximum absorption wavelength at 650 nm or longer and shorter than 900 nm, more preferably has a maximum absorption wavelength in a range of 700 to 860 nm, and still more preferably has a maximum absorption wavelength in a range of 750 nm to 850 nm.

The compound of the present invention can be preferably used to form, for example, near-infrared absorbing filters and the like which shield light having wavelengths of 700 nm or longer and shorter than 900 nm. In addition, the compound can also be used as photoelectric conversion materials in near-infrared absorbing filters for solid image pickup elements such as plasma display panels (PDP) or CCD, optical filters in heat ray-shielding films, compact disc-recordable (CD-R) or flash fusing materials. In addition, the composition can also be used as information display materials in security ink or invisible barcodes.

<Curable Composition>

A curable composition of the present invention includes the compound represented by General Formula (1). The compound represented by General Formula (1) is identical to the compound represented by General Formula (1), and a preferred range thereof is also identical.

In addition, the curable composition of the present invention may include components other than the compound represented by General Formula (1) which have been described in the section of the above-described near-infrared absorbing composition and preferably includes the above-described curable compound.

<Kit>

The present invention also relates to a kit including the near-infrared absorbing composition of the present invention and a coloring radiation-sensitive composition used in the above-described infrared transmitting filter. Regarding the details thereof, the above description can be referred to, and a preferred range thereof is also identical.

### EXAMPLES

Hereinafter, the present invention will be more specifically described using examples. Materials, amounts used, proportions, the contents of treatments, the orders of treatments, and the like described in the following examples can be appropriately changed within the scope of the gist of the present invention. Therefore, the scope of the present invention is not limited to specific examples described below. Particularly, unless particularly otherwise described, “%” and “parts” are on the basis of mass.

<Synthesis of Compound (A-1)>

A compound (A-1) was synthesized according to the following scheme.

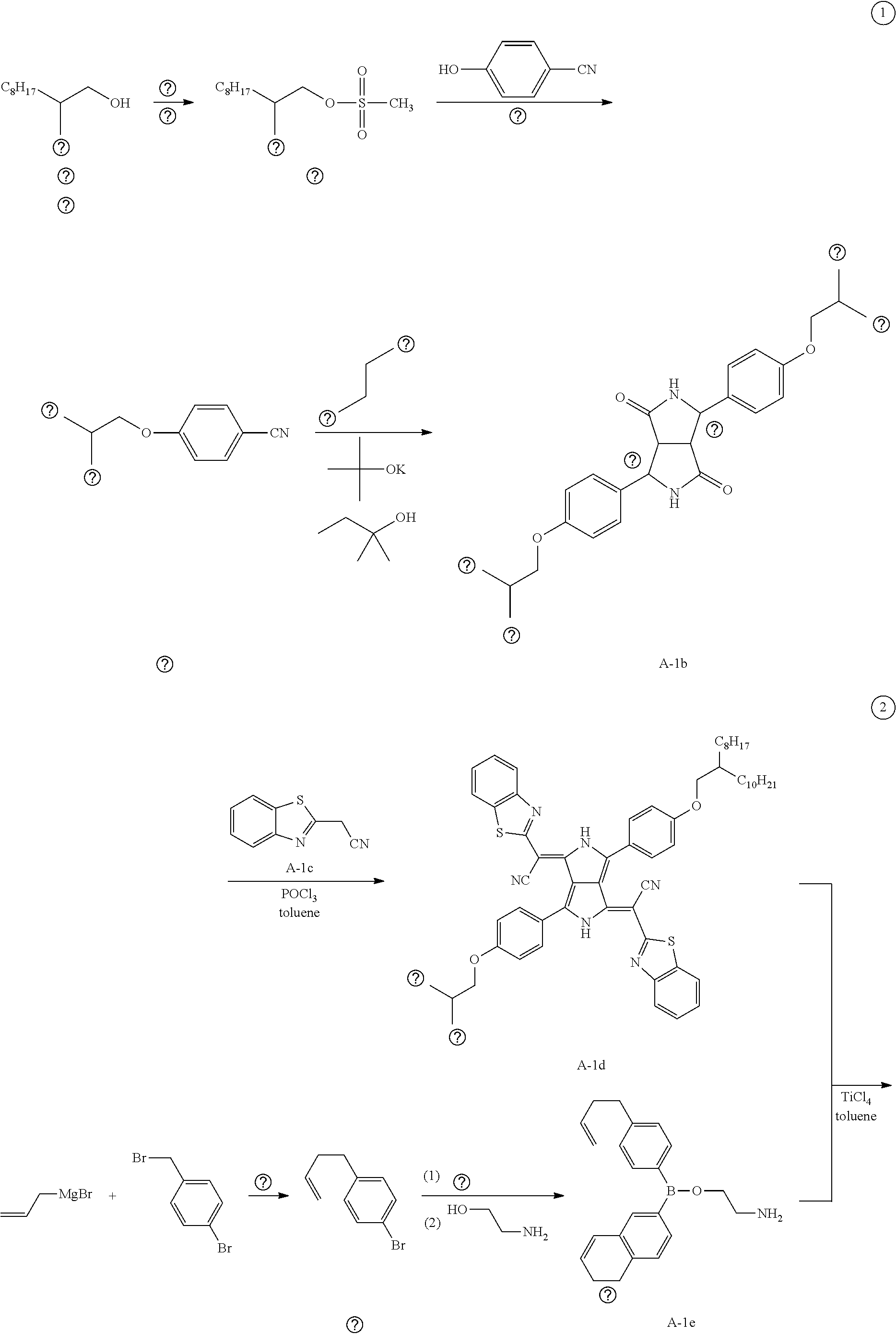

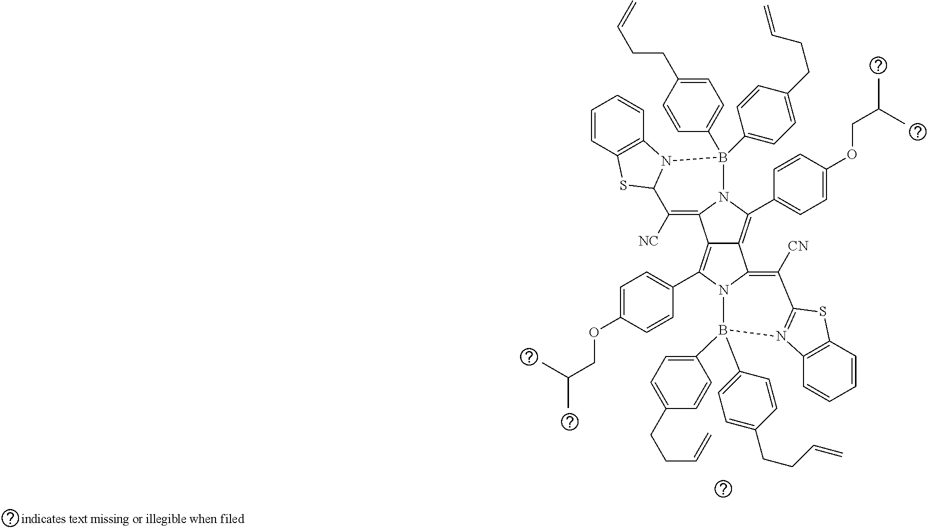

(Synthesis of Compound (A-1a))

Isoeicosanol (FINEOXOCOL 2000, manufactured by Nissan Chemical Industries, Ltd.) (20.0 parts by mass) and triethylamine (NEt₃) (8.13 parts by mass) were stirred in ethyl acetate (40 parts by mass), and methanesulfonyl chloride (8.44 parts by mass) was added dropwise thereto at −10° C. After the end of the dropwise addition, the components were reacted with each other for two hours at 30° C. An organic layer was removed by means of liquid separation operation, and the solvent was distilled away under reduced pressure, thereby obtaining a light yellow liquid (A-1a0 body) (25.5 parts by mass).

Subsequently, 4-cyanophenol (7.82 parts by mass) and potassium carbonate (10.1 parts by mass) were stirred in dimethylacetoamide (DMAc) (25 parts by mass), the (A-1a0 body) synthesized above (25.5 parts by mass) was added thereto, and the components were reacted with each other for six hours at 100° C. An organic layer was removed by means of liquid separation operation, the organic layer was washed with an aqueous solution of sodium hydroxide, and the solvent was distilled away under reduced pressure, thereby obtaining a compound (A-1a) (25.8 parts by mass) which was a light yellow liquid.

¹H-NMR (CDCl₃): δ0.55-0.96 (m, 18H), 0.96-2.10 (m, 21H), 3.88 (m, 2H), 6.93 (d, 2H), 7.56 (d, 2H)

(Synthesis of A-1b)

A diketopyrrolopyrrole compound (A-1b body) was synthesized using the compound (A-1a) synthesized above (13.1 parts by mass) as a raw material according to the method described in U.S. Pat. No. 5,969,154A, thereby obtaining a compound (A-1b) (7.33 parts by mass) which was an orange solid.

¹-NMR (CDCl₃): δ0.55-0.96 (m, 36H), 0.96-2.10 (m, 42H), 3.95 (m, 4H), 7.06 (d, 4H), 8.30 (d, 4H), 8.99 (brs, 2H)

(Synthesis of Compound (A-1d))

The compound (A-1b) (7.2 parts by mass) and 2-(2-benzothiazoryl) acetonitrile (3.42 parts by mass) were stirred in toluene (30 parts by mass), and phosphorus oxychloride (10.0 parts by mass) was added thereto and was heated and refluxed for five hours. An organic layer was removed by means of liquid separation operation, was washed with an aqueous solution of sodium hydroxide, and the solvent was distilled away under reduced pressure.

The obtained coarse product was purified by means of silica gel column chromatography (solvent: chloroform) and, furthermore, was recrystallized using a chloroform/acetonitrile solvent, thereby obtaining a compound (A-1d) (5.73 parts by mass) which was a green solid.

¹H-NMR (CDCl₃): δ0.55-1.00 (m, 36H), 1.00-2.10 (m, 42H), 3.97 (m, 4H), 7.11 (d, 4H), 7.28 (t, 2H), 7.43 (t, 2H), 7.67-7.75 (m, 6H), 7.80 (d, 2H), 13.16 (s, 2H)

(Synthesis of Compound (A-1e0))

4-Bromobenzyl bromide (manufactured by Tokyo Chemical Industry Co., Ltd.) (100 parts by mass) was added to dehydrated tetrahydrofuran (787 parts by mass), and was cooled to and stirred at −78° C. An allyl magnesium bromide solution (1 M diethyl ether solution, manufactured by sigma-Aldrich Co., LLC.) was added dropwise to the above-described reaction solution, was stirred for one hour at −78° C., and, furthermore, was stirred for one hour at room temperature. Distilled water (920 parts by weight) was added dropwise to the reaction solution, and an organic layer was removed by means of liquid separation operation, was washed with brine, and was dehydrated and dried using magnesium sulfate, and then the solvent was distilled away.

The obtained coarse product was purified by means of silica gel column chromatography (solvent: hexane, Rf=0.47), thereby obtaining (A-1e0) (80.6 parts by mass).

¹H-NMR (CDCl₃): δ2.34 (q, 2H), 2.66 (t, 2H), 5.00 (dd, 2H), 5.81 (m, 1H), 7.05 (d2, H), 7.39 (d, 2H)

(Synthesis of Compound (A-1e))

Magnesium (10.8 parts by mass) was added to dehydrated tetrahydrofuran (112 parts by mass), a solution of the compound (A-1e0) (78.8 parts by mass) and dehydrated tetrahydrofuran (235 parts by weight) was added dropwise to the reaction liquid, and was stirred, thereby preparing a Grignard reagent.

Tributhoxyborane (40.9 parts by weight) was added to dehydrated tetrahydrofuran (79 parts by weight) and was cooled to 5° C. The Grignard reagent was added dropwise to this reaction solution. After the end of the dropwise addition, the mixture was heated to 55° C., was stirred for one hour, and then was cooled to room temperature. A solvent mixture of concentrated hydrochloric acid (32.2 parts by mass) and water (100 parts by mass) was cooled in an ice bath, the reaction solution was added dropwise thereto, and then, heptane (800 parts by mass) was added dropwise thereto. An organic layer was removed by means of liquid separation operation and was washed with water, and the solvent was distilled away.

The obtained coarse product was purified by means of silica gel column chromatography (solvent; hexane:ethyl acetate=50:1, Rf=0.3 (hexane:ethyl acetate=5:1 developing solvent)).

The obtained purified substance was boiled together with heptane, was dissolved in heptane (800 parts by mass), and was cooled to 0° C. Ethanol (10.9 parts by weight) was added dropwise to the reaction solution at 0° C., thereby precipitating crystals. After the end of the dropwise addition, the components were stirred for one hour at room temperature, and the reaction liquid was filtered, thereby obtaining a compound (A-1e) (42.8 parts by mass).

¹H-NMR (CDCl₃): δ2.35 (q, 2H), 2.66 (t, 2H), 2.80 (bs, 2H), 3.84 (t, 2H), 4.10 (bs, 2H), 4.95 (dd, 2H), 5.03 (dd, 2H), 5.87 (m, 2H), 7.09 (d, 4H), 7.30 (d, 4H)

(Synthesis of Compound (A-1))

The compound (a-1e) (2.53 parts by mass) was stirred in toluene (70 parts by mass) at 40° C., titanium chloride (3.56 parts by mass) was added thereto, and the components were reacted with each other for 30 minutes. The compound (A-1d) (5.60 parts by mass) was added thereto and was heated and refluxed for one hour at an external temperature of 130° C. The mixture was cooled to room temperature, methanol (80 parts by mass) was added thereto so as to precipitate crystals, and the crystals were filtered. The obtained coarse crystal was purified by means of silica gel column chromatography (solvent: chloroform) and then, furthermore, was recrystallized using a toluene/methanol solvent, thereby obtaining a compound (A-1) (3.87 parts by mass) which is a green crystal that is a target compound.

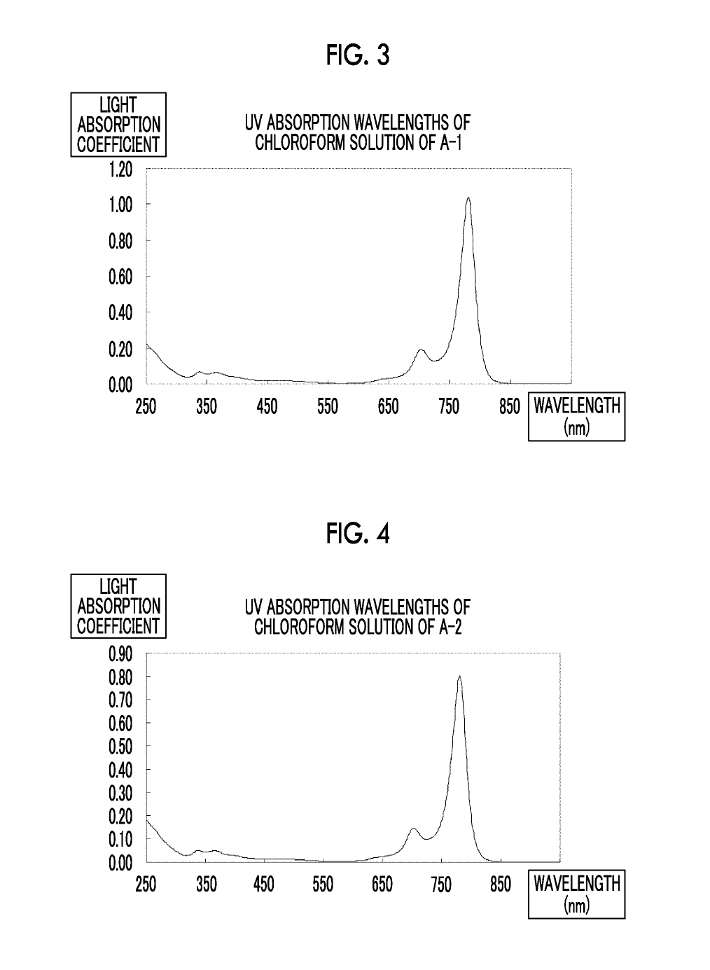

FIG. 3 is a view illustrating the spectroscopic characteristics of the compound (A-1) in a chloroform solution. The λmax of the compound (A-1) was 781 nm in chloroform. The molar absorption coefficient of the compound (A-1) was 2.17×10⁵ dm³/mol·cm in chloroform.

¹H-NMR (CDCl₃): δ0.55-1.01 (m, 36H), 1.01-2.10 (m, 42H), 3.81 (m, 4H), 4.99 (d, 2H), 5.05 (d, 2H), 5.80-5.95 (m, 4H), 6.43 (m, 8H), 6.81-7.11 (m, 14H), 7.11-7.22 (m, 8H), 7.47 (d, 2H)

<Synthesis of Compounds (A-2) and (A-3)>

Compounds (A-2) and (A-3) were synthesized according to the following scheme.

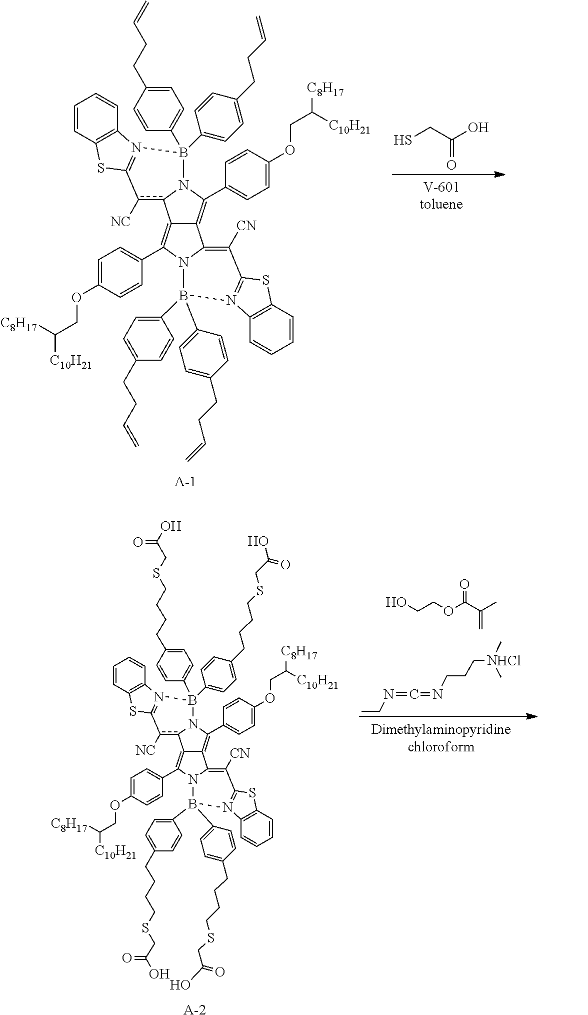

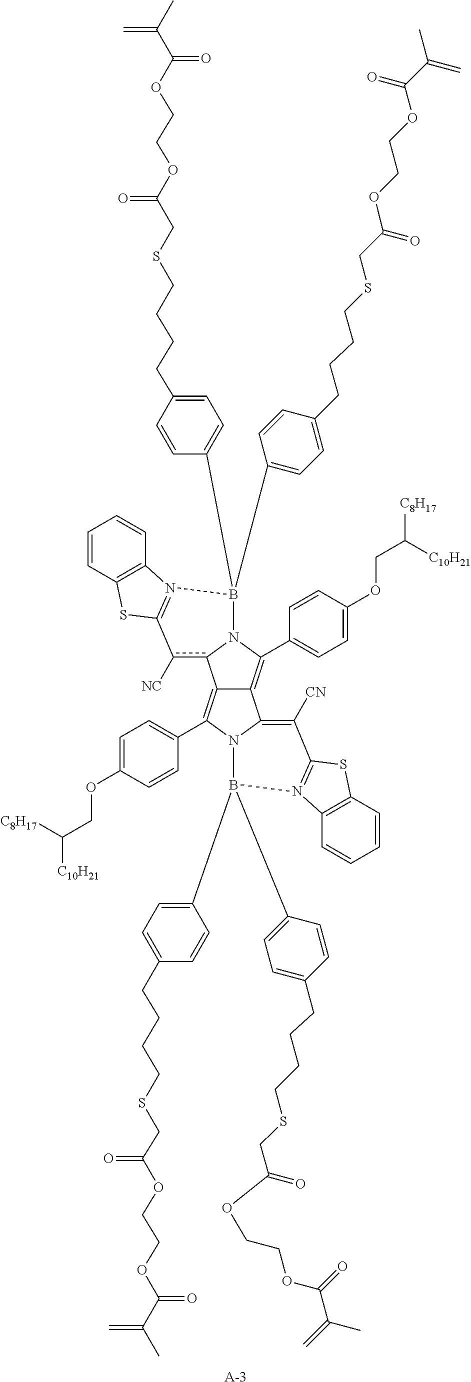

(Synthesis of Compound (A-2))

The compound (A-1) (6.00 parts by mass) and thioglycolic acid (9.54 parts by mass) were added to toluene (36.0 parts by mass) and were heated to 80° C. Dimethyl 2,2-azobis(2-methylpropionate) (V-601) (0.032 parts by mass) was added to the reaction liquid and was stirred for two hours at 80° C. The reaction liquid was cooled to room temperature and was dried under reduced pressure, toluene (10 parts by mass) was added thereto, and methanol (120 parts by mass) was added dropwise thereto. The precipitated crystals were filtered, thereby obtaining a compound (A-2) (6.86 parts by mass).

FIG. 4 is a view illustrating the spectroscopic characteristics of the compound (A-2) in a chloroform solution. The λmax of the compound (A-2) was 780 nm in chloroform. The molar absorption coefficient of the compound (A-2) was 2.08×10⁵ dm³/mol·cm in chloroform.

¹H-NMR (CDCl₃): δ0.55-1.01 (m, 36H), 1.01-2.10 (m, 42H), 3.81 (m, 4H), 4.99 (d, 2H), 5.05 (d, 2H), 5.80-5.95 (m, 4H), 6.43 (m, 8H), 6.81-7.11 (m, 14H), 7.11-7.22 (m, 8H), 7.47 (d, 2H)

(Synthesis of Compound (A-3))

The compound (A-2) (4.00 parts by mass), 2-hydroxyethyl methacrylate (0.99 parts by mass), and dimethylaminopyridine (0.93 parts by mass) were added to chloroform (not including ethanol, but containing amylene) (60 parts by mass), then, 1-ethyl-3-(3-dimethylaminopropyl)carbodiimide hydrochloride salt (1.18 parts by mass) was added thereto, and the components were stirred for one hour. The reaction liquid was neutralized by adding 1 N hydrochloric acid thereto, liquid separation operation was carried out by adding distilled water, the obtained organic layer was washed with distilled water, and the solvent was distilled away. Toluene (15 parts by mass) was added to the obtained solid, methanol (200 parts by mass) was added dropwise thereto, and the components were stirred at room temperature, thereby precipitating crystals. The obtained crystals were filtered, thereby obtaining a compound (A-3) (3.9 parts by mass).

The λmax of the compound (A-3) was 780 nm in chloroform. The molar absorption coefficient of the compound (A-3) was 2.05×10⁵ dm³/mol·cm in chloroform.

¹H-NMR (CDCl₃): δ0.55-1.01 (m, 36H), 1.01-2.10 (m, 42H), 3.81 (m, 4H), 5.5 (d, 4H), 6.2 (d, 4H), 6.43 (m, 8H), 6.81-7.11 (m, 14H), 7.11-7.22 (m, 8H), 7.47 (d, 2H)

<Synthesis of Compounds (A-4) and (A-5)>

(Synthesis of Compound (A-4a), Compound (A-4b), Compound (A-4d), and Compound (A-4f))

A compound (A-4a), a compound (A-4b), a compound (A-4d), and a compound (A-4f) were synthesized using the same methods for the compound (A-1a), the compound (A-1b), the compound (A-1d), and the compound (A-1), respectively.

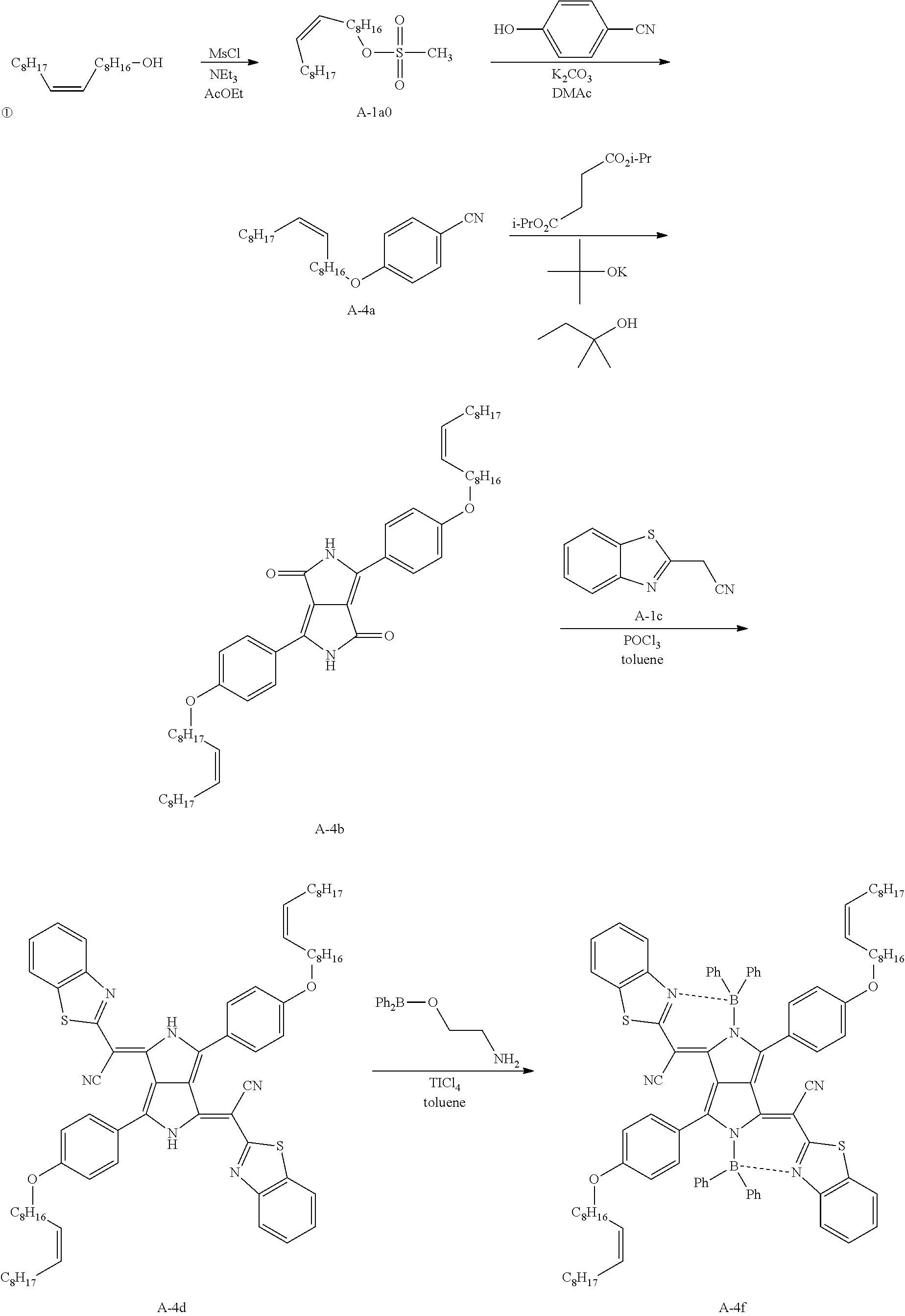

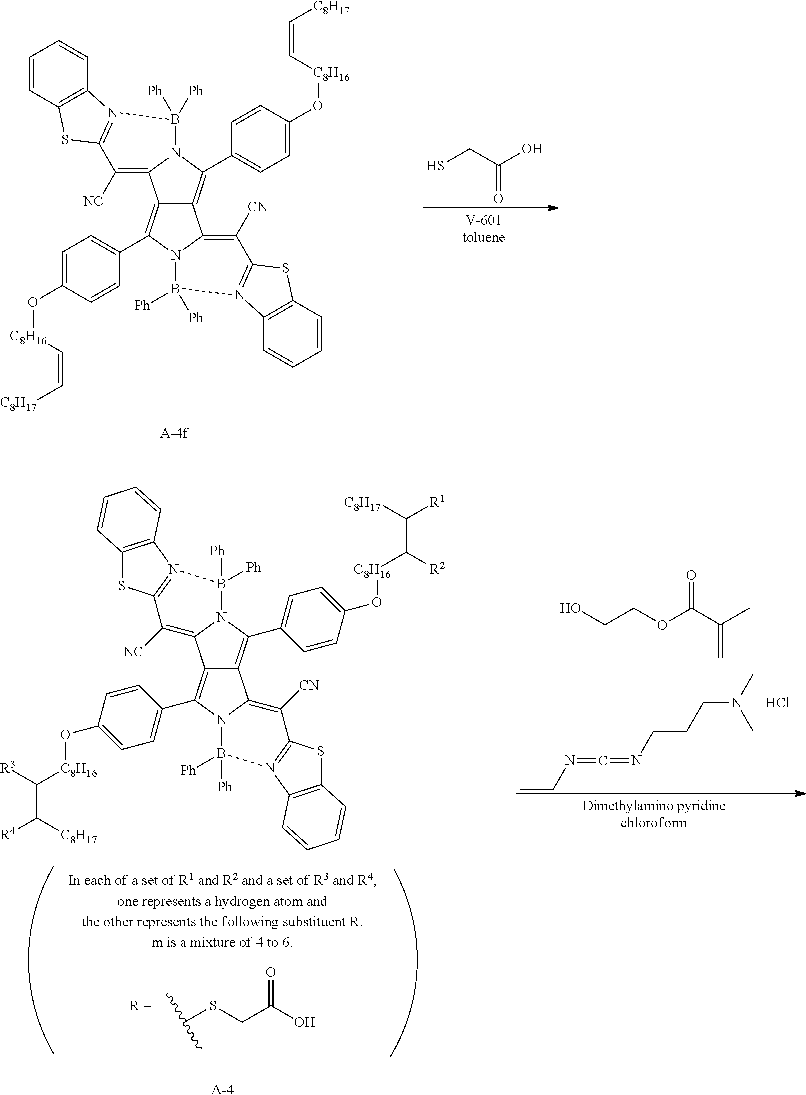

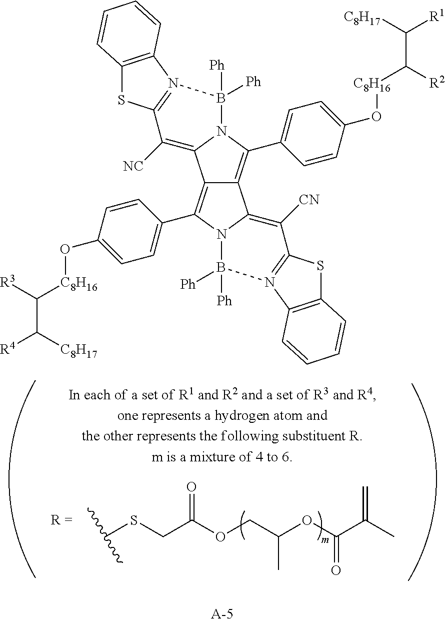

(Synthesis of Compound (A-4))

The compound (A-4f) (30 parts by mass) and thioglycolic acid (28.3 parts by mass) were added to toluene (300 parts by mass) and were heated to 80° C. Dimethyl 2,2-azobis(2-methylpropionate) (17.0 parts by mass) was added to the reaction liquid and was stirred for two hours at 80° C. Dimethyl 2,2-azobis(2-methylpropionate) (10.0 parts by mass) was further added to the reaction liquid and was stirred for two hours. The reaction liquid was cooled to room temperature and was dried under reduced pressure, toluene (150 parts by mass) was added thereto, and methanol (600 parts by mass) was added dropwise thereto. The precipitated crystals were filtered, thereby obtaining a compound (A-4) (24.5 parts by mass).

The λmax of the compound (A-4) was 781 nm in chloroform. The molar absorption coefficient of the compound (A-4) was 1.93×10⁵ dm³/mol·cm in chloroform.

(Synthesis of Compound (A-5))

A-4 (6.00 parts by mass), 2-hydroxyethyl methacrylate (3.13 parts by mass), and dimethylaminopyridine (1.78 parts by mass) were added to chloroform (not including ethanol, but containing amylene) (60 parts by mass), then, 1-ethyl-3-(3-dimethylaminopropyl)carbodiimide hydrochloride salt (2.26 parts by mass) was added thereto, and the components were stirred for one hour. The reaction liquid was neutralized by adding 1 N hydrochloric acid thereto, and liquid separation operation was carried out by adding distilled water. Toluene (60 parts by mass) was added to the obtained solid, methanol (600 parts by mass) was added dropwise thereto, and the components were stirred at room temperature, thereby precipitating crystals. The obtained crystals were filtered, thereby obtaining a compound (A-5) (5.78 parts by mass).

The λmax of the compound (A-5) was 781 nm in chloroform. The molar absorption coefficient of the compound (A-5) was 2.05×10⁵ dm³/mol·cm in chloroform.

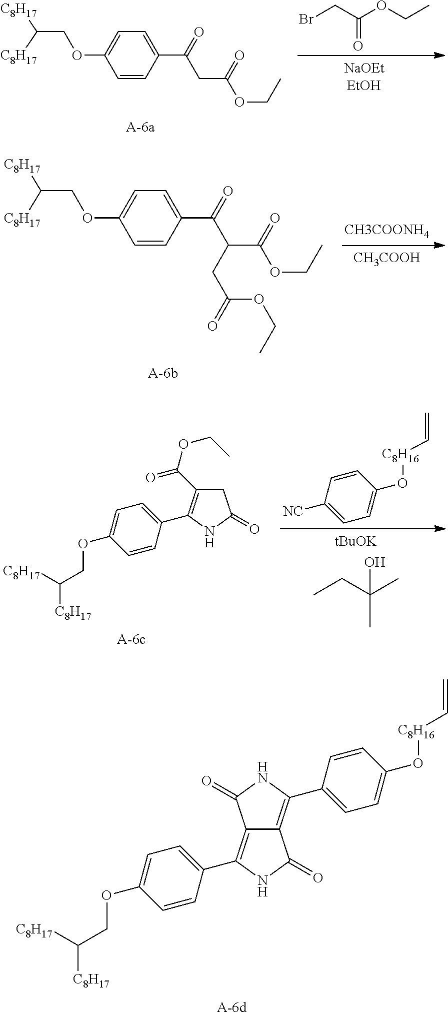

<Synthesis of Compound (A-6)>

(Synthesis of Compound (A-6b))

Sodium (1.2 parts by mass) was added to ethanol (52.0 parts by mass) and was cooled at 0° C., and the components were stirred together. A-6a (10.0 parts by mass) and ethyl bromoacetate (7.7 parts by mass) were added dropwise to the reaction liquid at 0° C. The reaction solution was stirred all night in a nitrogen atmosphere. After the stirring, distilled water was added thereto until sodium bromide was fully dissolved, and the pressure was reduced, thereby distilling ethanol away under reduced pressure. Next, diethyl ether was added, liquid separation operation was carried out, the extracted organic layer was washed with distilled water and was dried using sodium sulfate. The solvent was distilled away under reduced pressure, thereby obtaining a compound (A-6b) (10.7 parts by mass).

(Synthesis of A-6c)

The compound (A-6b) (10.7 parts by mass) and ammonium acetate (6.1 parts by mass) were added to acetic acid and were heated and stirred for 16 hours at an external temperature of 130° C. The reaction solution was added dropwise to cold water (400 parts by mass). The precipitated crystals were filtered and were washed with water (100 parts by mass). The obtained coarse product was recrystallized using methylene chloride, thereby obtaining a compound (A-6c) (8.8 parts by mass).

(Synthesis of A-6d)

Tertiary buthoxy potassium (3.4 parts by mass) was added to 2-methyl-2-buthanol (30 parts by mass) and was heated and stirred at 90° C. The compound (A-6c) (5.0 parts by mass) and p-(1-decaneoxy)benzonitrile (3.1 parts by mass) were sequentially added dropwise and were stirred for two hours at an external temperature of 120° C. After confirming the end of the reaction, distilled water (15.0 parts by mass) and methanol (15.0 parts by mass) were added thereto. The precipitated crystals were filtered, thereby obtaining a compound (A-6d) (2.4 parts by mass).

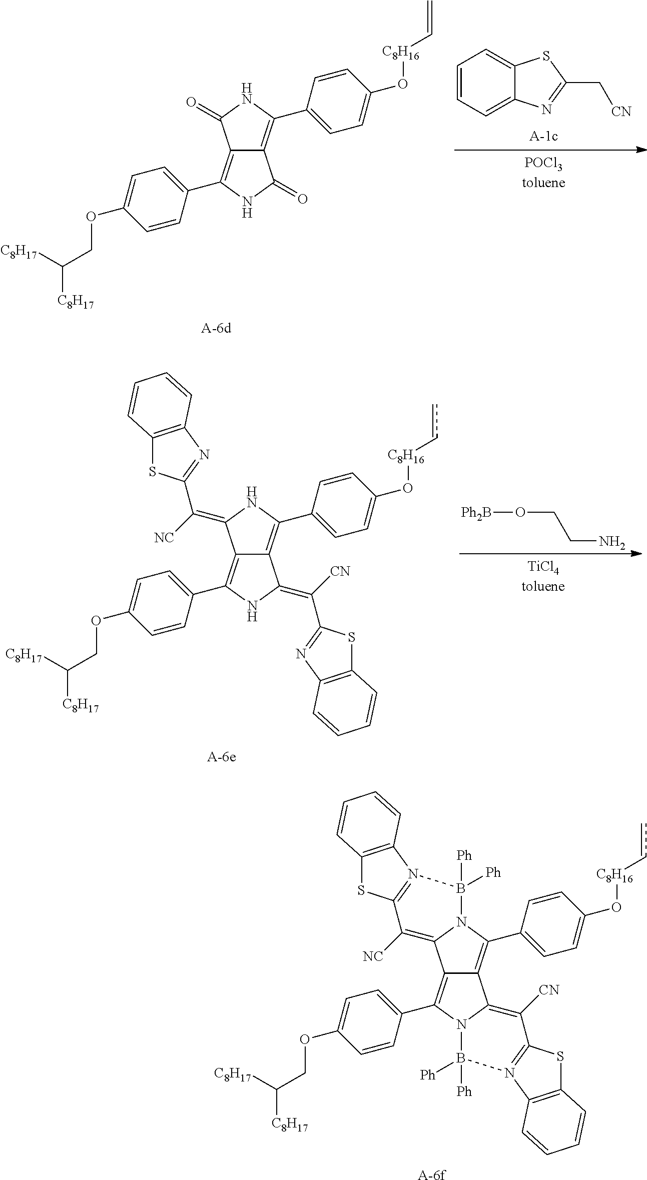

(Synthesis of Compound (A-6f) and Compound (A-6))

A compound (A-6e) and a compound (A-6f) were synthesized using the same methods as those in the synthesis examples of the compound (A-1d) and the compound (A-1).

The following compound (A-6) was synthesized using the same method as in the synthesis example of the compound (A-2) except for the fact that A-6f was used instead of A-1.

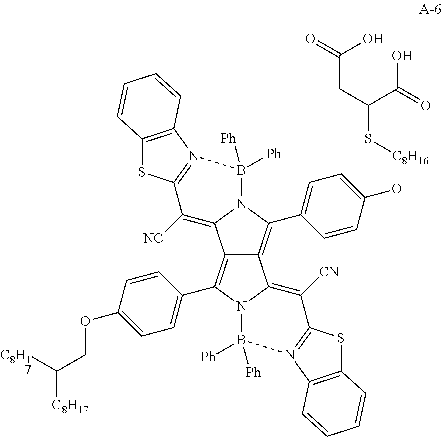

<Synthesis of Compound (A-7)>

A compound (A-7a) was synthesized using the compound (A-6e) and the compound (A-1e) as raw materials and the same method as in the synthesis example of the compound (A-1). Subsequently, a compound (A-7) was synthesized using the same method as for the compound (A-2).

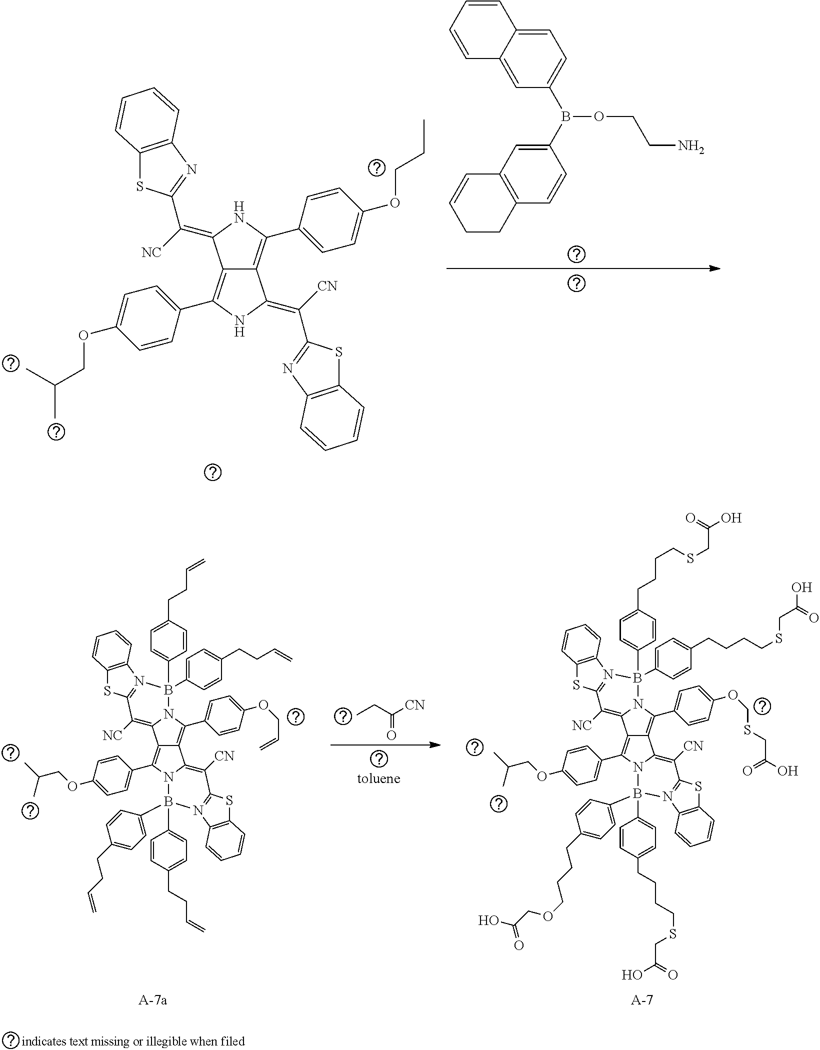

<Synthesis of Compounds (A-8) and (A-9)>

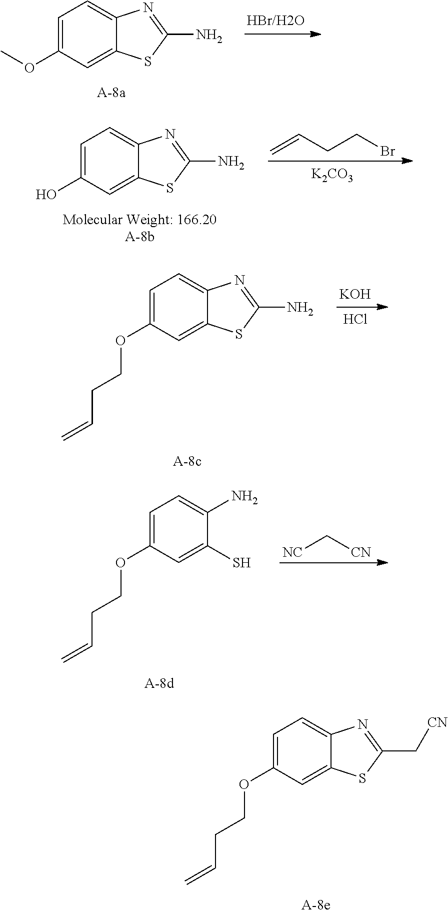

(Synthesis of Compound (A-8b))

A compound (A-8b) (156 parts by mass) was synthesized and obtained according to the method described in the specification of WO2010/54058A1.

(Synthesis of Compound (A-8c))

The compound (A-8b) (10 parts by mass), 3-butenylbromide (8.8 parts by mass), and potassium carbonate (9.9 parts by mass) were added to dimethyl sulfoxide (100 parts by mass) and were stirred for five hours at 50° C. After the end of the reaction, ethyl acetate was added to the reaction solution, liquid separation operation was carried out, the extracted organic layer was sequentially washed with 1 N hydrochloric acid, distilled water, and an aqueous solution of sodium chloride, and was dried using magnesium sulfate. The solvent was distilled away under reduced pressure, thereby obtaining a compound (A-8c) (10.5 parts by mass).

(Synthesis of Compound (A-8d))

The compound (A-8c) (12.2 parts by mass) was added to an aqueous solution of 25% by mass of potassium hydroxide (120 parts by mass), and the reaction solution was heated and refluxed for 24 hours. The obtained reaction liquid was neutralized to pH 6 using 6 N hydrochloric acid and acetic acid. The precipitated crystals were filtered, were washed with distilled water, and were dried, thereby obtaining a compound (A-8d) (10.3 parts by mass).

(Synthesis of Compound (A-8e))

Malononitrile (23.7 parts by mass), acetic acid (20.1 parts by mass), and methanol (197.7 parts by mass) were added and were cooled and stirred at 0° C. Subsequently, the compound (A-8d) (70.1 parts by mass) was slowly added thereto so that the inner temperature reached 40° C. or lower. After the end of the addition, the components were stirred for two hours at an inner temperature of 30° C., were cooled to the inner temperature of 10° C. or lower, and were stirred for 30 minutes. The precipitated crystals were filtered and were washed with cooled methanol, thereby obtaining a compound (A-8e) (68.4 parts by mass).

Compounds (A-8) and (A-9) were synthesized according to the following scheme.

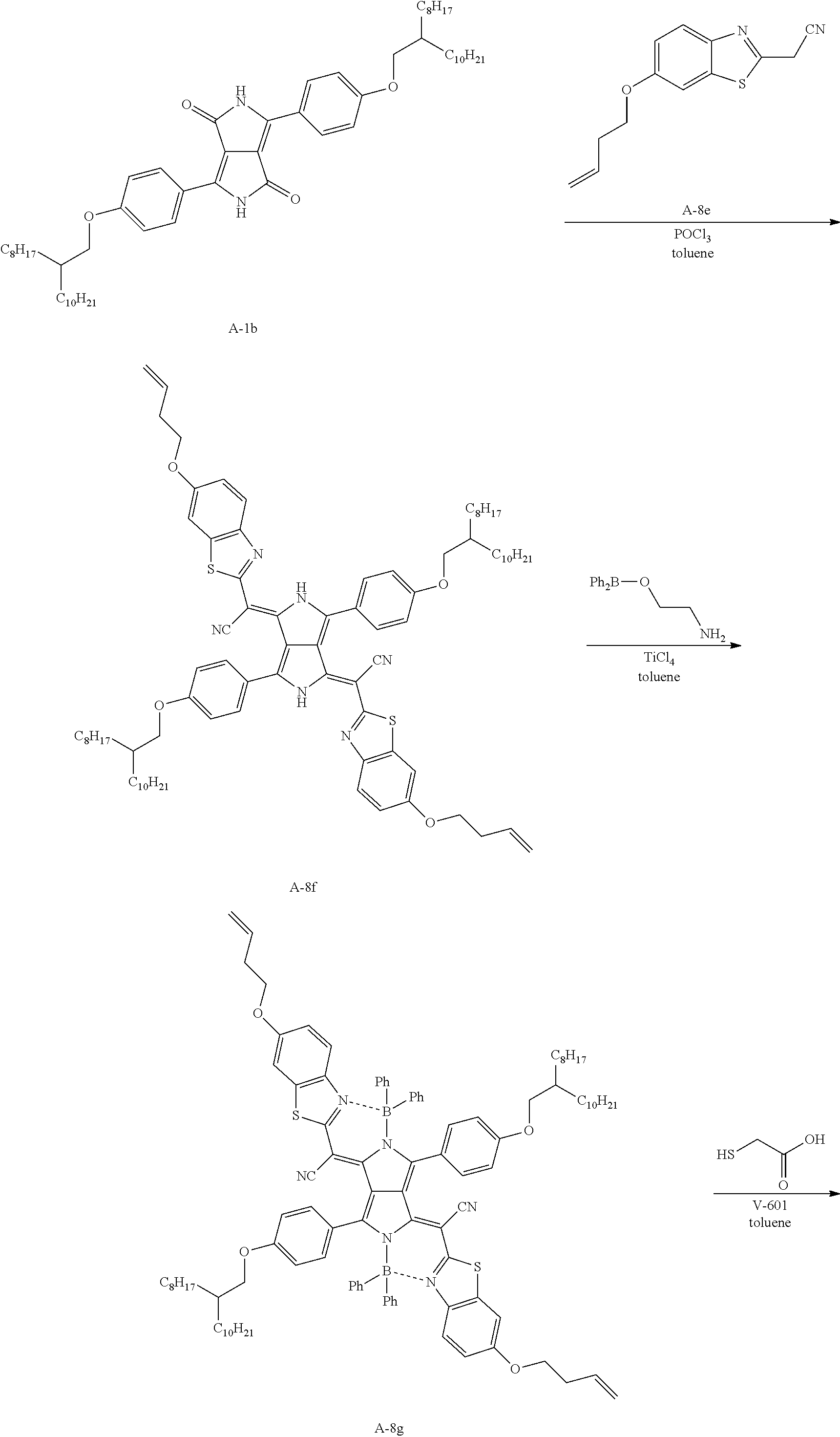

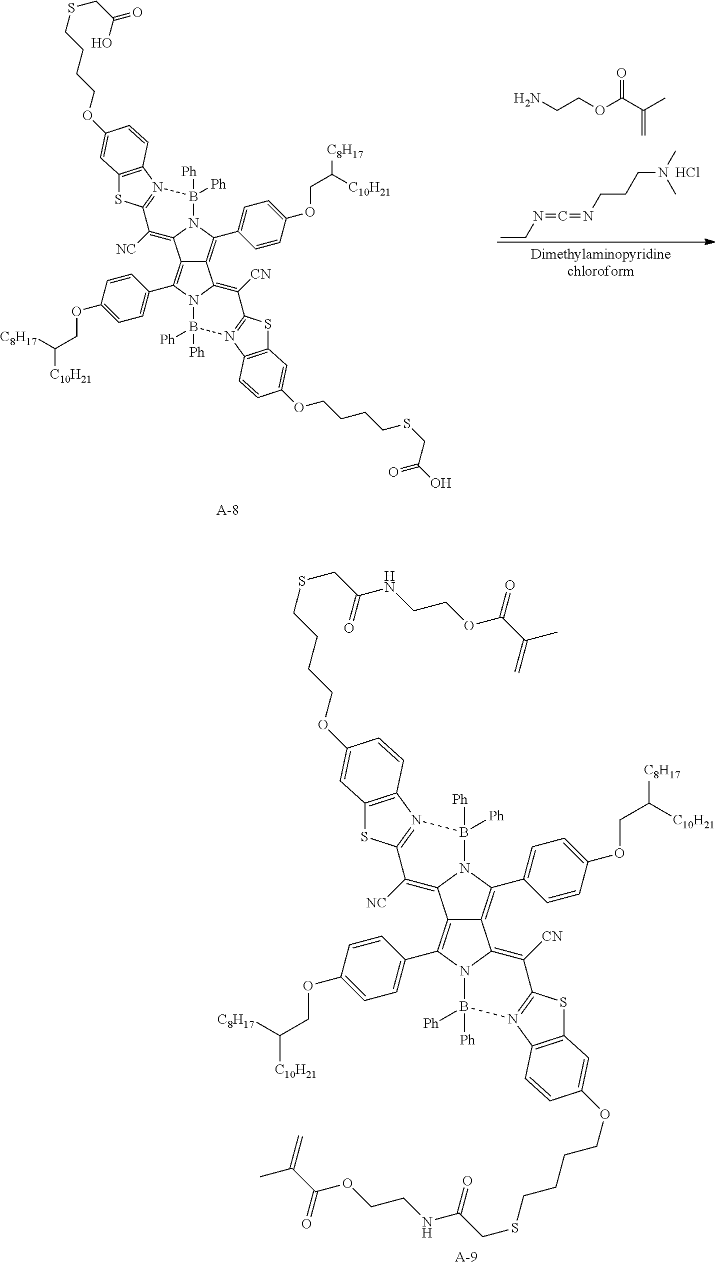

(Synthesis of Compound (A-8f))

A compound (A-8f) was synthesized using the same method as in the synthesis example of the compound (A-1d) except for the fact that the compound (A-8e) was used as a raw material.

(Synthesis of Compound (A-8g))

A compound (A-8g) was synthesized using the same method as in the synthesis example of the compound (A-1) except for the fact that the compound (A-8f) was used as a raw material.

(Synthesis of Compound (A-8))

A compound (A-8) was synthesized using the same method as in the synthesis example of the compound (A-2) except for the fact that the compound (A-8g) was used as a raw material.

(Synthesis of Compound (A-9))

A compound (A-9) was synthesized using the same method as in the synthesis example of the compound (A-3) except for the fact that the compound (A-8) and 2-amino-ethyl methacrylate were used as raw materials.

<Synthesis of compound (A-10)> A compound (A-10) was synthesized according to the following scheme.

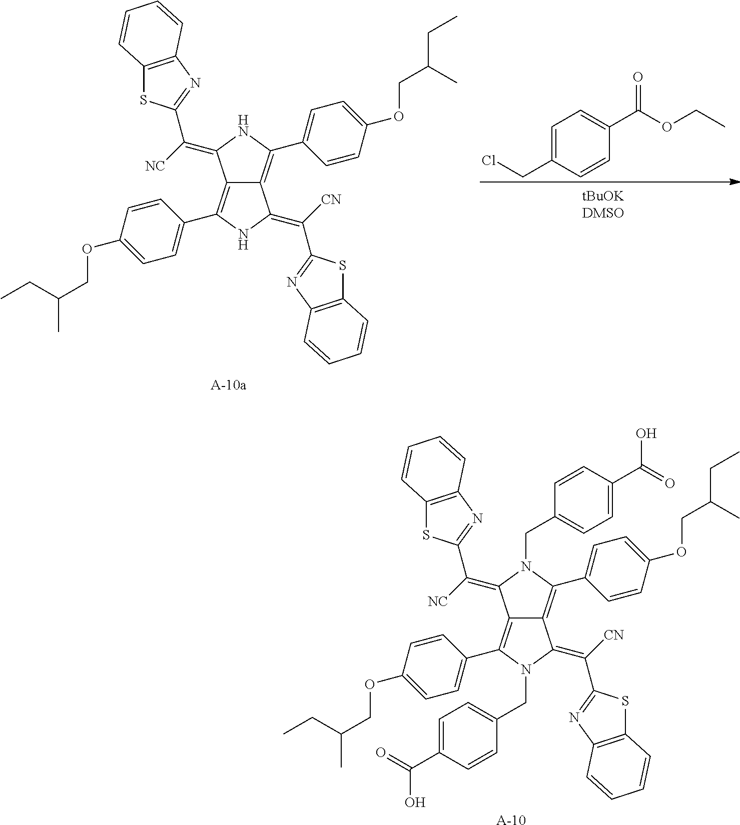

(Synthesis of Compound (A-10a))

A compound (A-10a) was synthesized using the same method as in the synthesis examples of the compound (A-1a0), the compound (A-1a), the compound (A-1b), and the compound (A-1d) except for the fact that 2-methyl butanol was used as a starting raw material.

(Synthesis of Compound (A-10))

Tertiary buthoxy potassium (0.30 parts by mass) and the compound (A-10a) (1.0 parts by mass) were added to dimethyl sulfoxide (14.0 parts by mass) and were heated and stirred at 70° C. Subsequently, ethyl 4-chloromethylbenzoate (0.88 parts by mass) was added dropwise thereto and was stirred for four hours at 70° C. The components were cooled to room temperature, and methanol (1.5 parts by mass) was added thereto. The precipitated crystals were washed with an aqueous solution of 30% by mass of sodium hydroxide (1.6 parts by mass). Furthermore, the crystals were heated and refluxed for 30 minutes, thereby performing hydrolysis. Next, distilled water (14.0 parts by mass) was added thereto, and 1 N acetic acid (15.0 parts by mass) was added thereto, thereby performing redeposition, and the precipitated crystals were filtered and washed with distilled water, thereby obtaining a compound (A-10) (0.6 parts by mass).

<Synthesis of Compound (A-11)>

A compound (A-11) was synthesized using the same synthesis method as for A-1e and A-1 except for the fact that 4-bromo-1 butene was used instead of A-1e0.

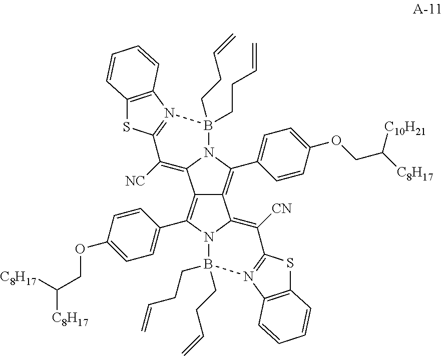

<Synthesis of Compound (A-12)>

(Synthesis of A-12a)

A compound (A-12a) was synthesized using the same synthesis method as for A-6 except for the fact that thioglycolic acid was used instead of thiomalic acid.

(Synthesis of A-12)

A compound (A-12) was synthesized using the same synthesis method as for A-3 except for the fact that (A-12a) was used as a raw material.

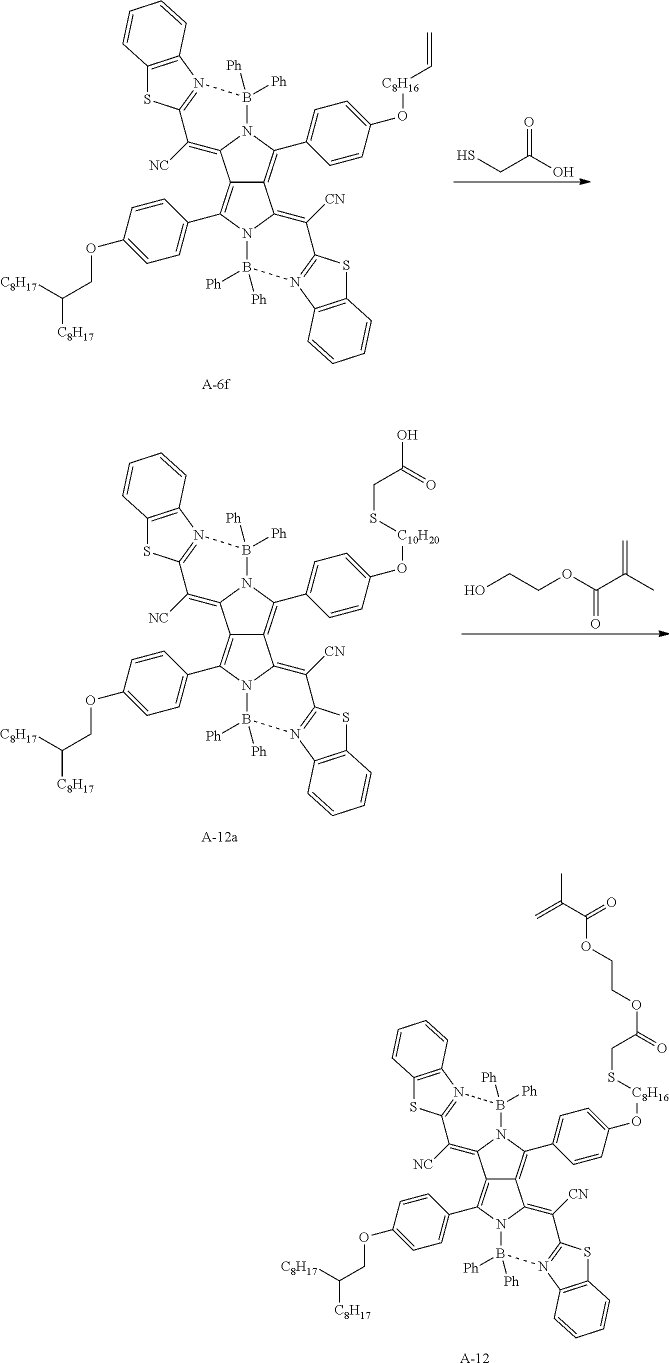

<Synthesis of Compound (A-13)>

A compound (A-13) was synthesized using the same synthesis method as for A-3 except for the fact that epichlorohydrin was used instead of 2-hydroxyethyl methacrylate.

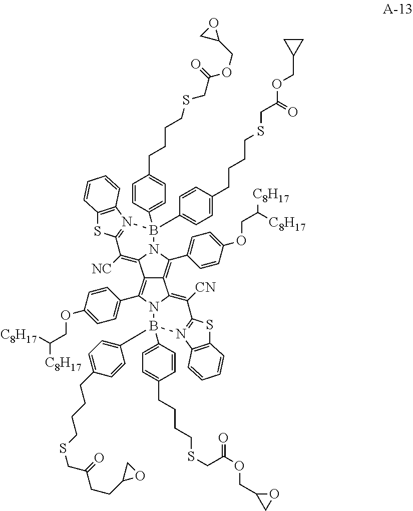

<Preparation of Near-Infrared Absorbing Composition>

### Near-Infrared Absorbing Composition of Example 1

The following components were mixed together, thereby preparing the near-infrared absorbing composition of Example 1.

| | | |
|---|---|---|
| Near-infrared absorbing substance: The following | 2.92 | parts by mass |
| compound (A-1) | | |
| Polymerizable compound (B-1): CYCLOMER P | 15.1 | parts by mass |
| (ACA) 230AA (manufactured by Daicel | | |
| Corporation) | | |
| Polymerizable compound (B-3): KAYARAD | 6.33 | parts by mass |
| DPHA (manufactured by Nippon Kayaku | | |
| Co., Ltd.) | | |
| Polymerization initiator (D-1): IRGACURE | 2.82 | parts by mass |
| OXE01 (manufactured by BASF) | | |
| Polymerization inhibitor | 0.09 | parts by mass |
| Solvent (F-1): Cyclohexanone | 72.74 | parts by mass |

### Near-Infrared Absorbing Compositions of Examples 2 to 17

Near-infrared absorbing compositions were prepared in the same manner as in Example 1 except for the fact that changes were made as shown in the following table.

TABLE 1

| | Near-infrared | | | | | | | | |
|---|---|---|---|---|---|---|---|---|---|
| | absorbing | | | | | | | Spectrum | |
| | coloring agent | | Polymerization | Curing agent | | Solvent resistance | | (λmax (nm)) | |
| | (A) | Curable compound (B) | initiator (D) | (E) | Solvent (F) | Kind of solvent | Evaluation | Solution | Film |
| Example 1 | A-1 | B-1/B-3 | D-1 | — | F-1 | Cyclohexanone | A | 781 | 820 |
| | | (mass ratio 70:30) | | | | | | | |
| Example 2 | A-2 | B-2 | — | — | F-1/F-2 | PGMEA | A | 780 | 800 |
| | | | | | (mass ratio 40:60) | | | | |
| Example 3 | A-3 | B-1 | D-1 | — | F-1 | PGMEA | A | 780 | 835 |
| Example 4 | A-4 | B-1 | — | — | F-1 | PGMEA | B | 781 | 790 |
| Example 5 | A-5 | B-1 | D-1 | E-1 | F-1 | PGMEA | A | 781 | 810 |
| Example 6 | A-6 | B-1 | D-1 | — | F-1 | PGMEA | B | 780 | 785 |
| Example 7 | A-7 | B-1 | — | — | F-2 | PGMEA | A | 780 | 800 |
| Example 8 | A-8 | B-1 | D-1 | — | F-1 | PGMEA | B | 780 | 795 |
| Example 9 | A-9 | B-1/B-2/B-3 | D-1 | — | F-1 | PGMEA | B | 780 | 825 |
| | | (mass ratio 60:30:10) | | | | | | | |
| Example 10 | A-10 | B-1 | — | E-1 | F-1 | PGMEA | B | 724 | 780 |
| Example 11 | A-11 | B-1 | D-1 | — | F-1 | PGMEA | B | 805 | 855 |
| Example 12 | A-12 | B-1 | D-1 | — | F-1 | PGMEA | B | 780 | 835 |
| Example 13 | A-13 | B-4 | D-1 | E-2 | F-1 | NMP | A | 780 | 800 |
| Example 14 | A-1 | B-1 | D-1 | — | F-1 | PGMEA | A | 781 | 820 |
| Example 15 | A-1 | B-2 | D-1 | — | F-2 | Butyl acetate | A | 781 | 820 |
| Example 16 | A-1 | B-3 | D-1 | — | F-1 | PGMEA | A | 781 | 820 |
| Example 17 | A-0 | B-1/B-3 | D-1 | — | F-1 | PGMEA | D | 780 | 820 |
| | | (mass ratio 70:30) | | | | | | | |

The reference signs shown in the table represent the following compounds. A-0 to A-13 represent the above-described compounds (A-0) to (A-13).

B-1: CYCLOMER P (ACA) 230AA (manufactured by Daicel Corporation)

B-2: EHPE3150 (manufactured by Daicel Corporation)

B-3: KAYARAD DPHA (manufactured by Nippon Kayaku Co., Ltd.)

B-4: Polymer having the following structure (Mw: 13,200, Mw/Mn: 1.69)

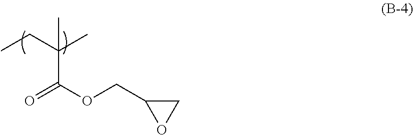

D-1: IRGACURE OXE01 (manufactured by BASF)

E-1: Pyromellitic anhydride (manufactured by Tokyo Chemical Industry Co., Ltd.)

E-2: RIKACID MTA-15 (manufactured by New Japan Chemical Co., Ltd.)

F-1: Cyclohexanone

F-2: Propylene glycol monomethyl ether

<Production of Cured Film>

Each of the near-infrared absorbing compositions prepared in the respective examples was applied onto a glass substrate using a spin coater (manufactured by Mikasa Co., Ltd.), thereby forming a coated film. In addition, a heating treatment (prebaking) was carried out at 100° C. for 120 seconds using a hot plate so that the dried film thickness of the coated film reached 0.6 μm. Next, the coated film was heated at 200° C. for five minutes and was cured, thereby forming a cured film.

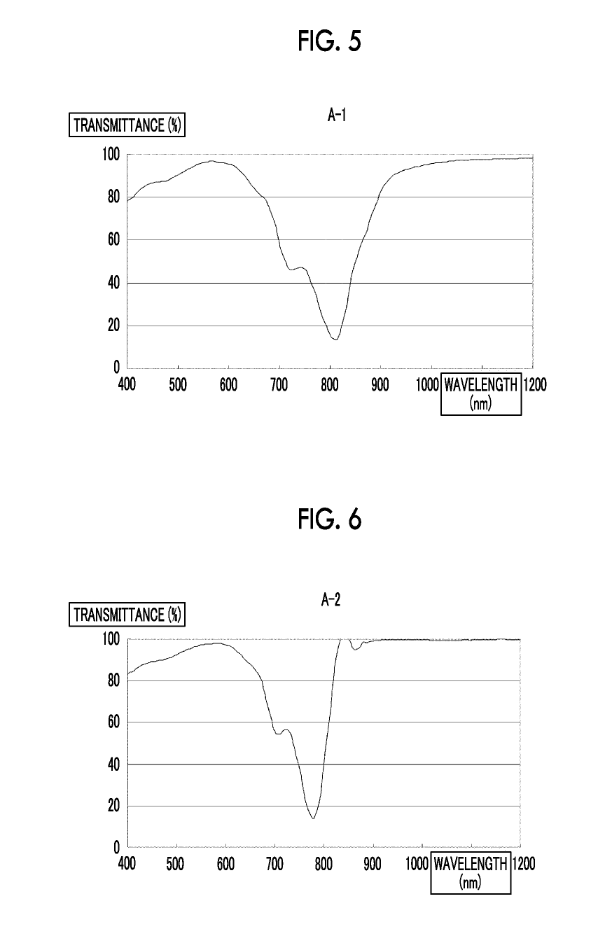

In addition, the spectroscopic characteristics of the obtained cured film were investigated. FIG. 5 is a view illustrating the spectroscopic characteristics of a cured film for which the near-infrared absorbing composition of Example 1 was used. FIG. 6 is a view illustrating the spectroscopic characteristics of a cured film for which the near-infrared absorbing composition of Example 2 was used.

<Evaluation of Solvent Resistance>

The cured films produced above were immersed in solvents shown in Table 1 for five minutes, and spectra before and after the immersion were compared with each other, thereby evaluating solvent resistance using the following expression. For the spectra, absorbance was measured using a spectrophotometer UV-4100 manufactured by Hitachi High-Technologies Corporation with an incidence angle of 0° at 865 nm.

Expression: (Absorbance after immersion/absorbance before immersion)×100

A: The value of the above-described expression was 95% or higher.

B: The value of the above-described expression was 80% or higher and lower than 95%.

C: The value of the above-described expression was 75% or higher and lower than 80%.

D: The value of the above-described expression was lower than 75%.

As is clear from Table 1, it was found that, according to the present invention, cured films which did not easily allow the elution of near-infrared absorbing coloring agents could be obtained even in a case in which the cured films were immersed in solvents. Particularly, it was found that, in a case in which the above-described compound represented by General Formula (1) was used, the effects were favorable.

In addition, it was found that, according to the present invention, favorable near-infrared shield properties could be maintained when cured films were produced using curable compositions.

In addition, in Example 1, in a case in which the polymerization initiator (D-1) was changed to IRGACURE OXE 02, excellent effects could be obtained as in Example 1.

In addition, in Example 1, even in a case in which the polymerizable compounds (B-1) and (B-3) were changed to LIGHT ACRYLATE DCP-A, KAYARAD D-330, KAYARAD D-320, KAYARAD D-310, or KAYARAD DPHA, excellent effects could be obtained as in Example 1.

As illustrated in FIG. 1, the near-infrared absorbing filters 111 of Example 1 and color filters were laminated on a silicon substrate, and the infrared transmitting filters of Experimental Examples 1 to 13 were formed in regions in which the infrared absorbing filters 111 were not present, thereby obtaining a solid image pickup element. The obtained solid image pickup element was excellent in terms of visible light noise performance and image quality. Meanwhile, the color filters were produced in the same manner as in the examples of JP2014-043556A. The infrared transmitting filter 113 was produced using the following method.

[Dispersive Resin 1]

As a dispersive resin 1, the alkali-soluble resin-3 described in Paragraphs “0172” and “0173” of JP2009-69822A was used.

[Dispersive resin 2]

As a dispersive resin 2, the following resin A was used.

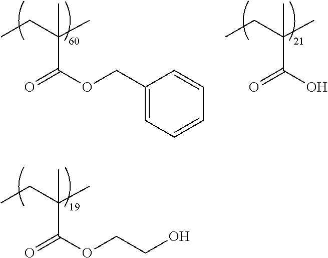

Resin A (the ratios in repeating units are molar ratios, Mw: 14,000)

[Dispersant 1]

As a dispersant 1, the dispersant-1 described in Paragraph “0175” of JP2009-69822A was used.

[Preparation of Pigment Dispersion Liquid B-1]

A mixed liquid having the following composition was mixed and dispersed for three hours using zirconia beads having a diameter of 0.3 mm in a beads mill (reduced pressure mechanism-equipped high-pressure disperser NANO-3000-10 (manufactured by Beryu Corp.)), thereby preparing a pigment dispersion liquid B-1.

| | |
|---|---|
| A pigment mixture consisting of a red pigment (C.I. Pigment | 11.8 parts |
| Red 254) and a yellow pigment (C.I. Pigment Yellow 139) | |
| Dispersant: BYK-111 manufactured by BYK-Chemie GmbH | 9.1 parts |
| Organic solvent: Propylene glycol methyl ether acetate | 79.1 parts |

[Preparation of Pigment Dispersion Liquid B-2]

A mixed liquid having the following composition was mixed and dispersed for three hours using zirconia beads having a diameter of 0.3 mm in a beads mill (reduced pressure mechanism-equipped high-pressure disperser NANO-3000-10 (manufactured by Beryu Corp.)), thereby preparing a pigment dispersion liquid B-2.

| | |
|---|---|
| A pigment mixture consisting of a blue pigment (C.I. Pigment | 12.6 parts |
| Blue 15:6) and a violet pigment (C.I. Pigment Violet 23) | |
| Dispersant: BYK-111 manufactured by BYK-Chemie GmbH | 2.0 parts |
| The above-described dispersive resin 2 | 3.3 parts |
| Organic solvent: Cyclohexane | 31.2 parts |
| Organic solvent: Propylene glycol methyl ether acetate | 50.9 parts |
| (PGMEA) | |

[Preparation of Pigment Dispersion Liquid B-3]

A mixed liquid having the following composition was mixed and dispersed for three hours using zirconia beads having a diameter of 0.3 mm in a beads mill (reduced pressure mechanism-equipped high-pressure disperser NANO-3000-10 (manufactured by Beryu Corp.)), thereby preparing a pigment dispersion liquid B-3.

| | |
|---|---|
| A pigment mixture consisting of a red pigment (C.I. | 13.5 parts |
| Pigment Red 254), a yellow pigment (C.I. Pigment Yellow | |
| 150), a blue pigment (C.I. Pigment Blue 15:6), a violet | |
| pigment (C.I. Pigment Violet 23), and a green pigment | |
| (C.I. Pigment 36) | |
| The above-described dispersant 1 | 2.2 parts |
| Dispersion aid: S12000 manufactured by The Lubrizol | 0.5 parts |
| Corporation | |
| The above-described dispersive resin 1 | 3.8 parts |
| Organic solvent: PGMEA | 80.0 parts |

[Preparation of Pigment Dispersion Liquid B-4]

A mixed liquid having the following composition was mixed and dispersed for three hours using zirconia beads having a diameter of 0.3 mm in a beads mill (reduced pressure mechanism-equipped high-pressure disperser NANO-3000-10 (manufactured by Beryu Corp.)), thereby preparing a pigment dispersion liquid B-4.

| | |
|---|---|
| A pigment mixture consisting of a red pigment (C.I. Pigment | 12.1 parts |
| Red 254), a yellow pigment (C.I. Pigment Yellow 150), a | |
| blue pigment (C.I. Pigment Blue 15:6), a violet pigment | |
| (C.I. Pigment Violet 23), and a green pigment | |
| (C.I. Pigment 36) | |
| Dispersant: BYK-161 manufactured by BYK-Chemie GmbH | 6.7 parts |
| Dispersion aid: S12000 manufactured by The Lubrizol | 0.7 parts |
| Corporation | |
| Organic solvent: PGMEA | 80.5 parts |

[Preparation of Pigment Dispersion Liquid B-5]

A mixed liquid having the following composition was mixed and dispersed for three hours using zirconia beads having a diameter of 0.3 mm in a beads mill (reduced pressure mechanism-equipped high-pressure disperser NANO-3000-10 (manufactured by Beryu Corp.)), thereby preparing a pigment dispersion liquid B-5.

| | |
|---|---|
| Black pigment (carbon black; C.I. Pigment Black 7) | 16.3 parts |
| Dispersant: BYK-161 manufactured by BYK-Chemie GmbH | 2.9 parts |
| Dispersion aid: S12000 manufactured by The Lubrizol | 0.8 parts |
| Corporation | |
| Organic solvent: PGMEA | 80.0 parts |

[Preparation of Pigment Dispersion Liquid B-6]

A mixed liquid having the following composition was mixed and dispersed for three hours using zirconia beads having a diameter of 0.3 mm in a beads mill (reduced pressure mechanism-equipped high-pressure disperser NANO-3000-10 (manufactured by Beryu Corp.)), thereby preparing a pigment dispersion liquid B-6.

| | |
|---|---|
| A pigment mixture consisting of a red pigment (C.I. Pigment | 20.0 parts |
| Red 254), a yellow pigment (C.I. Pigment Yellow 139), a blue | |
| pigment (C.I. Pigment Blue 15:6), and a violet pigment | |
| (C.I. Pigment Violet 23) | |
| Dispersant 1 | 3.4 parts |
| The above-described dispersive resin 1 | 6.4 parts |
| Organic solvent: PGMEA | 70.2 parts |

### Experimental Example 1

[Preparation of Coloring Radiation-Sensitive Composition (Infrared Transmitting Composition)]

The following components were mixed together, thereby preparing a coloring radiation-sensitive composition (infrared transmitting composition) of Experimental Example 1.

| | |
|---|---|
| Pigment dispersion liquid B-1 (refer to Table 2 below | 46.5 parts |
| regarding the mass ratio between individual pigments) | |
| Pigment dispersion liquid B-2 (refer to Table 2 below | 37.1 parts |
| regarding the mass ratio between individual pigments) | |
| The following alkali-soluble resin 1 | 1.1 parts |
| The following polymerizable compound 1 | 1.8 parts |
| The following polymerizable compound 2 | 0.6 parts |
| Photopolymerization initiator: The following | 0.9 parts |
| polymerization initiator 1 | |
| Surfactant 1: PGMEA solution of 1.00% by mass of | 4.2 parts |
| MEGAFAC F-781F manufactured by DIC Corporation | |
| (fluorine polymer-containing surfactant) | |
| Polymerization inhibitor: p-Methoxyphenol | 0.001 parts |
| Organic solvent 1: PGMEA | 7.8 parts |

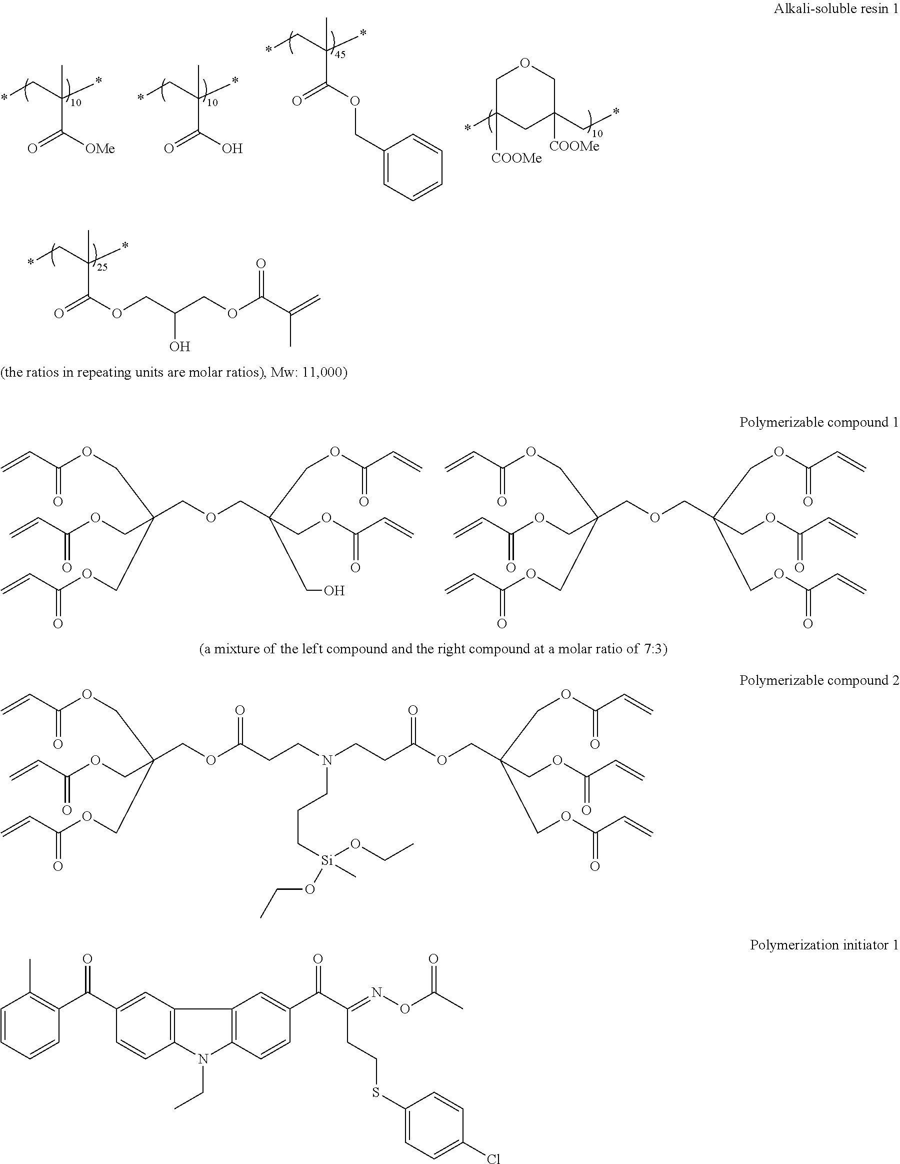

TABLE 2

| | Red | | | | | Black | |
|---|---|---|---|---|---|---|---|
| | pig- | Yellow | Blue | Violet | Green | pig- | |
| | ment | pigment | pigment | pigment | pigment | ment | |
| | ratio | ratio | ratio | ratio | ratio | ratio | Total |
| Example 1 | 0.37 | 0.17 | 0.36 | 0.10 | | | 1.00 |
| Example 2 | 0.37 | 0.17 | 0.36 | 0.10 | | | 1.00 |
| Example 3 | 0.41 | 0.19 | 0.32 | 0.08 | | | 1.00 |
| Example 4 | 0.28 | 0.12 | 0.48 | 0.12 | | | 1.00 |
| Example 5 | 0.45 | 0.20 | 0.28 | 0.07 | | | 1.00 |
| Example 6 | 0.24 | 0.11 | 0.52 | 0.13 | | | 1.00 |
| Example 7 | 0.37 | 0.17 | 0.36 | 0.10 | | | 1.00 |
| Example 8 | 0.37 | 0.17 | 0.36 | 0.10 | | | 1.00 |
| Example 9 | 0.37 | 0.17 | 0.36 | 0.10 | | | 1.00 |
| Example 10 | 0.32 | 0.18 | 0.25 | 0.07 | 0.18 | | 1.00 |
| Example 11 | 0.36 | 0.20 | 0.17 | 0.08 | 0.20 | | 1.00 |
| Example 12 | 0.32 | 0.18 | 0.25 | 0.07 | 0.18 | | 1.00 |
| Example 13 | 0.18 | 0.24 | 0.48 | 0.06 | | 0.04 | 1.00 |

Pigment ratio: The ratio of each of the pigments in the total pigments (in terms of mass)

### Experimental Examples 2 to 13

Individual colored radiation-sensitive compositions of Experimental Examples 2 to 13 were prepared by changing the pigment dispersion liquid, the alkali-soluble resin, the polymerizable compounds, the photopolymerization inhibitor, the surfactant, and the organic solvent to the components and the amounts (parts by mass) thereof shown in Table 3 below (refer to Table 2 regarding the mass ratio between individual pigments in the pigment dispersion liquid; in Table 3, blank cells indicated that the corresponding components were not used.) in the preparation of the coloring radiation-sensitive composition of Experimental Example 1.

Among materials used in the above-described examples and comparative examples, materials which are not described above will be described below.

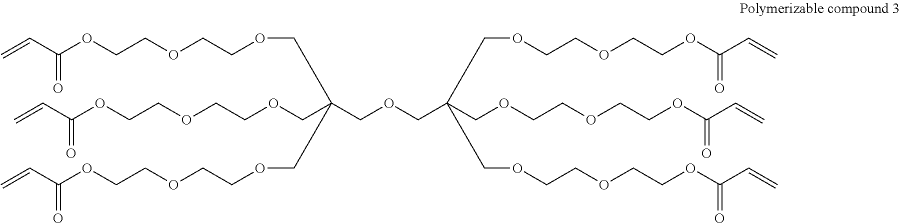 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

Polymerizable compound 4: U-6LPA (urethane acrylate) manufactured by Shin-Nakamura Chemical Co., Ltd.

Polymerizable compound 5: PM-21 (2-(meth)acryloyloxyethyl caproate acid phosphate) manufactured by Nippon Kayaku Co., Ltd.

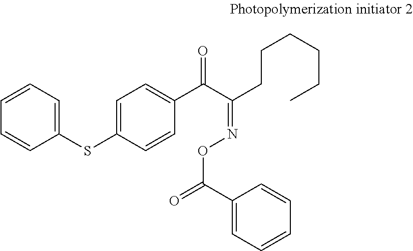 [SMILES: CCCCCC/C(=N/OC(=O)c1ccccc1)C(=O)c1ccc(Sc2ccccc2)cc1]

Photopolymerization initiator 3: IRGACURE 379 manufactured by BASF

Photopolymerization initiator 4: The photopolymerization initiator-1 (oxime-based initiator) described in Paragraph “0177” of JP2009-69822A

Organic solvent 2: 3-Methoxybutyl acetate

Alkali-soluble resin 2: The above-described resin A

Alkali-soluble resin 3: The alkali-soluble resin-1 (epoxy acrylate resin) described in Paragraph “0170” of JP2009-69822A

The spectroscopic characteristics were evaluated using each of the obtained colored radiation-sensitive compositions. The results are summarized in Table 3.

[Spectroscopic Characteristics]

Each of the colored radiation-sensitive compositions was applied onto a glass substrate by means of spin coating so that the film thickness after post baking reached 1.0 μm, was dried at 100° C. for 120 seconds using a hot plate, and, after the drying, furthermore, was heated (post baked) at 200° C. for 300 seconds using a hot plate.

The light transmittance of the substrate having a colored layer was measured using a spectrophotometer (ref. a glass substrate) of a UV-VIS-NIR spectrophotometer U-4100 (manufactured by Hitachi High-Technologies Corporation) in a wavelength range of 300 to 1300 nm.

[Production of Infrared Transmitting Filters]

Each of the colored radiation-sensitive compositions of Experimental Examples 1 to 13 was applied onto a silicon wafer using a spin so that the dried film thickness reached 1.0 μm, and a heating treatment (prebaking) was carried out at 100° C. for 120 seconds using a hot plate.

Next, the film was exposed using an FPA-3000 i5+ i line stepper (manufactured by Canon Inc.) and a photomask which was used to form a 1.4 μm×1.4 μm square pixel pattern from 50 to 750 mJ/cm² per 50 mJ/cm², whereby the optimal exposure amount at which the above-described square pixel pattern could be resolved was determined, and the film was exposed at this optical exposure amount.

After that, the silicon wafer on which the exposed coated film was formed was mounted on a horizontal rotating table of a spin shower developer (DW-30-type, manufactured by Chemitronics Co., Ltd.) and was paddle-developed for 60 seconds at 23° C. using a CD-2060 (manufactured by Fujifilm Electronics Materials), thereby forming colored patterns on the silicon wafer.

The silicon wafer on which the colored patterns were formed was rinsed with pure water and then was spray-dried.

Furthermore, a heating treatment (post baking) was carried out at 200° C. for 300 seconds using a hot plate, thereby obtaining each of silicon wafers having colored patterns as infrared transmitting filters of Experimental Examples 1 to 13.

<Evaluation>

(Visible Light Noise Performance)

In the thickness direction of the infrared transmitting filters obtained as described above, the ratio (t1/t2=x) of the average light transmittance t1 in a visible light range of 400 to 700 nm to the average light transmittance t2 in a visible light range of 825 to 1,300 nm was obtained using a spectrophotometer (ref. a glass substrate) of a UV-VIS-NIR spectrophotometer U-4100 (manufactured by Hitachi High-Technologies Corporation) and was evaluated on the basis of the following evaluation standards. As the grading becomes higher, the amount of noise derived from visible light components decreases, and performance becomes superior.

<Evaluation Standards>

5: x≦0.06

4: 0.06<x≦0.65

3: 0.065<x≦0.07

2: 0.07<x≦0.08

1: 0.08<x

(Post Coating Delay (PCD) Dependency)

The absolute value (Δw=|w2−w1|) of the difference between pattern noise (one side of the square pixel pattern) w1 obtained when the coloring radiation-sensitive composition was applied and then was immediately exposed in the “production of the infrared transmitting filters” and pattern noise (one side of the square pixel pattern) w2 obtained when the coloring radiation-sensitive composition was exposed after 72 hours from the application thereof was measured and was evaluated on the basis of the following evaluation standards. As the grading becomes higher, the dependency on PCD becomes lower, and performance becomes superior.

<Evaluation Standards>

5: Δw≦0.01

4: 0.01≦Δw<0.03

3: 0.03≦Δw<0.05

2: 0.05≦Δw<0.10

1: 0.10≦Δw

TABLE 3

| | | Example 1 | Example 2 | Example 3 | Example 4 | Example 5 | Example 6 | Example 7 | Example 8 | Example 9 | Example 10 | Example 11 | Example 12 | Example 13 |
|---|---|---|---|---|---|---|---|---|---|---|---|---|---|---|
| Composition of | Pigment dispersion liquid B-1 | 46.5 | 47.5 | 52.4 | 35.6 | 56.4 | 31 | 47.5 | 47.5 | 47.5 | | | | |
| compositions | Pigment dispersion liquid B-2 | 37.1 | 37.9 | 33 | 49.8 | 29 | 54.4 | 37.9 | 37.9 | 37.9 | | | | |
| | Pigment dispersion liquid B-3 | | | | | | | | | | 75.4 | | 75.4 | |
| | Pigment dispersion liquid B-4 | | | | | | | | | | | 79 | | |
| | Pigment dispersion liquid B-5 | | | | | | | | | | | | | 3 |
| | Pigment dispersion liquid B-6 | | | | | | | | | | | | | 59.4 |
| | Alkali-soluble resin 1*¹ | 1.1 | 0.5 | 0.5 | 0.5 | 0.5 | 0.5 | | 0.5 | | | | | |
| | Alkali-soluble resin 2*¹ | | | | | | | 0.5 | | 0.5 | | | 3.8 | |
| | Alkali-soluble resin 3*¹ | | | | | | | | | | 3.8 | 3.9 | | 3.2 |
| | Polymerizable compound 1*¹ | 1.8 | 0.6 | 0.6 | 0.6 | 0.6 | 0.6 | 0.6 | 0.6 | 0.6 | | | | 1 |
| | Polymerizable compound 2*¹ | 0.6 | 0.5 | 0.5 | 0.5 | 0.5 | 0.5 | 0.5 | 0.5 | 0.5 | | | | |
| | Polymerizable compound 3*¹ | | 1.4 | 1.4 | 1.4 | 1.4 | 1.4 | 1.4 | 1.4 | 1.4 | | | | |
| | Photopolymerization initiator 1 | 0.9 | | | | | | | | | | | | |
| | Photopolymerization initiator 2 | | 1 | 1 | 1 | 1 | 1 | 1 | | | | | | |
| | Photopolymerization initiator 3 | | | | | | | | 1 | 1 | | | 0.5 | |
| | Photopolymerization initiator 4 | | | | | | | | | | 0.5 | 0.3 | | 1.1 |
| | Surfactant 1*² | 4.2 | 4.2 | 4.2 | 4.2 | 4.2 | 4.2 | 4.2 | 4.2 | 4.2 | | | | |
| | Polymerizable compound 4 | | | | | | | | | | 1.3 | 0.8 | 1.3 | |
| | Polymerizable compound 5 | | | | | | | | | | 0.2 | 0.2 | 0.2 | |
| | Organic solvent 1 | 7.8 | 6.4 | 6.4 | 6.4 | 6.4 | 6.4 | 6.4 | 6.4 | 6.4 | 13.3 | 11.1 | 13.3 | 32.3 |
| | Organic solvent 2 | | | | | | | | | | 5.5 | 4.7 | 5.5 | |
| Characteristics | Maximum transmittance | 13 | 13 | 15 | 18 | 19 | 20 | 13 | 13 | 13 | 23 | 28 | 23 | 19 |
| | in visible light range | | | | | | | | | | | | | |
| | (400 to 750 nm) | | | | | | | | | | | | | |
| | Minimum transmittance | 98 | 98 | 98 | 98 | 97 | 99 | 98 | 98 | 98 | 95 | 95 | 95 | 78 |
| | in near-infrared range | | | | | | | | | | | | | |
| | (900 to 1,300 nm) | | | | | | | | | | | | | |
| | Transmittance at 800 nm | 56 | 56 | 61 | 47 | 64 | 44 | 59 | 59 | 59 | 81 | 86 | 81 | 53 |
| Evaluation | Average transmittance | 5.7 | 5.7 | 6.1 | 6.1 | 6.9 | 6.8 | 5.7 | 5.7 | 5.7 | 11.7 | 11.2 | 11.7 | 7.5 |
| | t1 of visible light range | | | | | | | | | | | | | |
| | (400 to 700 nm) | | | | | | | | | | | | | |
| | Average transmittance | 99.0 | 99.0 | 98.9 | 99.2 | 98.8 | 99.3 | 99.0 | 99.0 | 99.0 | 97.7 | 97.7 | 97.7 | 83.2 |
| | t2 of near-infrared range | | | | | | | | | | | | | |
| | (825 to 1,300 nm) | | | | | | | | | | | | | |
| | t1/t2 | 0.057 | 0.057 | 0.062 | 0.061 | 0.069 | 0.068 | 0.058 | 0.058 | 0.058 | 0.120 | 0.114 | 0.120 | 0.090 |
| | ΔW | 0.0078 | 0.0078 | 0.0078 | 0.0078 | 0.0078 | 0.0078 | 0.018 | 0.024 | 0.033 | 0.061 | 0.065 | 0.081 | 0.072 |
| | Visible light noise performance | 5 | 5 | 4 | 4 | 3 | 3 | 5 | 5 | 5 | 1 | 1 | 1 | 1 |
| | PCD dependency | 5 | 5 | 5 | 5 | 5 | 5 | 4 | 4 | 3 | 2 | 2 | 2 | 2 |

*¹In terms of solid contents
*²1% PGMEA solution

It was found that the infrared transmitting filters formed of the colored radiation-sensitive compositions of Experimental Examples 1 to 9 were capable of transmitting infrared rays (particularly near-infrared rays) in a state in which the amount of noise derived from visible light components was small.

In addition, the infrared transmitting filters of Experimental Examples 1 to 9 formed using the colored radiation-sensitive compositions including at least any one of the alkali-soluble resin having the repeating unit derived from the compound represented by Formula (ED1) and the oxime compound (photopolymerization initiator) were excellent in terms of PCD dependency, and the infrared transmitting filters of Experimental Examples 1 to 9 formed using the colored radiation-sensitive compositions including both the alkali-soluble resin and the oxime compound were superior in terms of PCD dependency.

In addition, the infrared transmitting filters of Experimental Examples 1, 2, 7 to 9 which had “the maximum value of the light transmittance in a wavelength range of 400 to 750 nm” of 15% or lower and “the minimum value of the light transmittance in a wavelength range of 900 to 1,300 nm” of 98% or higher were superior in terms of visible light noise performance.

### EXPLANATION OF REFERENCES

1: lens optical system

10: solid image pickup element

20: signal processing portion

30: signal switching portion

40: control portion

50: signal accumulation portion

60: light emission control portion

70: infrared LED

80, 81: image output portion

100: near-infrared sensor

110: solid image pickup element substrate

111: near-infrared absorbing filter

112: color filter

113: infrared transmitting filter

114: region

115: microlens

116: flattening layer

hν: incidence ray

What is claimed is:

1. An infrared sensor which has an infrared transmitting filter and a near-infrared absorbing filter and detects objects by detecting light having wavelengths of 700 nm or longer and shorter than 900 nm,
wherein the near-infrared absorbing filter includes a near-infrared absorbing substance having a maximum absorption wavelength at a wavelength of 700 nm or longer and shorter than 900 nm.

2. The infrared sensor according to claim 1,
wherein the near-infrared absorbing substance is a compound represented by General Formula (1) below; 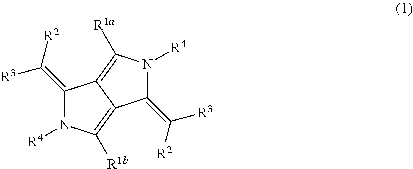
in General Formula (1), R^{1a} and R^{1b} each independently represent an alkyl group, an aryl group, or a heteroaryl group; R² and R³ each independently represent a hydrogen atom or a substituent, and R² and R³ may be bonded to each other and thus form a cyclic structure; R⁴'s each independently represent a hydrogen atom, an alkyl group, an aryl group, a heteroaryl group, (R^{4A})₂B—, (R^{4B})₂P—, (R^{4C})₃Si—, or (R^{4D})ₙM-; R^{4A} to R^{4D} each independently represent an atom or a group; n represents an integer of 2 to 4, and M represents an n+1-valent metal atom; in a case in which R⁴ represents (R^{4A})₂B—, (R^{4B})₂P—, (R^{4C})₃Si—, or (R^{4D})ₙM-, R⁴ may form a covalent bond or a coordinate bond with at least one selected from R^{1a}, R^{1b}, and R³; here, General Formula (1) satisfies at least one condition selected from at least one selected from R^{1a}, R^{1b}, and R⁴ having a crosslinking group and at least one selected from R² and R³ having crosslinking groups with a cyclic structure group therebetween.

3. The infrared sensor according to claim 2,
wherein the near-infrared absorbing substance satisfies at least one selected from conditions 1) to 3) below;
1) in General Formula (1), at least one selected from R^{1a} and R^{1b} has crosslinking groups with a cyclic structure group having aromaticity therebetween;
2) in General Formula (1), R² or R³ has crosslinking groups with a cyclic structure group having aromaticity therebetween; and
3) in General Formula (1), R⁴ has crosslinking groups with a cyclic structure group therebetween.

4. The infrared sensor according to claim 1,
wherein the near-infrared absorbing substance has two or more crosslinking groups in a molecule.

5. The infrared sensor according to claim 2,
wherein, in a case in which the crosslinking group is an olefin group or a styryl group, the near-infrared absorbing substance has three or more crosslinking groups in a molecule.

6. The infrared sensor according claim 2,
wherein R⁴ in the near-infrared absorbing substance represents (R^{4A})₂B—; here, R^{4A}'s each independently represent an atom or a group.

7. The infrared sensor according to claim 2,
wherein one of R² and R³ in the near-infrared absorbing substance is a cyano group, and the other has a heterocyclic group.

8. The infrared sensor according to claim 1,
wherein the near-infrared absorbing substance is a compound represented by any one of General Formulae (2) to (4) below; 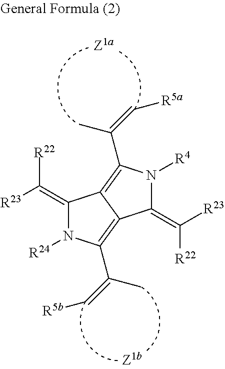
in General Formula (2), Z^{1a} and Z^{1b} each independently represent an atomic group forming an aryl ring or a heteroaryl ring; R^{5a} and R^{5b} each independently represent any one of an aryl group having 6 to 20 carbon atoms, a heteroaryl group having 4 to 20 carbon atoms, an alkyl group having 1 to 20 carbon atoms, an alkoxy group having 1 to 20 carbon atoms, an alkoxycarbonyl group having 2 to 20 carbon atoms, a carboxyl group, a carbamoyl group, a halogen atom, or a cyano group; R^{5a} or R^{5b} and Z^{1a} or Z^{1b} may be bonded to each other and thus form a fused ring; R²² and R²³ each independently represent a cyano group, an acyl group having 2 to 6 carbon atoms, an alkoxycarbonyl group having 2 to 6 carbon atoms, an alkyl group having 1 to 10 carbon atoms, an arylsulfinyl group having 6 to 10 carbon atoms, or a nitrogen-containing heteroaryl group having 3 to 20 carbon atoms, or R²² and R²³ may be bonded to each other and thus represent a cyclic acidic nucleus; R²⁴ represents a hydrogen atom, an alkyl group having 1 to 20 carbon atoms, an aryl group having 6 to 20 carbon atoms, a heteroaryl group having 3 to 20 carbon atoms, (R^{4A})₂B—, (R^{4B})₂P—, (R^{4C})₃Si—, or (R^{4D})ₙM-; R^{4A} to R^{4D} each independently represent an atom or a group; n represents an integer of 2 to 4, and M represents an n+1-valent metal atom; in a case in which R²⁴ represents (R^{4A})₂B—, (R^{4B})₂P—, (R^{4D})ₙM-, R²⁴ may form a covalent bond or a coordinate bond with at least one selected from R^{5a} and R²² to R²⁴; General Formula (2) satisfies at least one condition selected from at least one selected from R^{5a}, R^{5b}, and R²⁴ having a crosslinking group and at least one selected from R²² and R²³ having crosslinking groups with a nitrogen-containing heteroaryl group having 3 to 20 carbon atoms therebetween; 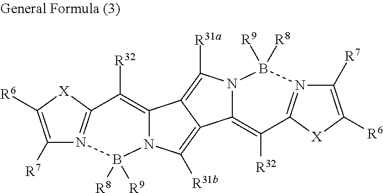
in General Formula (3), R^{31a} and R^{31b} each independently represent an alkyl group having 1 to 20 carbon atoms, an aryl group having 6 to 20 carbon atoms, or a heteroaryl group having 3 to 20 carbon atoms; R³² represents a cyano group, an acyl group having 2 to 6 carbon atoms, an alkoxycarbonyl group having 2 to 6 carbon atoms, an alkyl group having 1 to 10 carbon atoms, an arylsulfinyl group having 6 to 10 carbon atoms, or a nitrogen-containing heteroaryl group having 3 to 10 carbon atoms; R⁶ and R⁷ each independently represent a hydrogen atom, an alkyl group having 1 to 10 carbon atoms, an aryl group having 6 to 10 carbon atoms, or a heteroaryl group having 3 to 10 carbon atoms, R⁶ and R⁷ may be bonded to each other and thus form a ring, the ring being formed being an alicycle having 5 to 10 carbon atoms, an aryl ring having 6 to 10 carbon atoms, or a heteroaryl ring having 3 to 10 carbon atoms; R⁸ and R⁹ each independently represent an alkyl group having 1 to 10 carbon atoms, an alkoxy group having 1 to 10 carbon atoms, an aryl group having 6 to 20 carbon atoms, or a heteroaryl group having 3 to 10 carbon atoms; X represents an oxygen atom, a sulfur atom, —NR—, —CRR′—, or —CH═CH—, and R and R′ each independently represent a hydrogen atom, an alkyl group having 1 to 10 carbon atoms, or an aryl group having 6 to 10 carbon atoms; at least one selected from R⁶ to R⁹, R^{31a}, R^{31b}, and R³² has a crosslinking group; 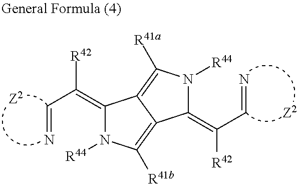
in General Formula (4), R^{41a} and R^{41b} represent each different groups and represent an alkyl groups having 1 to 20 carbon atoms, an aryl groups having 6 to 20 carbon atoms, or a heteroaryl groups having 3 to 20 carbon atoms; R⁴² represents a cyano group, an acyl group having 1 to 6 carbon atoms, an alkoxycarbonyl group having 2 to 6 carbon atoms, an alkyl group having 1 to 10 carbon atoms, an arylsulfinyl group having 6 to 10 carbon atoms, or a nitrogen-containing heteroaryl group having 3 to 10 carbon atoms; Z²'s each independently represent an atomic group forming a nitrogen-containing 5-membered heteroring or nitrogen-containing 6-membered heteroring with —C═N—; R⁴⁴ represents a hydrogen atom, an alkyl group having 1 to 20 carbon atoms, an aryl group having 6 to 20 carbon atoms, a heteroaryl group having 4 to 20 carbon atoms, (R^{4A})₂B—, (R^{4B})²P—, (R^{4C})₃Si—, or (R^{4D})ₙM-; R^{4A} to R^{4D} each independently represent an atom or a group; n represents an integer of 2 to 4, and M represents an n+1-valent metal atom; in a case in which R⁴⁴ represents (R^{4A})₂B—, (R^{4B})₂P—, (R^{4C})₃Si—, or (R^{4D})ₙM-, R⁴⁴ may form a covalent bond or a coordinate bond with a nitrogen-containing heterocycle formed by Z²; at least one selected from R^{41a}, R^{41b}, R⁴², and R⁴⁴ has a crosslinking group.

9. The infrared sensor according to claim 1,
wherein the near-infrared absorbing substance is a compound represented by General Formula (5) below; 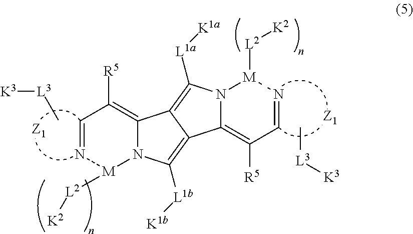
in General Formula (5), L^{1a}, L^{1b}, L², and L³ each independently represent a single bond or a divalent linking group; R⁵'s each independently represent a hydrogen atom or a substituent; Z¹ represents an atomic group forming a nitrogen-containing 5-membered heteroring or nitrogen-containing 6-membered heteroring with —C═N—; K^{1a}, K^{1b}, K², and K³ each independently represent a hydrogen atom, a fluorine atom, or a crosslinking group, and at least one of them represents a crosslinking group; M represents a boron atom, a phosphorus atom, a silicon atom, or a metallic atom; n's each independently represent an integer of 1 to 3; the bond between M and N indicated by a broken line represents a coordinate bond.

10. The infrared sensor according to claim 9,
wherein the near-infrared absorbing substance satisfies at least one selected from conditions 1A) to 3A) below;
1A) in General Formula (5), at least one selected from L^{1a} and L^{1b} includes a cyclic structure group having aromaticity;
2A) in General Formula (5), L² includes an aromatic hydrocarbon group; and
3A) in General Formula (5), L³ has a cyclic structure group having aromaticity.

11. The infrared sensor according to claim 9,
wherein, in General Formula (5), L^{1a} and L^{1b} each independently represent a single bond or an alkylene group having 1 to 30 carbon atoms, an arylene group having 6 to 20 carbon atoms, a heteroarylene group having 3 to 20 carbon atoms, —O—, —S—, —C(═O)—, or a group formed of a combination of these groups, L²'s each independently represent a single bond or an alkylene group having 1 to 20 carbon atoms, an arylene group having 6 to 18 carbon atoms, a heteroarylene group having 3 to 18 carbon atoms, —O—, —S—, —C(═O)—, or a group formed of a combination of these groups, L³'s each independently represent a single bond or an alkylene group having 1 to 20 carbon atoms, an arylene group having 6 to 18 carbon atoms, a heteroarylene group having 3 to 18 carbon atoms, —O—, —S—, —C(═O)—, or a group formed of a combination of these groups, and R⁵ is represented by a cyano group or a structure of General Formula (6) below; 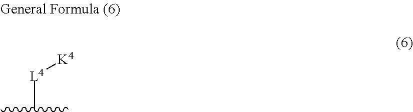
in General Formula (6), L⁴ represents a single bond or —O—, —C(═O)—, a sulfinyl group, an alkylene group having 1 to 10 carbon atoms, an arylene group having 6 to 18 carbon atoms, a nitrogen-containing heteroarylene group having 3 to 18 carbon atoms, or a group formed of a combination of these groups, and K⁴ represents a crosslinking group.

12. The infrared sensor according to claim 2,
wherein the crosslinking group is at least one selected from a (meth)acryloyloxy group, an epoxy group, an oxetanyl group, an isocyanate group, a hydroxyl group, an amino group, a carboxyl group, a thiol group, an alkoxysilyl group, a methylol group, a vinyl group, a (meth)acrylamido group, a sulfo group, a styryl group, and a maleimido group.

13. The infrared sensor according to claim 2,
wherein the crosslinking group is at least one selected from a (meth)acryloyloxy group, a vinyl group, an epoxy group, and an oxetanyl group.

14. The infrared sensor according to claim 2,
wherein the crosslinking group is at least one selected from crosslinking groups represented by General Formulae (A-1) to (A-3) below; 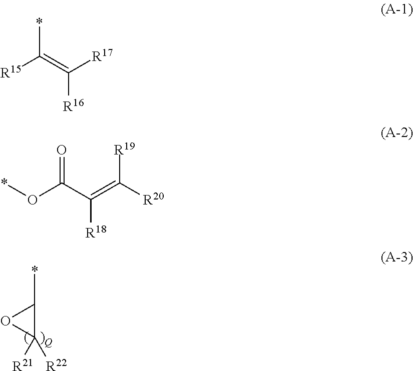
in Formula (A-1), R¹⁵, R¹⁶, and R¹⁷ each independently represent a hydrogen atom, an alkyl group having 1 to 18 carbon atoms, an alkenyl group having 1 to 18 carbon atoms, an alkynyl group having 1 to 18 carbon atoms, a cycloalkyl group having 3 to 18 carbon atoms, a cycloalkenyl group having 3 to 18 carbon atoms, a cycloalkynyl group having 3 to 18 carbon atoms, or an aryl group having 6 to 18 carbon atoms; in Formula (A-2), R¹⁸, R¹⁹, and R²⁰ each independently represent a hydrogen atom, a methyl group, a fluorine atom, or —CF₃; in Formula (A-3), R²¹ and R²² each independently represent a hydrogen atom, a methyl group, a fluorine atom, or —CF₃, and Q represents 1 or 2.

15. The infrared sensor according to claim 14,
wherein, in Formula (A-1), R¹⁶ and R¹⁷ represent hydrogen atoms, in Formula (A-2), R¹⁹ and R²⁰ represent hydrogen atoms, and, in Formula (A-3), R²¹ and R²² represent hydrogen atoms.

16. A near-infrared absorbing composition which is used to form near-infrared absorbing layers in infrared sensors that detect objects by detecting light having wavelengths of 700 nm or longer and shorter than 900 nm, comprising:
a near-infrared absorbing substance having a maximum absorption wavelength at a wavelength of 700 nm or longer and shorter than 900 nm.

17. The near-infrared absorbing composition according to claim 16,
wherein the near-infrared absorbing substance is a compound represented by General Formula (1) below; 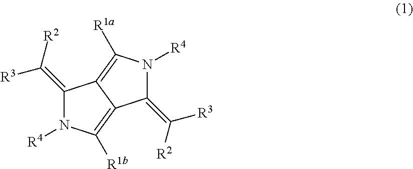
in General Formula (1), R^{1a} and R^{1b} each independently represent an alkyl group, an aryl group, or a heteroaryl group; R² and R³ each independently represent a hydrogen atom or a substituent, and R² and R³ may be bonded to each other and thus form a cyclic structure; R⁴'s each independently represent a hydrogen atom, an alkyl group, an aryl group, a heteroaryl group, (R^{4A})₂B—, (R^{4B})₂P—, (R^{4C})₃Si—, or (R^{4D})ₙM-; R^{4A} to R^{4D} each independently represent an atom or a group; n represents an integer of 2 to 4, and M represents an n+1-valent metal atom; in a case in which R⁴ represents (R^{4A})₂B—, (R^{4B})₂P—, (R^{4C})₃Si—, or (R^{4D})ₙM-, R⁴ may form a covalent bond or a coordinate bond with at least one selected from R^{1a}, R^{1b}, and R³; here, General Formula (1) satisfies at least one condition selected from at least one selected from R^{1a}, R^{1b}, and R⁴ having a crosslinking group and at least one selected from R² and R³ having crosslinking groups with a cyclic structure group therebetween, and, in a case in which the crosslinking group is an olefin group or a styryl group, the total number of the crosslinking groups is three or more.

18. A near-infrared absorbing composition comprising:
a compound represented by General Formula (1) below; 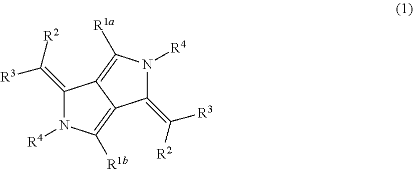
in General Formula (1), R^{1a} and R^{1b} each independently represent an alkyl group, an aryl group, or a heteroaryl group; R² and R³ each independently represent a hydrogen atom or a substituent, and R² and R³ may be bonded to each other and thus form a cyclic structure; R⁴'s each independently represent a hydrogen atom, an alkyl group, an aryl group, a heteroaryl group, (R^{4A})₂B—, (R^{4B})₂P—, (R^{4C})₃Si—, or (R^{4D})ₙM-; R^{4A} to R^{4D} each independently represent an atom or a group; n represents an integer of 2 to 4, and M represents an n+1-valent metal atom; in a case in which R⁴ represents (R^{4A})₂B—, (R^{4B})₂P—, (R^{4C})₃Si—, or (R^{4D})ₙM-, R⁴ may form a covalent bond or a coordinate bond with at least one selected from R^{1a}, R^{1b}, and R³; here, General Formula (1) satisfies at least one condition selected from at least one selected from R^{1a}, R^{1b}, and R⁴ having a crosslinking group and at least one selected from R² and R³ having crosslinking groups with a cyclic structure group therebetween, and, in a case in which the crosslinking group is an olefin group or a styryl group, the total number of the crosslinking groups is three or more.

19. The near-infrared absorbing composition according to claim 18, further comprising:
at least one selected from a curable compound, a polymerization initiator, a curing agent, and a solvent.

20. The near-infrared absorbing composition according to claim 18, further comprising:
a coloring agent different from the near-infrared absorbing substance or the compound represented by General Formula (1).

21. A cured film formed using the near-infrared absorbing composition according to claim 18.

22. A near-infrared absorbing filter formed using the near-infrared absorbing composition according to claim 18.

23. An image sensor comprising:
a photoelectric conversion element; and
the near-infrared absorbing filter according to claim 22 on the photoelectric conversion element.

24. A camera module comprising:
a solid image pickup element; and
the near-infrared absorbing filter according to claim 22.

25. A compound represented by General Formula (1) below: 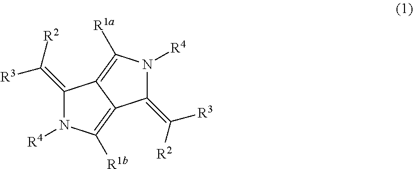
in General Formula (1), R^{1a} and R^{1b} each independently represent an alkyl group, an aryl group, or a heteroaryl group; R² and R³ each independently represent a hydrogen atom or a substituent, and R² and R³ may be bonded to each other and thus form a cyclic structure; R⁴'s each independently represent a hydrogen atom, an alkyl group, an aryl group, a heteroaryl group, (R^{4A})₂B—, (R^{4B})₂P—, (R^{4C})₃Si—, or (R^{4D})ₙM-; R^{4A} to R^{4D} each independently represent an atom or a group; n represents an integer of 2 to 4, and M represents an n+1-valent metal atom; in a case in which R⁴ represents (R^{4A})₂B—, (R^{4B})²P—, (R^{4C})₃Si—, or (R^{4D})ₙM-, R⁴ may form a covalent bond or a coordinate bond with at least one selected from R^{1a}, R^{1b}, and R³; here, General Formula (1) satisfies at least one condition selected from at least one selected from R^{1a}, R^{1b}, and R⁴ having a crosslinking group and at least one selected from R² and R³ having crosslinking groups with a cyclic structure group therebetween, and, in a case in which the crosslinking group is an olefin group or a styryl group, the total number of the crosslinking groups is three or more.

26. The compound according to claim 25,
wherein, in General Formula (1), one of R² and R³ is a cyano group, and the other is a group having a heterocyclic group.

27. The compound according to claim 25,
wherein the crosslinking group is at least one selected from a (meth)acryloyloxy group, an epoxy group, an oxetanyl group, an isocyanate group, a hydroxyl group, an amino group, a carboxyl group, a thiol group, an alkoxysilyl group, a methylol group, a vinyl group, a (meth)acrylamido group, a sulfo group, a styryl group, and a maleimido group, and, in a case in which the crosslinking group is a vinyl group or a styryl group, the total number of the crosslinking groups is three or more.
